(19) United States
(12) Patent Application Publication
(10) Pub. No.: US 2024/0423051 A1
(43) Pub. Date: Dec. 19, 2024

(54) DISPLAY SUBSTRATE AND MANUFACTURING METHOD THEREFOR, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Tiaomei ZHANG, Beijing (CN); Wenbo CHEN, Beijing (CN); Bangqing XIAO, Beijing (CN); Yujing LI, Beijing (CN); Zhiliang JIANG, Beijing (CN); Ming HU, Beijing (CN)

(21) Appl. No.: 18/702,338

(22) PCT Filed: Jul. 31, 2023
(86) PCT No.: PCT/CN2023/110408

§ 371 Date: Apr. 18, 2024

(30) Foreign Application Priority Data
Aug. 1, 2022 (CN) 202210913154.4

(51) Int. Cl. H10K 59/131; H10K 59/12; H10K 59/121; H10K 59/88

(52) U.S. Cl. CPC H10K 59/1315; H10K 59/1201; H10K 59/1213; H10K 59/1216; H10K 59/88

(57) ABSTRACT

A display substrate and manufacturing method therefor, and a display apparatus. The display substrate comprises driving structure layer comprising multiple light-emitting units and light-emitting structure layer comprising multiple unit rows and at least two dummy rows. A unit row comprises multiple circuit units arranged in a first direction, a dummy row comprises multiple dummy unit arranged in first direction, multiple unit rows and at least two dummy rows are sequentially arranged in a second direction intersecting first direction; at least one dummy row is provided with first connecting line extending in first direction and connected to first initial signal line extending in second direction to form a mesh structure for transmitting first initial signal; and/or at least another dummy row is provided with second connecting line extending in first direction and connected to a second initial signal line extending in second direction to form a mesh structure for transmitting second initial signal.

### CROSS-REFERENCE TO RELATED APPLICATIONS

The present application is a U.S. National Phase Entry of International Application No. PCT/CN2023/110408 having an international filing date of Jul. 31, 2023, which claims priority to Chinese Patent Application No. 202210913154.4 filed to the CNIPA on Aug. 1, 2022, which are hereby incorporated herein by reference in their entireties.

### TECHNICAL FIELD

The present disclosure relates to, but is not limited to, the field of display technologies, and particularly, to a display substrate and a preparation method therefor, and a display apparatus.

### BACKGROUND

An Organic Light Emitting Diode (OLED for short) and a Quantum-dot Light Emitting Diode (QLED for short) are active light emitting display devices, and have advantages, such as self-luminescence, wide viewing angle, high contrast ratio, low power consumption, very high response speed, lightness and thinness, flexibility, and low cost. With constant development of display technologies, a flexible display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matter described herein in detail. The summary is not intended to limit the scope of protection of the claims.

In one aspect, the present disclosure provides a display substrate including a drive structure layer disposed on a base substrate, and a light emitting structure layer disposed on a side of the drive structure layer away from the base substrate, wherein the light emitting structure layer includes a plurality of light emitting units, the drive structure layer includes a plurality of unit rows and at least two dummy rows, a unit row includes a plurality of circuit units sequentially arranged along a first direction, a dummy row includes a plurality of dummy units sequentially arranged along the first direction, the plurality of unit rows and the at least two dummy rows are sequentially provided along a second direction, the first direction and the second direction intersect; a circuit unit includes a pixel driving circuit, a dummy unit includes a dummy pixel circuit, the pixel driving circuit is configured to drive a corresponding light emitting unit, an orthographic projection of at least one light emitting unit on the base substrate at least partially overlaps an orthographic projection of the dummy pixel circuit on the base substrate; at least one dummy row is provided with a first connection line extending along the first direction, the first connection line is connected with a first initial signal line extending along the second direction to form a mesh structure for transmitting a first initial signal; and/or, at least another dummy row is provided with a second connection line extending along the first direction, the second connection line is connected with a second initial signal line extending along the second direction, to form a mesh structure for transmitting a second initial signal.

In an exemplary implementations, in a plane perpendicular to the base substrate, the drive structure layer includes a semiconductor layer, a first conductive layer, a second conductive layer, and a third conductive layer that are sequentially disposed on the base substrate, the first connection line is disposed in at least one of the semiconductor layer, the first conductive layer, and the second conductive layer, the second connection line is disposed in at least one of the semiconductor layer, the first conductive layer, and the second conductive layer, and the first initial signal line and the second initial signal line are disposed in the third conductive layer.

In an exemplary implementations, a first conductive layer in a dummy unit of the at least one dummy row includes the first connection line; a third conductive layer of at least one dummy unit in the dummy row at least includes a first initial electrode, the first initial signal line is connected with the first initial electrode, and the first initial electrode is connected with the first connection line through a via.

In an exemplary implementations, a first conductive layer in a dummy unit of the at least one dummy row includes the second connection line; a third conductive layer of at least one dummy unit in the dummy row at least includes a second initial electrode, the second initial signal line is connected with the second initial electrode, and the second initial electrode is connected with the second connection line through a via.

In an exemplary implementations, a second conductive layer in a dummy unit of the at least one dummy row includes the first connection line; a third conductive layer of at least one dummy unit in the dummy row at least includes a third initial electrode, the first initial signal line is connected with the third initial electrode, and the third initial electrode is connected with the first connection line through a via.

In an exemplary implementations, a second conductive layer in a dummy unit of the at least one dummy row includes the second connection line; a third conductive layer of at least one dummy unit in the dummy row at least includes a fourth initial electrode, the second initial signal line is connected with the fourth initial electrode, and the fourth initial electrode is connected with the second connection line through a via.

In an exemplary implementations, a semiconductor layer in a dummy unit of the at least one dummy row includes the first connection line; a third conductive layer of at least one dummy unit in the dummy row at least includes a fifth initial electrode, the first initial signal line is connected with the fifth initial electrode, and the fifth initial electrode is connected with the first connection line through a via.

In an exemplary implementations, a semiconductor layer in a dummy unit of the at least one dummy row includes the second connection line; a third conductive layer of at least one dummy unit in the dummy row at least includes a sixth initial electrode, the second initial signal line is connected with the sixth initial electrode, and the sixth initial electrode is connected with the second connection line through a via.

In an exemplary implementations, a first conductive layer in a dummy unit of the at least one dummy row includes the first connection line, and a second conductive layer in a dummy unit of the dummy row includes the second connection line; a third conductive layer of at least one dummy unit in the dummy row at least includes a first initial electrode and a fourth initial electrode, the first initial signal line is connected with the first initial electrode, the first initial electrode is connected with the first connection line through a via, the second initial signal line is connected with the fourth initial electrode, and the fourth initial electrode is connected with the second connection line through a via.

In an exemplary implementations, a first conductive layer in a dummy unit of the at least one dummy row includes the second connection line, and a second conductive layer in a dummy unit of the dummy row includes the first connection line; a third conductive layer of at least one dummy unit in the dummy row at least includes a second initial electrode and a third initial electrode, the first initial signal line is connected to the third initial electrode, the third initial electrode is connected to the first connection line through a via, the second initial signal line is connected to the second initial electrode, and the second initial electrode is connected to the second connection line through a via.

In an exemplary implementations, a first conductive layer of a dummy unit of the at least one dummy row includes the first connection line, and a third conductive layer of at least one dummy unit of the dummy row at least includes a first initial electrode, the first initial signal line is connected to the first initial electrode, the first initial electrode is connected to the first connection line through a via; a first conductive layer of a dummy unit of at least another dummy row includes the second connection line, a third conductive layer of at least one dummy unit of the dummy row at least includes a second initial electrode, the second initial signal line is connected to the second initial electrode, and the second initial electrode is connected to the second connection line through a via.

In an exemplary implementations, a second conductive layer in a dummy unit of the at least one dummy row includes the first connection line, and a third conductive layer of at least one dummy unit of the dummy row at least includes a third initial electrode, the first initial signal line is connected to the third initial electrode, and the third initial electrode is connected to the first connection line through a via; a second conductive layer in a dummy unit of at least another dummy row includes the second connection line, a third conductive layer of at least one dummy unit of the dummy row at least includes a fourth initial electrode, the second initial signal line is connected to the fourth initial electrode, and the fourth initial electrode is connected to the second connection line through a via.

In an exemplary implementations, at least one circuit unit includes a pixel driving circuit at least including a first transistor, a second transistor, a third transistor, a fourth transistor, a fifth transistor, a sixth transistor, a seventh transistor, a first node and a second node; a first electrode of the first transistor is connected to the first initial signal line, a second electrode of the first transistor is connected to the second node, a first electrode of the second transistor is connected to the second node, a second electrode of the second transistor is connected to a second electrode of the third transistor and a first electrode of the sixth transistor, a first electrode of the third transistor is connected to the first node, a first electrode of the fourth transistor is connected to a data signal line, a second electrode of the fourth transistor is connected to the first node, a first electrode of the fifth transistor is connected to a first power supply line, a second electrode of the fifth transistor is connected to the first node, a second electrode of the sixth transistor is connected to a second electrode of the seventh transistor, and a first electrode of the seventh transistor is connected to the second initial signal line.

In an exemplary implementations, in at least one circuit unit, an active layer of the third transistor is in a shape of a straight line extending along the first direction.

In an exemplary implementations, in at least one circuit unit, the first transistor, the sixth transistor, and the seventh transistor are disposed on a same side of the third transistor in the second direction.

In an exemplary implementations, an orthographic projection of the second node on the base substrate overlaps at least partially an orthographic projection of the first power supply line on the base substrate.

In an exemplary implementations, the second node is located between the first initial signal line and the second initial signal line in the first direction.

In an exemplary implementations, at least one circuit unit further includes a light emitting control line extending along the first direction, the light emitting control line is connected to a gate electrode of the fifth transistor and a gate electrode of the sixth transistor, and an orthographic projection of the second node on the base substrate at least partially overlaps an orthographic projection of the light emitting control line on the base substrate.

In an exemplary implementations, the pixel driving circuit further includes a first shielding electrode connected to the first initial signal line, an orthographic projection of the first shielding electrode on the base substrate at least partially overlaps an orthographic projection of an active layer of the first transistor on the base substrate.

In an exemplary implementations, orthographic projections of a via through which the first electrode of the fifth transistor is connected to a first region of an active layer of the fifth transistor, a via through which the second electrode of the sixth transistor is connected to a second region of an active layer of the sixth transistor, a via through which the first initial signal line is connected to a first region of an active layer of the first transistor, a via through which the second node is connected to a second region of the active layer of the first transistor on the base substrate at least partially overlap an orthographic projection of a hole extension line on the base substrate, the hole extension line is a straight line extending along the first direction.

In an exemplary implementations, at least one dummy unit includes a dummy pixel circuit at least including a semiconductor body part and a storage capacitor, the storage capacitor includes a first electrode plate and a second electrode plate, an orthographic projection of the first electrode plate on the base substrate at least partially overlaps an orthographic projection of the second electrode plate on the base substrate; semiconductor body parts adjacent in the first direction are connected to each other by a third auxiliary connection line to form the first connection line or the second connection line, or first electrode plates adjacent in the first direction are connected to each other by a first auxiliary connection line to form the first connection line or the second connection line, or second electrode plates adjacent in the first direction are connected to each other by a second auxiliary connection line to form the first connection line or the second connection line.

In an exemplary implementations, the dummy pixel circuit of the at least one dummy unit is connected to a first dummy signal line, a second dummy signal line and/or a dummy light emitting line, the first dummy signal line, the second dummy signal line and/or the dummy light emitting line, after extending to one side or two sides of the display substrate along the first direction, are connected to a bezel power supply lead line in a bezel region, the bezel power supply lead line is configured to transmit a high voltage power supply signal or a low voltage power supply signal.

In an exemplary implementations, the dummy pixel circuit of the at least one dummy unit further includes a first dummy transistor, a second dummy transistor, a third dummy transistor, a fourth dummy transistor, a fifth dummy transistor, a sixth dummy transistor, and a seventh dummy transistor, an active layer of the third dummy transistor serves as the semiconductor body part, and active layers of the first dummy transistor, the second dummy transistor, the fourth dummy transistor, the fifth dummy transistor, the sixth dummy transistor, and the seventh dummy transistor lack channel regions.

In an exemplary implementations, one or two unit rows are provided between dummy rows adjacent in the second direction.

In an exemplary implementations, a size of the dummy row in the second direction is less than or equal to a size of the unit row in the second direction.

In an exemplary implementations, a light emitting unit at least includes an anode, an orthographic projection of the anode on the base substrate at least partially overlaps an orthographic projection of the first connection line on the base substrate; and/or, an orthographic projection of the anode on the base substrate at least partially overlaps an orthographic projection of the second connection line on the base substrate.

In an exemplary implementations, for anodes of light emitting units of a same color, an orthographic projection of the anodes on the base substrate and an orthographic projection of the first connection line on the base substrate have a first overlapping region, the orthographic projection of the anodes on the base substrate and an orthographic projection of the second connection line on the base substrate have a second overlapping region, the orthographic projection of the anodes on the base substrate and an orthographic projection of the second electrode plate of the pixel driving circuit in at least one circuit unit have a third overlapping region, an area of at least one first overlapping region is smaller than an area of the third overlapping region, and an area of at least one second overlapping region is smaller than the area of the third overlapping region.

In another aspect, the present disclosure also provides a display apparatus, including the display substrate described above.

In another aspect, the present disclosure further provides a preparation method for a display substrate, including:
forming a drive structure layer on a base substrate; wherein the drive structure layer includes a plurality of unit rows and at least two dummy rows, a unit row includes a plurality of circuit units sequentially arranged along a first direction, a dummy row includes a plurality of dummy units sequentially arranged along the first direction, the plurality of unit rows and the at least two dummy rows are sequentially provided along a second direction, the first direction and the second direction intersect; a circuit unit includes a pixel driving circuit, a dummy unit includes a dummy pixel circuit, the pixel driving circuit is configured to drive a corresponding light emitting unit; at least one dummy row is provided with a first connection line extending along the first direction, the first connection line is connected with a first initial signal line extending along the second direction to form a mesh structure for transmitting a first initial signal; and/or, at least one another dummy row is provided with a second connection line extending along the first direction, the second connection line is connected with a second initial signal line extending along the second direction to form a mesh structure for transmitting a second initial signal; and
forming a light emitting structure layer on the drive structure layer, wherein the light emitting structure layer includes a plurality of light emitting units, an orthographic projection of at least one light emitting unit on the base substrate at least partially overlaps an orthographic projection of the dummy pixel circuit on the base substrate.

Other aspects of the present disclosure may be comprehended after the drawings and the detailed descriptions are read and understood.

### BRIEF DESCRIPTION OF DRAWINGS

Accompany drawings are used to provide understanding of technical solution of the present disclosure, and form a part of the specification. The accompany drawings and embodiments of the present disclosure are adopted to explain the technical solution of the present disclosure, and do not form limitations on the technical solution of the present disclosure.

FIG. 1 is a schematic diagram of a structure of a display apparatus.

FIG. 2 is a schematic diagram of a structure of a display substrate.

FIG. 3 is a schematic diagram of a sectional structure of a display region in a display substrate.

FIG. 4 is a schematic diagram of an equivalent circuit of a pixel driving circuit.

FIG. 5 is a schematic diagram of a planar structure of a light emitting structure layer in a display substrate according to an embodiment of the present disclosure.

FIG. 6 is a schematic diagram of a planar structure of a drive circuit layer in a display substrate according to an embodiment of the present disclosure.

FIG. 7 is a schematic diagram of an arrangement of a first circuit region according to an exemplary embodiment of the present disclosure.

FIG. 8 is a schematic diagram of an arrangement of another first circuit region according to an exemplary embodiment of the present disclosure.

FIG. 9 is a schematic diagram of an arrangement of yet another first circuit region according to an exemplary embodiment of the present disclosure.

FIG. 10 is a schematic diagram of an arrangement of still yet another first circuit region according to an exemplary embodiment of the present disclosure.

FIG. 11 is a schematic diagram of a planar structure of a second circuit region according to an exemplary embodiment of the present disclosure.

FIG. 12 is a schematic diagram of a structure of a first circuit region according to an exemplary embodiment of the present disclosure.

FIG. 13 is a schematic diagram of an initial signal line with a mesh structure according to an exemplary embodiment of the present disclosure.

FIG. 14 is a schematic diagram of a display substrate after a pattern of a semiconductor layer is formed according to the present disclosure.

FIG. 15A is a schematic diagram of a display substrate after a pattern of a first conductive layer is formed according to the present disclosure.

FIG. 15B is a schematic planar view of the first conductive layer in FIG. 15A.

FIG. 16A is a schematic diagram of a display substrate after a pattern of a second conductive layer is formed according to the present disclosure.

FIG. 16B is a schematic planar view of the second conductive layer in FIG. 16A.

FIG. 17 is a schematic diagram of a display substrate after a pattern of a fourth insulating layer is formed according to the present disclosure.

FIG. 18A is a schematic diagram of a display substrate after a pattern of a third conductive layer is formed according to the present disclosure.

FIG. 18B is a schematic planar view of the third conductive layer in FIG. 18A.

FIG. 19 is a schematic diagram of a display substrate after a pattern of a first planarization layer is formed according to the present disclosure.

FIG. 20A is a schematic diagram of a display substrate after a pattern of a fourth conductive layer is formed according to the present disclosure.

FIG. 20B is a schematic planar view of the fourth conductive layer in FIG. 20A.

FIG. 21 is a schematic diagram of an initial signal line with another mesh structure according to an exemplary embodiment of the present disclosure.

FIG. 22 is a schematic diagram of the display substrate shown in FIG. 21 after a pattern of a first conductive layer is formed.

FIG. 23 is a schematic diagram of the display substrate shown in FIG. 21 after a pattern of a second conductive layer is formed.

FIG. 24 is a schematic diagram of the display substrate shown in FIG. 21 after a pattern of a third conductive layer is formed.

FIG. 25 is a schematic diagram of an initial signal line with yet another mesh structure according to an exemplary embodiment of the present disclosure.

FIG. 26 is a schematic diagram of the display substrate shown in FIG. 25 after a pattern of a semiconductor layer is formed.

FIG. 27 is a schematic diagram of the display substrate shown in FIG. 25 after a pattern of a first conductive layer is formed.

FIG. 28 is a schematic diagram of the display substrate shown in FIG. 25 after a pattern of a second conductive layer is formed.

FIG. 29 is a schematic diagram of the display substrate shown in FIG. 25 after a pattern of a fourth insulating layer is formed.

FIG. 30 is a schematic diagram of the display substrate shown in FIG. 25 after a pattern of a third conductive layer is formed.

FIG. 31 is a schematic diagram of an initial signal line with still yet another mesh structure according to an exemplary embodiment of the present disclosure.

FIG. 32 is a schematic diagram of an initial signal line with also still yet another mesh structure according to an exemplary embodiment of the present disclosure.

FIG. 33 is a schematic diagram of an initial signal line with also still further yet another mesh structure according to an exemplary embodiment of the present disclosure.

FIG. 34 is a schematic diagram of another first circuit region after a pattern of a semiconductor layer is formed according to an embodiment of the present disclosure.

FIG. 35 is a schematic diagram of another first circuit region after a pattern of a first conductive layer is formed according to an embodiment of the present disclosure.

FIG. 36 is a schematic diagram of another first circuit region after a pattern of a second conductive layer is formed according to an embodiment of the present disclosure.

FIG. 37 is a schematic diagram of another first circuit region after forming a pattern of a third conductive layer is formed according to an embodiment of the present disclosure.

FIG. 38 is a schematic diagram of an arrangement of anodes in a first circuit region according to an embodiment of the present disclosure.

Reference signs are described as follows.

| | | |
|---|---|---|
| 11-First active layer; | 12-Second active layer; | 13-Third active layer; |
| 14-Fourth active layer; | 15-Fifth active layer; | 16-Sixth active layer; |
| 17-Seventh active layer; | 18-Fracture; | 19-Third auxiliary connection line; |
| 21-First scan signal line; | 22-Second scan signal line; | 23-Light emitting control line; |
| 24-First electrode plate; | 25-First auxiliary connection line; | 31-Second electrode plate; |
| 32-Second auxiliary connection line; | 33-Opening; | 41-First connection electrode; |
| 42-Second connection electrode; | 43-Third connection electrode; | 44-Fourth connection electrode; |
| 45-First shielding electrode; | 51-Data signal line; | 52-First power supply line; |
| 53-Power supply connection electrode; | 54-Anode connection electrode; | 61-First initial signal line; |
| 62-Second initial signal line; | 71-First connection line; | 72-Second connection line; |
| 81-First initial electrode; | 82-Second initial electrode; | 83-Third initial electrode; |
| 84-Fourth initial electrode; | 85-Fifth initial electrode; | 86-Sixth initial electrode; |
| 100-Display region; | 101-Base substrate; | 102-Drive circuit layer; |
| 103-Light emitting structure layer; | 104-Encapsulation structure layer; | 110-First circuit region; |
| 120-Second circuit region; | 121-Compression circuit region; | 122-Connection line region; |
| 200-Bonding region; | 300-Bezel region; | 301-Anode; |
| 302-Pixel definition layer; | 303-Organic light emitting layer; | 304-Cathode; |
| 401-First encapsulation layer; | 402-Second encapsulation layer; | 403-Third encapsulation layer; |
| 411-Eleventh connection electrode; | 412-Twelfth connection electrode; | 413-Thirteenth connection electrode; |
| 414-Fourteenth connection electrode. | | |

### DETAILED DESCRIPTION

To make the objectives, technical solutions, and advantages of the present disclosure clearer, the embodiments of the present disclosure will be described in detail below in with reference to the accompany drawings. It is to be noted that the implementations may be implemented in various forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementations of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the composition elements may be changed as appropriate according to a direction according to which each composition element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or detachable connection, or integral connection; it may be a mechanical connection or electrical connection; it may be a direct connection, or indirect connection through an intermediate, or internal communication between two elements. Those of ordinary skills in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In cases that transistors with opposite polarities are used, or a current direction changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of composition elements through an element with a certain electrical action. An “element with a certain electrical action” is not particularly limited as long as electric signals between the connected composition elements may be sent and received. Examples of the “element with the certain electrical action” not only include an electrode and a line, but also include a switch element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulating thin film” may be replaced with an “insulating layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

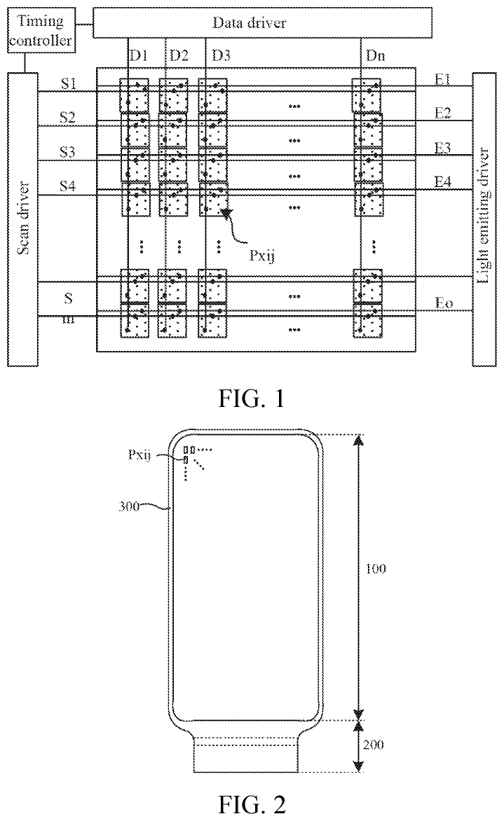

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include a plurality of sub-pixels Pxij, i and j may be natural numbers. At least one sub-pixel Pxij may include a circuit unit and a light emitting device connected to the circuit unit. The circuit unit may include a pixel driving circuit connected to a scan signal line, a data signal line and a light emitting signal line. In an exemplary implementations, the timing controller may provide a grayscale value and a control signal suitable for a specification of the data signal driver to the data signal driver, may provide a clock signal, a scan start signal, etc. suitable for a specification of the scan driver to the scan driver, and may provide a clock signal, an emission stop signal, etc. suitable for a specification of the light emitting driver to the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and generate a scan signal in a manner of sequentially transmitting a scan start signal provided in a form of an on-level pulse to a next-stage circuit under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

FIG. 2 is a schematic diagram of a structure of a display substrate. As shown in FIG. 2, the display substrate may include a display region 100, a bonding region 200 located at a side of the display region 100, and a bezel region 300 located at another side of the display region 100. In an exemplary implementations, the display region 100 may be a flat region, including a plurality of sub-pixels Pxij that constitute a pixel array, wherein the plurality of sub-pixels Pxij are configured to display a dynamic picture or a static image, and the display region 100 may be referred to as an Active Area (Active Area, AA for short). In an exemplary implementation, the display substrate may be deformable, e.g., may be crimped, bent, folded, or curled.

In an exemplary implementations, the bonding region 200 may include a fan-out region, a bending region, a drive chip region, and a bonding pin region that are disposed sequentially along a direction away from the display region 100. The fan-out region is connected with the display region, and may at least include a data fan-out line, a high voltage power supply line, and a low voltage power supply line. A plurality of data fan-out lines are configured to be connected with data signal lines of the display region in a Fan-out trace manner, the high voltage power supply line is configured to be connected with a first power supply line (VDD) of the display region 100, and the low voltage power supply line is configured to be connected with a second power supply line (VSS) of the bezel region 300. The bending region is connected to the fan-out region and may include a composite insulating layer provided with a groove, and is configured to bend the bonding region to a back of the display region. The drive chip region may at least include an Integrated Circuit (IC for short) and is configured to be connected to the plurality of data fan-out lines. The bonding pin zone may at least include a plurality of bonding pads, and is configured to be bonded to and connected with an external Flexible Printed Circuit (FPC for short).

In an exemplary implementations, the bezel region 300 may include a circuit region, a power supply line region, and a crack dam region, and a cutting region which are sequentially disposed along the direction away from the display region 100. The circuit region is connected to the display region 100 and may at least include a gate drive circuit which is connected to a first scan signal line, a second scan signal line, and a light emitting control line of a pixel driving circuit in the display region 100. The power supply line region is connected to the circuit region and may at least include a power supply lead line, and the power supply lead line extends along a direction parallel to an edge of the display region and is connected with a cathode in the display region 100. The crack dam region is connected to the power supply line region and may at least include a plurality of cracks arranged on the composite insulating layer. The cutting region is connected to the crack dam region and may at least include a cutting groove arranged on the composite insulating layer, and the cutting groove is configured that a cutting device implements cutting along cutting grooves respectively after preparation of all film layers of the display substrate are completed.

In an exemplary implementation, the fan-out region in the bonding region 200 and the power supply line region in the bezel region 300 may be provided with a first isolation dam and a second isolation dam, the first isolation dam and the second isolation dam may extend in a direction parallel to an edge of the display region, thus forming an annular structure surrounding the display region 100, wherein the edge of the display region is an edge at a side of the display region, the bonding region or the bezel region.

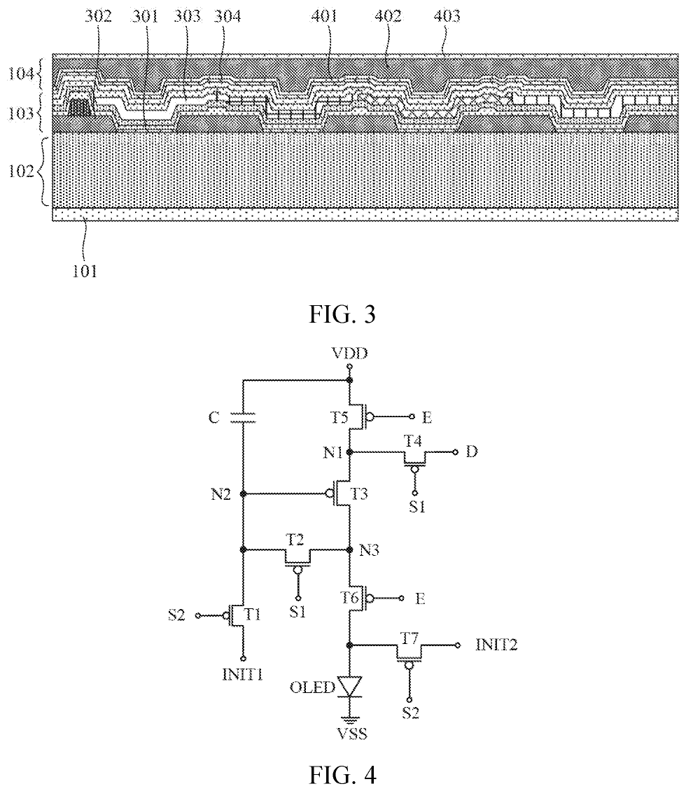

FIG. 3 is a schematic diagram of a sectional structure of a display region in a display substrate, illustrating a structure of four sub-pixels of the display region. As shown in FIG. 3, on a plane perpendicular to the display substrate, the display substrate may include a drive circuit layer 102 arranged on a base substrate 101, a light emitting structure layer 103 arranged on a side of the drive circuit layer 102 away from the base substrate, and an encapsulation layer 104 arranged on a side of the light emitting structure layer 103 away from the base substrate. In some possible implementations, the display substrate may include another film layer, such as a touch structure layer, which is not limited here in the present disclosure.

In an exemplary implementations, the base substrate 101 may be a flexible base substrate, or may be a rigid base substrate. The drive circuit layer 102 may include a plurality of circuit units, a circuit unit may at least include a pixel driving circuit, and the pixel driving circuit may include a plurality of transistors and a storage capacitor. The light emitting structure layer 103 may include a plurality of light emitting units, each of which may include an anode 301, a pixel definition layer 302, an organic light emitting layer 303 and a cathode 304. The organic light emitting layer 303 is disposed between the anode 301 and the cathode 304, and the organic light emitting layer 303 emits light of a corresponding color under driving of the anode 301 and the cathode 304. The encapsulation structure layer 104 may include a first encapsulation layer 401, a second encapsulation layer 402, and a third encapsulation layer 403 which are stacked, the first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403, which may ensure that external water vapor cannot enter the light emitting structure layer 103.

In an exemplary implementations, the organic light emitting layer may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementations, one or more layers of hole injection layers, hole transport layers, electron block layers, hole block layers, electron transport layers, and electron injection layers of all light emitting units may be connected together to be a common layer. Emitting layers of adjacent light emitting units may be overlapped slightly, or may be mutually isolated.

FIG. 4 is a schematic diagram of an equivalent circuit of a pixel driving circuit. In an exemplary implementations, the pixel driving circuit may have a structure of 3T1C, 4T1C, 5T1C, 5T2C, 6T1C, 7T1C, or 8T1C. As shown in FIG. 4, the pixel driving circuit may include seven transistors (a first transistor T1 to a seventh transistor T7), one storage capacitor C, and the pixel driving circuit is respectively connected with eight signal lines (a data signal line D, a first scan signal line S1, a second scan signal line S2, a light emitting signal line E, a first initial signal line INIT1, a second initial signal line INIT2, a first power supply line VDD, and a second power supply line VSS).

In an exemplary implementations, the pixel driving circuit may include a first node N1, a second node N2, and a third node N3. The first node N1 is connected to a first electrode of the third transistor T3, a second electrode of the fourth transistor T4 and a second electrode of the fifth transistor T5 respectively. The second node N2 is connected to a second electrode of the first transistor, a first electrode of the second transistor T2, a control electrode of the third transistor T3 and a second end of the storage capacitor C respectively. The third node N3 is connected to a second electrode of the second transistor T2, a second electrode of the third transistor T3 and a first electrode of the sixth transistor T6 respectively.

In an exemplary implementation, a first end of the storage capacitor C is connected to the first power supply line VDD, and the second end of the storage capacitor C is connected to the second node N2, i.e., the second end of the storage capacitor C is connected to the control electrode of the third transistor T3.

A control electrode of the first transistor T1 is connected with the second scan signal line S2, a first electrode of the first transistor T1 is connected with the first initial signal line INIT1, and a second electrode of the first transistor is connected with the second node N2. When a scan signal with an on-level is applied to the second scan signal line S2, the first transistor T1 transmits a first initial voltage to the control electrode of the third transistor T3 so as to initialize a charge amount of the control electrode of the third transistor T3.

The control electrode of the second transistor T2 is connected with the first scan signal line S1, the first electrode of the second transistor T2 is connected with the second node N2, and the second electrode of the second transistor T2 is connected with the third node N3. When a scan signal with an on-level is applied to the first scan signal line S1, the second transistor T2 enables the control electrode of the third transistor T3 to be connected with the second electrode of the third transistor T3.

The control electrode of the third transistor T3 is connected with the second node N2, i.e., the control electrode of the third transistor T3 is connected with the second end of the storage capacitor C, the first electrode of the third transistor T3 is connected with the first node N1, and the second electrode of the third transistor T3 is connected with the third node N3. The third transistor T3 may be referred to as a drive transistor, and the third transistor T3 determines an amount of a drive current flowing between the first power supply line VDD and the second power supply line VSS according to a potential difference between the control electrode and the first electrode of the third transistor T3.

The control electrode of the fourth transistor T4 is connected with the first scan signal line S1, the first electrode of the fourth transistor T4 is connected with the data signal line D, and the second electrode of the fourth transistor T4 is connected with the first node N1. The fourth transistor T4, may be referred to as a switch transistor, a scan transistor, etc., and the fourth transistor T4 enables a data voltage of the data signal line D to be input into the pixel driving circuit when a scan signal with an on level is applied to the first scan signal line S1.

The control electrode of the fifth transistor T5 is connected with the light emitting signal line E, the first electrode of the fifth transistor T5 is connected with the first power supply line VDD, and the second electrode of the fifth transistor T5 is connected with the first node N1. The control electrode of the sixth transistor T6 is connected to the light emitting signal line E, the first electrode of the sixth transistor T6 is connected to the third node N3, and the second electrode of the sixth transistor T6 is connected to the first electrode of the light emitting device. The fifth transistor T5 and the sixth transistor T6 may be referred to as light emitting transistors. When a light emitting signal with an on level is applied to the light emitting signal line E, the fifth transistor T5 and the sixth transistor T6 enable the light emitting device to emit light by forming a drive current path between the first power supply line VDD and the second power supply line VSS.

A control electrode of the seventh transistor T7 is connected with the second scan signal line S2, a first electrode of the seventh transistor T7 is connected with the second initial signal line INIT2, and a second electrode of the seventh transistor T7 is connected with the first electrode of the light emitting device. When a scan signal with an on-level is applied to the second scan signal line S2, the seventh transistor T7 transmits an second initialization voltage to the first electrode of the light emitting device so as to initialize a charge amount accumulated in the first electrode of the light emitting device or release a charge amount accumulated in the first electrode of the light emitting device.

In an exemplary implementation, the light emitting device may be an OLED including a first electrode (anode), an organic light emitting layer, and a second electrode (cathode) which are stacked, or may be a QLED including a first electrode (anode), a quantum dot emitting layer, and a second electrode (cathode) which are stacked.

In an exemplary implementation, the second electrode of the light emitting device is connected to the second power supply line VSS, a signal of the second power supply line VSS is a low-level signal, and a signal of the first power supply line VDD is a high-level signal continuously provided.

In an exemplary implementation, the first transistor T1 to the seventh transistor T7 may be P-type transistors, or may be N-type transistors. Use of a same type of transistors in a pixel driving circuit may simplify a process flow, reduce a process difficulty of a display panel, and improve a product yield. In some possible implementations, the first transistor T1 to the seventh transistor T7 may include a P-type transistor and an N-type transistor.

In an exemplary implementations, for the first transistor T1 to the seventh transistor T7, low temperature poly-silicon thin film transistors may be used, or oxide thin film transistors may be used, or both a low temperature poly-silicon thin film transistor and an oxide thin film transistor may be used. An active layer of a low temperature poly-silicon thin film transistor may be made of Low Temperature Poly-Silicon (LTPS for short), and an active layer of an oxide thin film transistor may be made of an oxide semiconductor (Oxide). Low temperature poly-silicon thin film transistors have advantages such as high migration rate and fast charging, and oxide thin film transistors have advantages such as low leakage current. The low temperature poly-silicon thin film transistors and the oxide thin film transistors are integrated on one display substrate to form a low temperature polycrystalline oxide (LTPO) display substrate, so that the advantages of both the low temperature poly-silicon thin film transistors and the oxide thin film transistors can be utilized, low-frequency driving can be achieved, power consumption can be decreased, and display quality can be improved.

In an exemplary implementations, taking a case that seven transistors in FIG. 4 are all P-type transistors as an example, a working process of the pixel driving circuit may include following stages.

In a first stage A1, referred to as a reset stage, a signal of the second scan signal line S2 is a low-level signal, and signals of the first scan signal line S1 and the light emitting signal line E are high-level signals. The signal of the second scan signal line S2 is a low-level signal, which causes the first transistor T1 and the seventh transistor T7 to be turned on. The first transistor T1 is turned on so that a first initial voltage of the first initial signal line INIT1 is provided to the second node N2 to initialize the storage capacitor C to clear an original data voltage in the storage capacitor. The seventh transistor T7 is turned on, so that a second initial voltage of the second initial signal line INIT2 is provided to a first electrode of an OLED to initialize (reset) the first electrode of the OLED and clear its internal pre-stored voltage, thereby completing initialization. The signals of the first scan signal line S1 and the light emitting signal line E are high-level signals, so that the second transistor T2, the fourth transistor T4, the fifth transistor T5 and the sixth transistor T6 are turned off. An OLED does not emit light in this stage.

In a second stage A2, referred to as a data writing stage or a threshold compensation stage, a signal of the first scan signal line S1 is a low-level signal, signals of the second scan signal line S2 and the light emitting signal line E are high-level signals, and the data signal line D outputs a data voltage. In this stage, the second end of the storage capacitor C is at a low level, so the third transistor T3 is turned on. The signal of the first scan signal line S1 is the low-level signal, so that the second transistor T2 and the fourth transistor T4 are turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd−|Vth|, wherein Vd is the data voltage output by the data signal line D, and Vth is the threshold voltage of the third transistor T3. The signal of the second scan signal line S2 is the high-level signal, so that the first transistor T1 and the seventh transistor T7 are turned off. A signal of the light emitting signal line E is a high-level signal, so that the fifth transistor T5 and the sixth transistor T6 are turned off.

In a third stage A3, referred to as a light emitting stage, a signal of the light emitting signal line E is a low-level signal, and signals of the first scan signal line S1 and the second scan signal line S2 are high-level signals. The signal of the light emitting signal line E is the low-level signal, so that the fifth transistor T5 and the sixth transistor T6 are turned on, and a power voltage output by the first power supply line VDD provides a drive voltage to the first electrode of the OLED through the turned-on fifth transistor T5, the third transistor T3, and the sixth transistor T6 to drive the OLED to emit light.

In a driving process of the pixel driving circuit, a drive current flowing through the third transistor T3 (drive transistor) is determined by a voltage difference between the gate electrode and the first electrode of the third transistor T3. Since the voltage of the second node N2 is Vd−|Vth|, the drive current of the third transistor T3 is as follows.

$${I = K * {( Vgs - Vth )}^{2} = K * [ Vdd - Vd + \vert Vth \vert ) - Vth ]}^{2} = K * {[ ( Vdd - Vd ]}^{2}$$

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

With development of OLED display technologies, consumers have higher requirements for a display effect of a display product. A narrow bezel and a full screen have become a new trend in development of display products. Therefore, bezel narrowing or even a frameless design has received more attention in a design of an OLED display product. Since signal lines of an integrated circuit and a bonding pad in a bonding region need to be led into a relatively wide display region through data fan-out lines in a fan-out manner, a fan-shaped region occupies relatively large space, resulting in a relatively large width of a lower bezel. In addition, the existing display substrate still has the problem of poor display uniformity.

Exemplary embodiments of the present disclosure provide a display substrate. On a plane perpendicular to the display substrate, the display substrate may include a drive circuit layer disposed on a base substrate, a light emitting structure layer disposed on a side of the drive circuit layer away from the base substrate, and an encapsulation structure layer disposed on a side of the light emitting structure layer away from the base substrate. The drive circuit layer may include a plurality of circuit units, a circuit unit may at least include a pixel driving circuit configured to output a corresponding current to a connected light emitting device. The light emitting structure layer may include a plurality of light emitting units, each of which may include a light emitting device configured to emit light of a corresponding brightness in response to a current output by the connected pixel driving circuit.

In an exemplary implementation, the circuit units mentioned in the present disclosure refer to regions divided according to pixel driving circuits, and light emitting units mentioned in the present disclosure refer to regions divided according to light emitting devices. In an exemplary implementation, a position and shape of an orthographic projection of a light emitting unit on the base substrate may correspond to a position and shape of an orthographic projection of a circuit unit on the base substrate, or the position and shape of the orthographic projection of the light emitting unit on the base substrate may not correspond to the position and shape of the orthographic projection of the circuit unit on the base substrate.

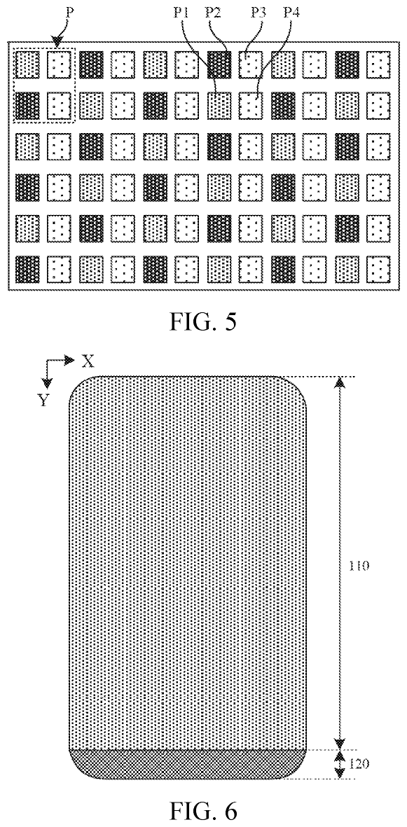

FIG. 5 is a schematic diagram of a planar structure of a light emitting structure layer in a display substrate according to an exemplary example of the present disclosure. As shown in FIG. 5, in an exemplary implementations, on a plane parallel to the display substrate, the light emitting structure layer of the display substrate may include a plurality of pixel units P arranged in a matrix manner, at least one pixel unit P may include a first light emitting unit P1 emitting light of a first color, a second light emitting unit P2 emitting light of a second color, and two light emitting units, i.e., a third light emitting unit P3 and fourth light emitting unit P4 emitting light of a third color, each of the four light emitting units may include a light emitting device, the light emitting device in each light emitting unit is respectively connected with a pixel driving circuit of a corresponding circuit unit, and the light emitting device is configured to emit light with a corresponding brightness in response to a current output by the connected pixel driving circuit.

In an exemplary implementations, the first light emitting unit P1 may be a red light emitting unit (R) that emits red light, the second light emitting unit P2 may be a blue light emitting unit (B) that emits blue light, and the third light emitting unit P3 and the fourth light emitting unit P4 may be green light emitting units (G) that emit green light. The light emitting unit may be in a shape of a rectangle, a rhombus, a pentagon, or a hexagon, and the four light emitting units may be arranged side by side horizontally, side by side vertically, or in a square or a diamond, or the like.

In a possible exemplary implementations, the pixel unit may include three light emitting units, the three light emitting units may be arranged side by side horizontally, side by side vertically, or in a manner like a Chinese character [symbol] or the like, which is not limited in the present disclosure.

FIG. 6 is a schematic diagram of a planar structure of a drive circuit layer in a display substrate according to an exemplary embodiment of the present disclosure. The display substrate adopts a structure (Fanout in AA, FIAA for short) in which data fan-out lines are located in the display region. As shown in FIG. 6, in an exemplary implementations, on a plane parallel to the display substrate, the drive circuit layer of the display region may at least include a first circuit region 110 and a second circuit region 120. The first circuit region 110 is configured to be provided with a plurality of circuit units, a circuit unit may at least include a pixel driving circuit and a data signal line configured to provide a data signal to the pixel driving circuit, and the pixel driving circuit is configured to output a corresponding current to the connected light emitting device. The second circuit region 120 is configured to be provided with a plurality of data connection lines, one end of each of the plurality of data connection lines is correspondingly connected to a plurality of data signal lines in the display region, and the other end of each of the plurality of data connection lines extends to the bonding region and is correspondingly connected to the integrated circuit in the bonding region. Since the bonding region does not need to be provided with fan-shaped oblique lines, a width of a fan-out region can be reduced, and a width of a lower bezel can be effectively reduced.

In an exemplary implementations, the second circuit region 120 may be disposed on a side of the first circuit region 110 in a second direction Y, the second circuit region 120 is close to the bonding region, and the second circuit region 120 may be in a shape of a strip extending along a first direction X, the first direction X intersects the second direction Y. In an exemplary implementations, the first direction X may be an extension direction of a scan signal line, the second direction Y may be an extension direction of a data signal line, and the first direction is perpendicular to the second direction.

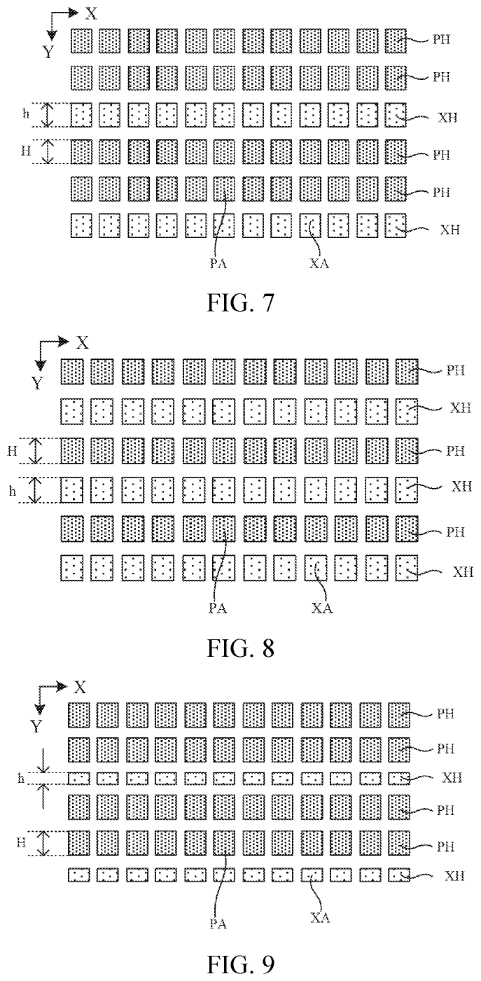

FIG. 7 is a schematic diagram of an arrangement of a first circuit region according to an exemplary embodiment of the present disclosure. As shown in FIG. 7, the first circuit region may include a plurality of circuit units PA that may form a plurality of unit rows PH and a plurality of dummy units XA that may form at least one dummy row XH.

In an exemplary implementations, the unit row PH may include a plurality of circuit units PA sequentially disposed along the first direction X, and the dummy row XH may include a plurality of dummy units XA sequentially disposed along the first direction X.

In an exemplary implementations, two unit rows PH may be provided between dummy rows XH adjacent in the second direction Y, that is, one dummy row XH is inserted for every two unit rows PH along the second direction Y, and two unit rows PH and one dummy row XH are alternately arranged to form a 2 (unit rows) inserted with 1 (dummy row) structure.

In an exemplary implementations, in the second direction Y, the unit row PH has a circuit unit size H in the second direction, and the dummy row XH has a dummy unit size h in the second direction, which may be equal to the circuit unit size H in the second direction.

In an exemplary implementations, a circuit unit PA in a unit row PH may at least include a pixel driving circuit connected to a scan signal line, a light emitting signal line, a data signal line, and an initial signal line, respectively, and the pixel driving circuit is configured to receive a data voltage transmitted by the data signal line and output a corresponding current to the connected light emitting device under control of the scan signal line and the light emitting signal line.

In an exemplary implementations, the dummy unit XA in the dummy row XH may include a dummy pixel circuit that does not output a current that controls the light emitting device to emit light. In an exemplary implementations, the dummy pixel circuit may include a plurality of dummy transistors, a plurality of dummy signal lines and at least one connection line, the at least one connection line is configured to be connected to the first initial signal line or the second initial signal line, the plurality of dummy signal lines are configured to be connected to a bezel power supply lead line of the bezel region, the dummy transistor is configured to exhibit a morphology and structure of a corresponding transistor in the pixel driving circuit, and the bezel power supply lead line of the bezel region is configured to transmit a high voltage power supply signal or a low voltage power supply signal. In an exemplary implementations, an orthographic projection of the at least one light emitting unit on the base substrate at least partially overlaps an orthographic projection of the dummy pixel circuit in the at least one dummy unit on the base substrate.

A display substrate with an existing structure adopts a layout structure in which 1 dummy row is inserted for 4 unit rows, which has the problem of lateral stripes affecting the display effect. Through research, it is found that the problem of lateral stripes is caused by an irrational layout of dummy rows. Since the circuit unit size (Pitch, also called pixel size) in the second direction is about 64 μm, and the size of 4 unit rows is about 256 μm, which is beyond the recognition range of human eyes for differences (about 250 μm), fine lateral stripes can be seen in the display state and the screen-off state, resulting in the problem of lateral stripes. Exemplary embodiments of the present disclosure provide a display substrate, which adopts a layout structure in which 1 dummy row is inserted for 2 unit rows, the circuit unit size in the second direction is about 64 μm, and the size of the 2 unit rows is about 128 μm, which is much smaller than the recognition range of human eyes for differences, and the lateral stripes cannot be seen in the display state and the screen-off state, thus effectively solving the problem of lateral stripes and improving the display quality and display effect.

FIG. 8 is a schematic diagram of an arrangement of another first circuit region according to an exemplary embodiment of the present disclosure. As shown in FIG. 8, the structure of the first circuit region according to the present exemplary embodiment is substantially the same as that of the first circuit region shown in FIG. 7, except that one unit row PH may be provided between adjacent dummy rows XH, that is, along the second direction Y, one dummy row XH is inserted for each unit row PH, and one unit row PH and one dummy row XH are alternately arranged, to form a 1 inserted-by 1 structure.

In an exemplary implementations, structures of the circuit unit PA and the dummy unit XA in the structure shown in FIG. 8 are substantially the same as structures of the circuit unit PA and the dummy unit XA in the structure shown in FIG. 7.

In an exemplary implementations, in the second direction Y, the unit row PH has a circuit unit size H in the second direction, and the dummy row XH has a dummy unit size h in the second direction, which may be equal to the circuit unit size H in the second direction.

Exemplary embodiments of the present disclosure provides a display substrate, which adopts a layout structure in which 1 dummy row is inserted for 1 unit row, the circuit unit size in the second direction is about 64 μm, and the size of 1 unit row is about 64 μm, which minimizes the spacing (cycle period) between adjacent dummy rows, maximizes the elimination of lateral stripes, and effectively solves the problem of lateral stripes, and improves the display quality and display effect.

FIG. 9 is a schematic diagram of an arrangement of yet another first circuit region according to an exemplary embodiment of the present disclosure. As shown in FIG. 9, the structure of the first circuit region according to the present exemplary embodiment is substantially the same as that of the first circuit region shown in FIG. 7, except that the dummy row XH has a dummy unit size h in the second direction, which is smaller than the circuit unit size H in the second direction.

In an exemplary implementations, the dummy unit size h in the second direction may be about 30% to 60% of the circuit unit size H in the second direction, that is, the dummy row XH size in the second direction in the structure shown in FIG. 9 is about half of the dummy row XH size in the second direction in the structure shown in FIG. 7, forming a 2 (unit rows) inserted with half (half dummy row) structure.

In an exemplary implementations, the structure of the circuit unit PA in the structure shown in FIG. 9 is substantially the same as the structure of the circuit unit PA in the structure shown in FIG. 7, and the dummy unit XA in the structure shown in FIG. 9 may only include part of the structure of the dummy pixel circuit, thereby decreasing the size of the dummy row XH in the second direction, allowing more space to set up the circuit unit and improving the resolution of the display region.

Exemplary embodiments of the present disclosure provide a display substrate, which adopts a layout structure in which 2 unit rows are inserted with half a dummy row, which can not only reduce the spacing (cycle period) between adjacent dummy rows, effectively solve the problem of lateral stripes, improve the display quality and display effect, but also improve the resolution of the display region.

FIG. 10 is a schematic diagram of an arrangement of still yet another first circuit region according to an exemplary embodiment of the present disclosure. As shown in FIG. 10, the structure of the first circuit region according to the present exemplary embodiment is substantially the same as that of the first circuit region shown in FIG. 8, except that the dummy row XH has a dummy unit size h in the second direction, which is smaller than the circuit unit size H in the second direction.

In an exemplary implementations, the dummy unit size h in the second direction may be about 30% to 60% of the circuit unit size H in the second direction, that is, the dummy row XH size in the second direction in the structure shown in FIG. 10 is about half of the dummy row XH size in the second direction in the structure shown in FIG. 8, forming a 1 inserted with half structure.

In an exemplary implementations, the structure of the circuit unit PA in the structure shown in FIG. 10 is substantially the same as the structure of the circuit unit PA in the structure shown in FIG. 8, and the dummy unit XA in the structure shown in FIG. 10 may include only part of the structure of the dummy pixel circuit, thereby decreasing the size of the dummy row XH in the second direction, allowing more space to set up the circuit unit and improving the resolution of the display region.

Exemplary embodiments of the present disclosure provide a display substrate, which adopts a layout structure in which 1 unit row is inserted with half a dummy row, which can not only minimize the spacing (cycle period) between adjacent dummy rows, effectively solve the problem of lateral stripes, improve the display quality and the display effect, but also maximize the resolution of the display region.

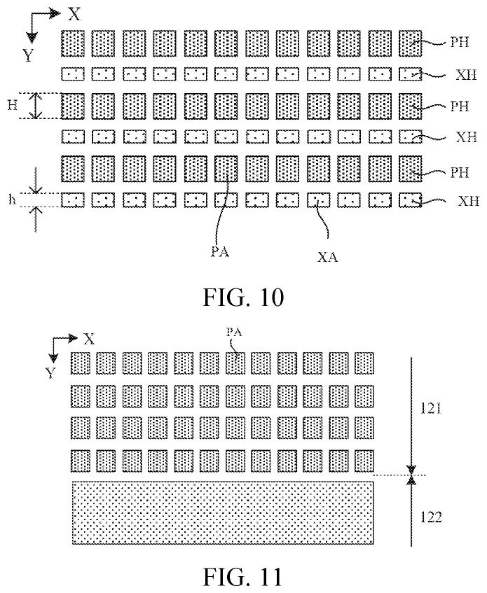

FIG. 11 is a schematic diagram of a planar structure of a second circuit region according to an exemplary embodiment of the present disclosure. As shown in FIG. 11, the second circuit region may include a compression circuit region 121, and a connection line region 122 which may be disposed at a side of the compression circuit region 121 away from the first circuit region. The compression circuit region 121 may include a plurality of circuit units PA which may form a plurality of unit rows, and the connection line region 122 may include a plurality of data connection lines.

In an exemplary implementations, the compression circuit region 121 may be provided with a plurality of circuit units PA in a compact longitudinal compression manner, and a space obtained by compression serves as a setting space of data connection lines. In an exemplary implementations, respective ends at a side of a plurality of data connection lines are correspondingly connected with a plurality of data signal lines in the second circuit region, and the respective other ends of the plurality of data connection lines are correspondingly connected with an integrated circuit after extending to a bonding region. Since the bonding region does not need to be provided with fan-shaped oblique lines, a width of a fan-out region is reduced, and a width of a lower bezel is effectively reduced.

In an exemplary implementations, the second circuit region is provided with circuit units in a compact compression manner, in order to maintain the consistency of pixel driving circuits in the display region, the first circuit region is also provided with circuit units in a same compact compression manner as the second circuit region, and a plurality of above-mentioned dummy rows are provided in the space obtained by compression.

Exemplary embodiments of the present disclosure provide a display substrate including a drive structure layer disposed on a base substrate and a light emitting structure layer disposed on a side of the drive structure layer away from the base substrate. The light emitting structure layer includes a plurality of light emitting units, the drive structure layer includes a plurality of unit rows and at least two dummy rows, a unit row includes a plurality of circuit units sequentially arranged along a first direction, a dummy row includes a plurality of dummy units sequentially arranged along the first direction, the plurality of unit rows and the at least two dummy rows are sequentially provided along a second direction, the first direction and the second direction intersect. A circuit unit includes a pixel driving circuit, a dummy unit includes a dummy pixel circuit, and the pixel driving circuit is configured to drive a corresponding light emitting unit. An orthographic projection of at least one light emitting unit on the base substrate at least partially overlaps an orthographic projection of the dummy pixel circuit on the base substrate. At least one dummy row is provided with a first connection line extending along the first direction, the first connection line is connected with a first initial signal line extending along the second direction to form a mesh structure for transmitting a first initial signal; and/or, at least another dummy row is provided with a second connection line extending along the first direction, the second connection line is connected with a second initial signal line extending along the second direction, to form a mesh structure for transmitting a second initial signal.

In an exemplary implementations, in a plane perpendicular to the base substrate, the drive structure layer may include a semiconductor layer, a first conductive layer, a second conductive layer, and a third conductive layer provided sequentially on the base substrate. Initial signal lines forming a mesh structure may include any one or more of the following: the first connection line is provided in at least one of the semiconductor layer, the first conductive layer, and the second conductive layer, the second connection line is provided in at least one of the semiconductor layer, the first conductive layer, and the second conductive layer, and the first initial signal line and the second initial signal line are provided in the third conductive layer. For example, the first connection line and the second connection line may both be provided in the semiconductor layer. For another example, the first connection line and the second connection line may both be disposed in the first conductive layer. For yet another example, both the first connection line and the second connection line may be provided in the second conductive layer. For yet another example, the first connection line may be provided in the semiconductor layer, and the second connection line may be provided in the first conductive layer, or the first connection line may be provided in the first conductive layer, and the second connection line may be provided in the semiconductor layer. For yet another example, the first connection line may be provided in the semiconductor layer, and the second connection line may be provided in the second conductive layer, or the first connection line may be provided in the second conductive layer, and the second connection line may be provided in the semiconductor layer. For yet another example, the first connection line may be provided in the first conductive layer, and the second connection line may be provided in the second conductive layer, or the first connection line may be provided in the second conductive layer, and the second connection line may be provided in the first conductive layer.

In an exemplary implementations, at least one circuit unit includes a pixel driving circuit which may include a storage capacitor and a plurality of transistors. The semiconductor layer may further include active layers of the plurality of transistors, the first conductive layer may further include gate electrodes of the plurality of transistors and a first electrode plate of the storage capacitor, the second conductive layer may further include a second electrode plate of the storage capacitor, and the third conductive layer may further include first electrodes and second electrodes of the plurality of transistors.

In an exemplary implementations, the drive structure layer may further include a fourth conductive layer which may at least include a data signal line and a first power supply line.

In an exemplary implementations, the drive structure layer may further include a first insulating layer, a second insulating layer, a third insulating layer, a fourth insulating layer, and a first planarization layer, the first insulating layer may be disposed between the base substrate and the semiconductor layer, the second insulating layer may be disposed between the semiconductor layer and the first conductive layer, the third insulating layer may be disposed between the first conductive layer and the second conductive layer, the fourth insulating layer may be disposed between the second conductive layer and the third conductive layer, and the first planarization layer may be disposed between the third conductive layer and the fourth conductive layer.

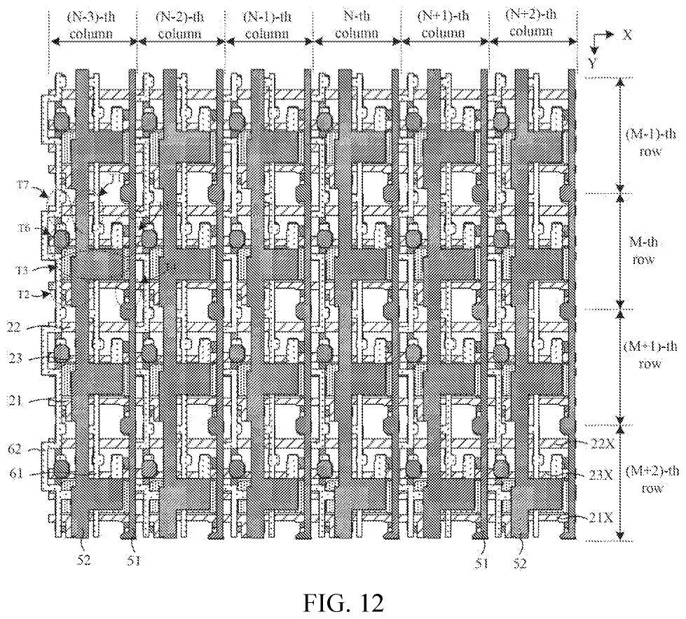

FIG. 12 is a schematic diagram of a structure of a first circuit region according to an exemplary embodiment of the present disclosure, illustrating a planar structure of two unit rows and two dummy rows in the first circuit region, which forms a 2 inserted with 1 structure. An M-th row and an (M+1)-th row are unit rows, and include six circuit units respectively, and an (M−1)-th row and an (M+2)-th row are dummy rows, and include six dummy units respectively. The circuit unit size of the unit row in the second direction is substantially equal to the dummy unit size of the dummy row in the second direction.

As shown in FIG. 12, in an exemplary implementations, the unit row may at least include a plurality of circuit units sequentially arranged along the first direction X, and at least one circuit unit may include a pixel driving circuit connected to the first scan signal line 21, the second scan signal line 22, the light emitting control line 23, the data signal line 51, the first power supply line 52, the first initial signal line 61 and the second initial signal line 62, respectively. In an exemplary implementations, the first scan signal line 21, the second scan signal line 22, and the light emitting control line 23 may be in a shape of a line extending along the first direction X, and the data signal line 51, the first power supply line 52, the first initial signal line 61, and the second initial signal line 62 may be in a shape of a line extending along the second direction Y. The first scan signal line 21 and the second scan signal line 22 are configured to provide a first scan signal and a second scan signal to the pixel driving circuit. The light emitting control line 23 is configured to provide a light emitting control signal to the pixel driving circuit. The data signal line 51 is configured to provide a data signal to the pixel driving circuit. The first power supply line 52 is configured to provide a first power supply signal to the pixel driving circuit. The first initial signal line 61 and the second initial signal line 62 are configured to provide a first initial signal and a second initial signal to the pixel driving circuit, respectively. The first initial signal may be configured to initialize (reset) the storage capacitor, and the second initial signal may be configured to initialize (reset) a light emitting device row.

In the present disclosure, A extends along a B direction means that A may include a main portion and a secondary portion connected with the main portion, the main portion is a line, a line segment, or a strip-shaped body, the main portion extends along the B direction, and a length of the main portion extends along the B direction is greater than a length of the secondary portion extends along another direction.

In an exemplary implementations, a plurality of transistors in the pixel driving circuit may at least include a first transistor T1, a second transistor T2, a third transistor T3, a fourth transistor T4, a fifth transistor T5, a sixth transistor T6, and a seventh transistor T7. A gate electrode of the first transistor T1 and a gate electrode of the second transistor T2 are connected to the second scan signal line 22, the gate electrode of the second transistor T2 and a gate electrode of the fourth transistor T4 are connected to the first scan signal line 21, and a gate electrode of the fifth transistor T5 and a gate electrode of the sixth transistor T6 are connected to the light emitting control line 23. A first electrode of the first transistor T1 is connected to the first initial signal line 61, a second electrode of the first transistor T1 is connected to a first electrode of the second transistor T2 and a gate electrode of the third transistor T3, a second electrode of the second transistor T2 is connected to a second electrode of the third transistor T3 and a first electrode of the sixth transistor T6, a first electrode of the third transistor T3 is connected to a second electrode of the fourth transistor T4 and a second electrode of the fifth transistor T5, a first electrode of the fourth transistor T4 is connected to the data signal line 51, a first electrode of the fifth transistor T5 is connected to the first power supply line 52, a second electrode of the sixth transistor T6 is connected with a second electrode of the seventh transistor

T7, a first electrode of the seventh transistor T7 is connected to the second initial signal line 62.

In an exemplary implementations, in at least one circuit unit, the first transistor T1, the sixth transistor T6, and the seventh transistor T7 may be disposed on a same side of the third transistor T3 in second direction Y.

In an exemplary implementations, a second electrode of the first transistor T1, a first electrode of the second transistor T2, and a gate electrode of the third transistor T3 are connected to each other to form a second node of the pixel driving circuit, and an orthographic projection of the second node on the base substrate at least partially overlaps an orthographic projection of the first power supply line 52 on the base substrate.

In an exemplary implementations, the second node may be located between the first initial signal line 61 and the second initial signal line 62.

In an exemplary implementations, the orthographic projection of the second node on the base substrate may at least partially overlap an orthographic projection of the light emitting control line 23 on the base substrate.

In an exemplary implementations, the dummy row may at least include a plurality of dummy units sequentially arranged along the first direction X, at least one dummy unit may include a dummy pixel circuit which may include a storage capacitor and a first dummy transistor to a seventh dummy transistor, and the dummy pixel circuit is connected to a first dummy signal line 21X, a second dummy signal line 22X and a dummy light emitting line 23X, respectively. In an exemplary implementations, the first dummy signal line 21X, the second dummy signal line 22X, and the dummy light emitting line 23X may be in a shape of a line extending along the first direction X, and the first dummy signal line 21X, the second dummy signal line 22X, and/or the dummy light emitting line 23X may extend to one side or two sides of the display substrate along the first direction X, and then be connected to a bezel power supply lead line of the bezel region, which is configured to transmit a high-voltage power supply signal or a low voltage power supply signal.

In an exemplary implementations, the positions and structures of the dummy transistors and the storage capacitor in the dummy unit are substantially similar to those of the transistors and the storage capacitor in the circuit unit, except that an active layer of the third dummy transistor may serves as the semiconductor body part, and the active layers of the first dummy transistor, the second dummy transistor, the fourth dummy transistor, the fifth dummy transistor, the sixth dummy transistor, and the seventh dummy transistor lack channel regions.

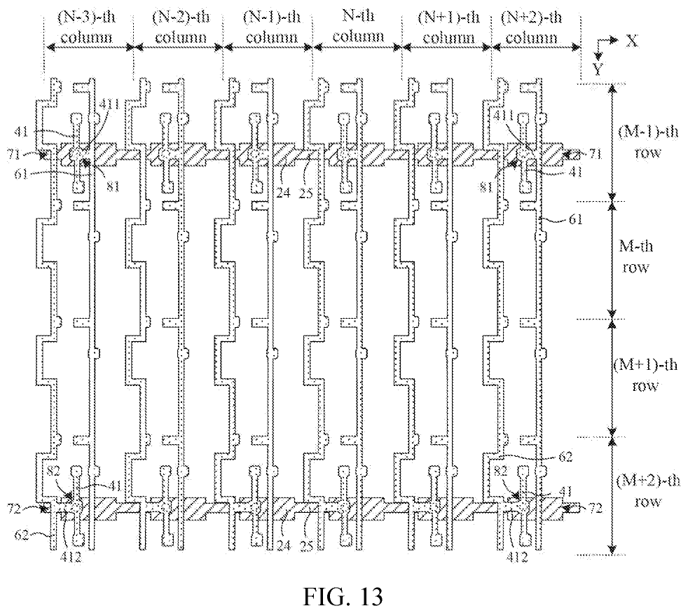

FIG. 13 is a schematic diagram of initial signal lines with a mesh structure according to an exemplary embodiment of the present disclosure, and an arrangement of circuit units and dummy units is the same as an arrangement shown in FIG. 12. As shown in FIG. 13, in an exemplary implementations, the first initial signal line 61 and the second initial signal line 62 may be disposed in each unit column, the first connection line 71 may be disposed in the (M−1)-th row as a dummy row, the first connection line 71 in the (M−1)-th row is connected to the first initial signal line 61, and the second connection line 72 may be disposed in an (M+2)-th row as a dummy row, the second connection line 72 in the (M+2)-th row is connected to the second initial signal line 62, both the first connection line 71 and the second connection line 72 are located in the first conductive layer.

In an exemplary implementations, the first connection line 71 and the second connection line 72 may be in a shape of a line in which a main body portion extends along the first direction X. The first connection line 71 and the second connection line 72 may include first electrode plates 24 and first auxiliary connection lines 25 alternately arranged along the first direction X and connected sequentially, i.e., first electrode plates 24 adjacent in the first direction X are connected to each other through the first auxiliary connection lines 25.

In an exemplary implementations, the first initial signal line 61 may be in a shape of a line in which a main body portion extends along the second direction Y, and in the (M−1)-th row, the first initial signal line 61 may be connected to the first connection line 71 through the first initial electrode 81 to form a first initial signal line with a mesh structure. The second initial signal line 62 may be in a shape of a line in which a main body portion extends in the second direction Y, and in the (M+2)-th row, the second initial signal line 62 may be connected to the second connection line 72 through the second initial electrode 82 to form a second initial signal line with a mesh structure. Thus, a mesh structure for transmitting a first initial signal and a mesh structure for transmitting a second initial signal are formed simultaneously in the display region.

In an exemplary implementations, the first initial signal line 61 may be connected to the first initial electrode 81 which may be connected to the first connection line 71 through a via.

In an exemplary implementations, the first initial electrode 81 may include a first connection electrode 41 and an eleventh connection electrode 411 connected to each other. The first connection electrode 41 and the eleventh connection electrode 411 may be provided in at least one dummy unit in the (M−1)-th row, a first end of the eleventh connection electrode 411 is connected to the first initial signal line 61, a second end of the eleventh connection electrode 411 is connected with the first connection electrode 41, the first connection electrode 41 is connected with the first connection line 71 through a via, thereby realizing a connection between the first connection line 71 extending along the first direction X and the first initial signal line 61 extending along the second direction Y, so that the first initial signal line 61 and the first connection line 71 form a mesh structure for transmitting a first initial signal in the display region, which can not only effectively reduce the resistance of the first initial signal line and reduce the voltage drop of the first initial signal, but also effectively improve the uniformity of the first initial signal in the display substrate, effectively improve the display uniformity and the display effect and the display quality.

In an exemplary implementations, the second initial signal line 62 may be connected to the second initial electrode 82 which may be connected to the second connection line 72 through a via.

In an exemplary implementations, the second initial electrode 82 may include a first connection electrode 41 and a twelfth connection electrode 412 connected to each other. The first connection electrode 41 and the twelfth connection electrode 412 may be provided in at least one dummy unit in the (M+2)-th row, a first end of the twelfth connection electrode 412 is connected to the second initial signal line 62, a second end of the twelfth connection electrode 412 is connected to the first connection electrode 41, and the first connection electrode 41 is connected to the second connection line 72 through a via, thereby realizing a connection between the second connection line 72 extending along the first direction X and the second initial signal line 62 extending along the second direction Y, so that the second initial signal line 62 and the second connection line 72 form a mesh structure for transmitting a second initial signal in the display region, which can not only effectively reduce the resistance of the second initial signal line and reduce the voltage drop of the second initial signal, but also effectively improve the uniformity of the second initial signal in the display substrate, effectively improve the display uniformity and the display effect and the display quality.

In an exemplary implementations, the first initial electrode 81 of the dummy unit in an N-th column is connected to the first initial signal line 61 in the N-th column, and the second initial electrode 82 of the dummy unit in the N-th column is connected to the second initial signal line 62 in the N-th column.

In an exemplary implementations, the first electrode plate 24 and the first auxiliary connection line 25 may be arranged in a same layer, i.e. the first conductive layer, and are synchronously formed through a same patterning process, and are of an interconnected integral structure. The first initial signal line 61, the first connection electrode 41, and the eleventh connection electrode 411 may be arranged in a same layer, i.e. the third conductive layer, and are synchronously formed through a same patterning process, and are of an interconnected integral structure. The second initial signal line 62, the first connection electrode 41, and the twelfth connection electrode 412 may be arranged in a same layer, i.e. the third conductive layer, and are synchronously formed through a same patterning process, and are of an interconnected integral structure.

Exemplary description is made below through a manufacturing process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

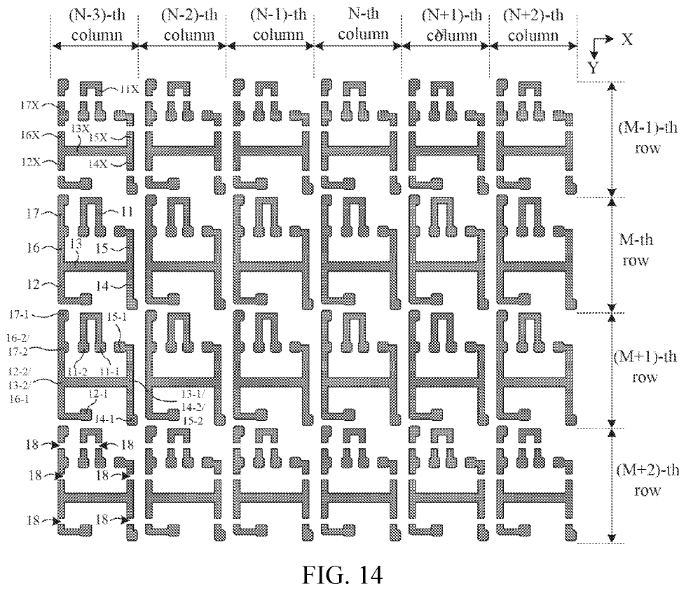

In an exemplary implementations, taking two unit rows and two dummy rows in the first circuit region as an example, the preparation process of the display substrate may include the following operations.
(11) A pattern of a semiconductor layer is formed. In an exemplary implementation, forming the pattern of the semiconductor layer may include: a first insulating thin film and a semiconductor thin film are sequentially deposited on a base substrate, and the semiconductor thin film is patterned through a patterning process to form a first insulating layer that covers the base substrate and the semiconductor layer disposed on the first insulating layer, as shown in FIG. 14.

In an exemplary implementations, the semiconductor layer of the circuit unit may include a first active layer 11 of the first transistor T1 to a seventh active layer 17 of the seventh transistor T7, and the second active layer 12 to the seventh active layer 17 are of an interconnected integral structure, and the first active layer 11 may be provided separately.

In an exemplary implementations, the first active layer 11, the fifth active layer 15, the sixth active layer 16, and the seventh active layer 17 may be located on a side of the third active layer 13 of the present circuit unit in an opposite direction of the second direction Y, and the second active layer 12 and the fourth active layer 14 may be located on a side of the third active layer 13 of the present circuit unit in the second direction Y.

In an exemplary implementations, the first active layer 11 may be in a shape of an “n”, the second active layer 12 may be in a shape of an “L”, the third active layer 13 may be in a shape of a straight line extending along the first direction X, and the fourth active layer 14, the fifth active layer 15, the sixth active layer 16, and the seventh active layer 17 may be in a shape of an “I”. In the present disclosure, by providing a third active layer (an active layer of a drive transistor) in a shape of a straight line extends in the first direction X, the aspect ratio (W/L) of the drive transistor can be better controlled, and the uniformity of the plurality of drive transistors on the display substrate can be improved.

In an exemplary implementations, an active layer of each transistor may include a first region, a second region, and a channel region located between the first region and the second region. In an exemplary embodiment, the first region 13-1 of the third active layer may simultaneously serve as the second region 14-2 of the fourth active layer and the second region 15-2 of the fifth active layer; the second region 13-2 of the third active layer may simultaneously serve as the second region 12-2 of the second active layer and the first region 16-1 of the sixth active layer; the second region 16-2 of the sixth active layer may serve as the second region 17-2 of the seventh active layer; the first region 11-1 of the first active layer, the second region 11-2 of the first active layer, the first region 12-1 of the second active layer, the first region 14-1 of the fourth active layer, the first region 15-1 of the fifth active layer and the first region 17-1 of the seventh active layer may be individually provided.

In an exemplary implementations, the semiconductor layer of the dummy unit may at least include a first dummy active layer 11X of the first dummy transistor to a seventh dummy active layer 17X of the seventh dummy transistor, and the positions and shapes of the first dummy active layer 11X to the seventh dummy active layer 17X in the dummy unit are substantially the same as the positions and shapes of the first active layer 11 to the seventh active layer 17 in the circuit unit, respectively, except that the third dummy active layer may serve as the semiconductor body part 13X, and the first dummy active layer 11X, the second dummy active layer 12X, and the fourth dummy active layer 14X to the seventh dummy active layer 17X are each provided with a fracture 18.

In an exemplary implementations, the position and shape of the third dummy active layer in the dummy unit are substantially the same as the position and shape of the third active layer of the circuit unit in the circuit unit. Except for the third dummy active layer, the fractures 18 of the other dummy active layers are respectively disposed between the first region and the second region of the corresponding dummy active layer, so that the dummy active layer has only the first region and the second region, but lacks a channel region and cannot perform signal transmission, thus forming the first dummy transistor to the seventh dummy transistor.

In an exemplary implementations, since the second dummy active layer 12, the fourth dummy active layer 14, the fifth dummy active layer 15, and the sixth dummy active layer 16 are each provided with the fracture 18, the semiconductor body part 13X cannot perform signal transmission. In some possible exemplary implementations, the semiconductor body part 13X may also be provided with a fracture 18, which is not limited in the present disclosure.

In an exemplary implementations, positions of a plurality of fractures 18 may correspond to the positions of a first scan signal line, a second scan signal line, and a light emitting control line subsequently formed, and orthographic projections of the fractures 18 on the base substrate overlap at least partially orthographic projections of the first scan signal line, the second scan signal line, and the light emitting control line on the base substrate.

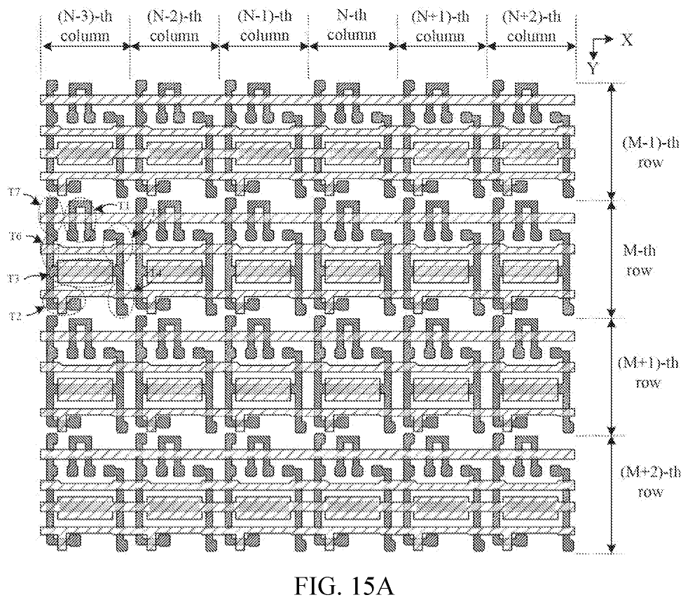

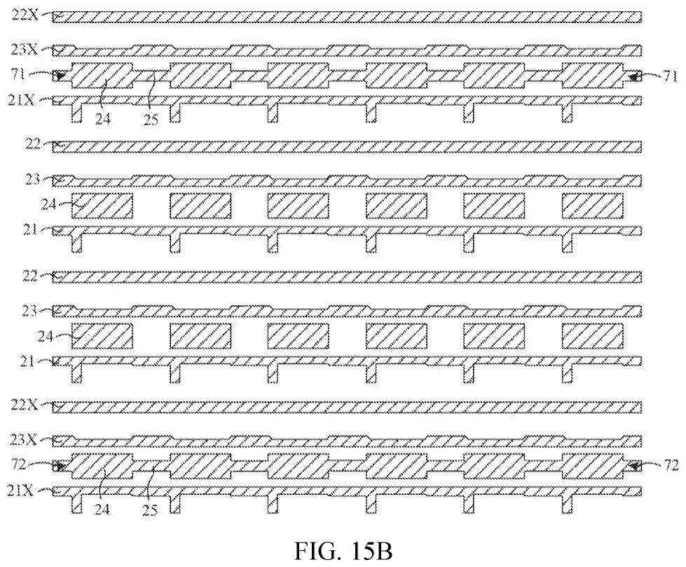

The present disclosure, by providing a fracture in the dummy unit for breaking the dummy active layer, not only enables the dummy active layer in the dummy unit and the active layer in the circuit unit to present the same morphology and improves the process uniformity, but also enables a first dummy signal line, a second dummy signal line and a dummy light emitting signal line subsequently formed in the dummy unit to have more flexible connection structure and can be connected to the relevant DC signals more freely. The first dummy signal line, the second dummy signal line and the dummy light emitting signal line may be connected to the bezel power supply lead line in the bezel region, thereby greatly reducing the load of transmitting a power supply signal, which is beneficial to improvement of display uniformity.
(12) A pattern of a first conductive layer is formed. In an exemplary implementation, forming the pattern of the first conductive layer may include: depositing sequentially a second insulating thin film and a first conductive thin film on the base substrate on which the aforementioned patterns are formed, and patterning the first conductive thin film through a patterning process to form a second insulating layer that covers a pattern of the semiconductor layer and form the pattern of the first conductive layer arranged on the second insulating layer, as shown in FIG. 15A and FIG. 15B. FIG. 15B is a schematic planar view of the first conductive layer in FIG. 15A. In an exemplary implementation, the first conductive layer may be called a first gate metal (GATE1) layer.

In an exemplary implementations, a pattern of a first conductive layer of a circuit unit may at least include a first scan signal line 21, a second scan signal line 22, a light emitting control line 23, and a first electrode plate 24 of a storage capacitor.

In an exemplary implementations, the first electrode plate 24 of the storage capacitor may be in a shape of a rectangle, and chamfers may be provided at corners of the rectangle. An orthographic projection of the first electrode plate 24 on the base substrate is at least partially overlapped with an orthographic projection of a third active layer of a third transistor T3 on the base substrate. In an exemplary implementation, the first electrode plate 24 may serve as an electrode plate of the storage capacitor and a gate electrode of the third transistor T3 simultaneously.

In an exemplary implementations, the first scan signal line 21, the second scan signal line 22, and the light emitting control line 23 may be in a line shape of which a main body portion extends along a first direction X. The first scan signal line 21 may be located at a side of the first electrode plate 24 of the present circuit unit in the second direction Y, the light emitting control line 23 may be located at a side of the first electrode plate 24 of the present circuit unit in an opposite direction of the second direction Y, and the second scan signal line 22 may be located at a side of the light emitting control line 23 of the present circuit unit away from the first electrode plate 24.

In an exemplary implementations, a first scan signal line 21 of a circuit unit is provided with a gate electrode block protruding toward a direction away from the first electrode plate 24, and a region in which the first scan signal line 21 and the gate electrode block are overlapped with a second active layer serves as a gate electrode of a second transistor T2 to form a second transistor T2 with a double-gate structure.

In an exemplary implementations, a region in which a first scan signal line 21 is overlapped with a fourth active layer serves as a gate electrode of a fourth transistor T4. A region in which a second scan signal line 22 is overlapped with a first active layer serves as a gate electrode of a first transistor T1 with a double-gate structure, and a region in which the second scan signal line 22 is overlapped with a seventh active layer serves as a gate electrode of a seventh transistor T7. A region in which a light emitting control line 23 is overlapped with a fifth active layer serves as a gate electrode of a fifth transistor T5, and a region in which the light emitting control line 23 is overlapped with a sixth active layer serves as a gate electrode of a sixth transistor T6.

In an exemplary implementations, a pattern of a first conductive layer of a dummy unit may at least include a first dummy signal line 21X, a second dummy signal line 22X, a dummy light emitting signal line 23X, a first electrode plate 24, and a first auxiliary connection line 25, and the positions and shapes of the first dummy signal line 21X, the second dummy signal line 22X, the dummy light emitting signal line 23X, and the first electrode plate 24 in the dummy unit are substantially the same as the positions and shapes of the first scan signal line 21, the second scan signal line 22, the light emitting control line 23, and the first electrode plate 24 of the storage capacitor in the circuit unit, respectively, except that first electrode plates 24 adjacent in the first direction X are connected to each other through the first auxiliary connection line 25. Herein, the first electrode plate of the dummy unit is only a designation borrowed from the structure in the circuit unit, and the first electrode plate is essentially a block member, which is not limited to one electrode plate of the storage capacitor.

In an exemplary implementations, an orthographic projection of the fractures on the dummy active layer on the base substrate overlaps at least partially an orthographic projection of the first dummy signal line 21X, the second dummy signal line 22X, or the dummy light emitting signal line 23X on the base substrate, respectively.

In an exemplary implementations, an orthographic projection of the fractures 18 on the dummy active layer on the base substrate may be within a range of an orthographic projection of the first dummy signal line 21X, the second dummy signal line 22X, or the dummy light emitting signal line 23X on the base substrate, respectively.

In an exemplary implementations, the first auxiliary connection line 25 may be in a shape of a strip in which a main body portion extends along the first direction X, and may be provided on a side of the first electrode plate 24 in the first direction X or in an opposite direction of the first direction X, that is, the first auxiliary connection line 25 may be located between first electrode plates 24 adjacent in the first direction X. A first end of the first auxiliary connection line 25 is connected with the first electrode plate 24 of the present dummy unit, and a second end of the first auxiliary connection line 25, after extending along the first direction X or along an opposite direction of the first direction X, is connected with the first electrode plate 24 of an adjacent dummy unit. The first auxiliary connection line 25 is configured, such that first electrode plates of adjacent dummy units on a dummy row are connected with each other, and first electrode plates of a plurality of dummy units in a dummy row form an interconnected integral structure. The first electrode plate with an integral structure may be reused as the first connection line 71 or the second connection line 72.

In an exemplary implementations, in a plurality of dummy rows in the display region, the first connection line 71 may be disposed in a part of the dummy lines, and a second connection line 72 may be disposed in another part of the dummy lines, the first connection line 71 is configured to be connected with a first initial signal line formed subsequently, and the second connection line 72 is configured to be connected with a first initial signal line formed subsequently. For example, the first connection line 71 and the second connection line 72 may be respectively disposed in two dummy rows adjacent in the second direction Y such that the first connection line 71 and the second connection line 72 are alternately arranged in the second direction Y.

In an exemplary implementations, in the (M−1)-th row as a dummy row, the first electrode plate with an integral structure may be reused as the first connection line 71, which may be in a shape of a strip in which a main body portion extends along the first direction X, and in the (M+2)-th row as a dummy row, the first electrode plate with an integral structure may be reused as the second connection line 72 which may be in a shape of a strip in which a main body portion extends along the first direction X.

In an exemplary implementations, the first scan signal line 21, the second scan signal line 22 and the light emitting control line 23 in the M-th and (M+1)-th rows, which are circuit rows, are respectively connected to a gate drive circuit of the bezel region, and are provided with corresponding scan signals and light emitting control signals provided by the gate drive circuit. The first dummy signal line 21X, the second dummy signal line 22X, and the dummy light emitting signal line 23X in the (M−1)-th and (M+2)-th rows which are dummy rows may be configured as constant voltage signal lines to be connected to a bezel power supply lead line of the bezel region. In an exemplary implementations, the bezel power supply lead line may be configured to transmit a high voltage power supply signal (VDD) or may be configured to transmit a low voltage power supply signal (VSS). For example, the first dummy signal line 21X, the second dummy signal line 22X, and the dummy light emitting signal line 23X may be connected to each other through a connection line in the bezel region and then connected to the bezel power supply lead line of the bezel region. The present disclosure may greatly reduce a load of transmitting a high voltage power supply signal or a low voltage power supply signal by connecting a signal line of a dummy row with a bezel power supply lead line in a bezel region, which is beneficial to improvement of display uniformity.

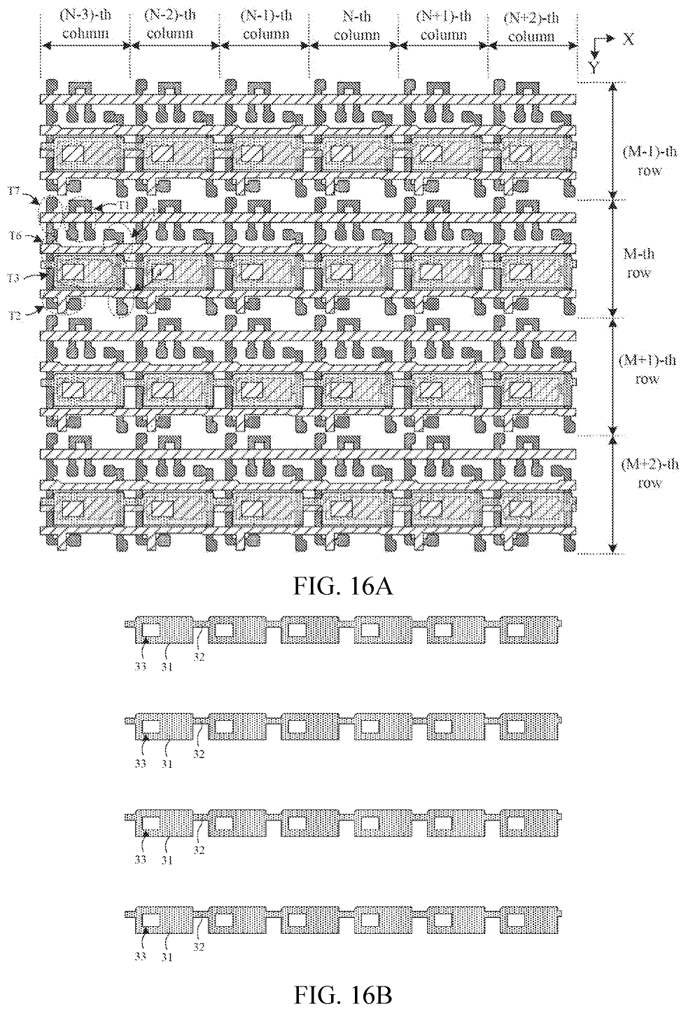

In an exemplary implementations, after the pattern of the first conductive layer is formed, the semiconductor layer may be subjected to a conductive treatment by using the first conductive layer as a shelter. The semiconductor layer in a region, which is sheltered by the first conductive layer, forms channel regions of the first transistor T1 to the seventh transistor T7, and the semiconductor layer in a region, which is not sheltered by the first conductive layer, is made to be conductive, that is, first regions and second regions of the first active layer to the seventh active layer are all made to be conductive.
(13) A pattern of a second conductive layer is formed. In an exemplary implementation, forming the pattern of the second conductive layer may include: a third insulating thin film and a second conductive thin film are sequentially deposited on the base substrate on which the aforementioned patterns are formed, and the second conductive thin film is patterned through a patterning process to form a third insulating layer that covers the first conductive layer and the pattern of the second conductive layer arranged on the third insulating layer, as shown in FIG. 16A and FIG. 16B. FIG. 16B is a schematic planar view of the second conductive layer in FIG. 16A. In an exemplary implementation, the second conductive layer may be called a second gate metal (GATE 2) layer.

In an exemplary implementations, the pattern of the second conductive layer of the circuit unit may at least include a second electrode plate 31 of the storage capacitor and a second auxiliary connection line 32.

In an exemplary implementations, a contour shape of the second electrode plate 31 of the storage capacitor may be a shape of a rectangle, corners of the rectangle may be provided with chamfers, an orthographic projection of the second electrode plate 31 on the base substrate is at least overlapped with an orthographic projection of the first electrode plate 24 on the base substrate, the second electrode plate 31 serves as the other electrode plate of the storage capacitor, and the first electrode plate 24 and the second electrode plate 31 form a storage capacitor of a pixel driving circuit.

In an exemplary implementations, the second auxiliary connection line 32 may be provided on a side of the second electrode plate 31 in the first direction X or in an opposite direction of the first direction X, a first end of the second auxiliary connection line 32 is connected with the second electrode plate 31 of the present circuit unit, and a second end of the second auxiliary connection line 32 extends along the first direction X or the opposite direction of the first direction X and then is connected with a second electrode plate 31 of an adjacent circuit unit, the second auxiliary connection line 32 is configured to enable second electrode plates of adjacent circuit units in a unit row to be connected with each other. In an exemplary implementations, the second auxiliary connection line 32 enables second electrode plates of a plurality of circuit units in a unit row to form an integral structure connected with each other, the second electrode plates with the integral structure may be reused as a power supply signal line, which ensures that a plurality of second electrode plates in a unit row have a same potential, which is beneficial to improving uniformity of a panel, avoids poor display of the display substrate and ensures a display effect of the display substrate.

In an exemplary implementations, the second electrode plate 31 is provided with an opening 33, and the opening 33 may be located in a middle of the second electrode plate 31. The opening 33 may be rectangular, so that the second electrode plate 31 forms an annular structure. The opening 33 exposes the third insulating layer covering the first electrode plate 24, and an orthographic projection of the first electrode plate 24 on the base substrate contains an orthographic projection of the opening 33 on the base substrate. In an exemplary implementations, the opening 33 is configured to accommodate a first via formed subsequently, and the first via is located in the opening 33 and exposes the first electrode plate 24, so that a second electrode of the first transistor T1 formed subsequently is connected with the first electrode plate 24.

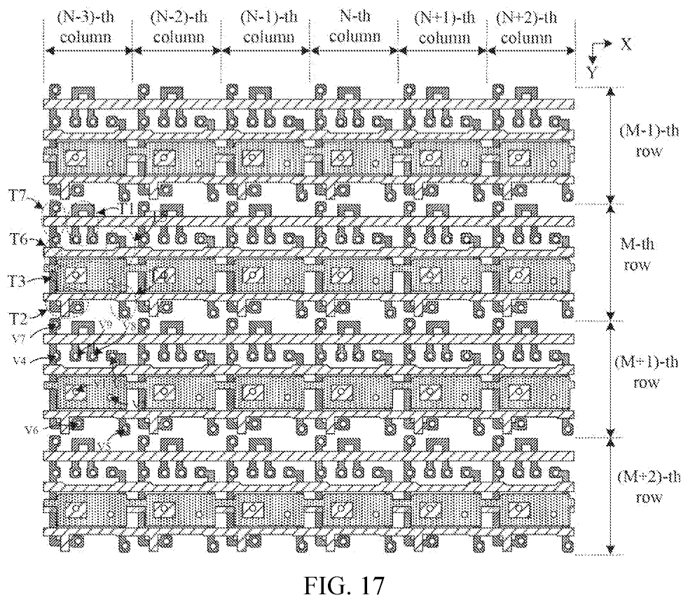

In an exemplary implementations, the pattern of the second conductive layer of the dummy unit and the pattern of the second conductive layer of the circuit unit may be substantially the same, which will not be repeated here.
(14) A pattern of a fourth insulating layer is formed. In an exemplary implementation, forming the pattern of the fourth insulating layer may include: depositing a fourth insulating thin film on the base substrate on which the aforementioned patterns are formed, and patterning the fourth insulating thin film by a patterning process, to form a fourth insulating layer covering the second conductive layer, wherein a plurality of vias are provided on the fourth insulating layer, as shown in FIG. 17.

In an exemplary implementations, the plurality of vias of the circuit unit may at least include a first via V1, a second via V2, a third via V3, a fourth via V4, a fifth via V5, a sixth via V6, a seventh via V7, an eighth via V8, and a ninth via V9.

In an exemplary implementations, an orthographic projection of the first via V1 on the base substrate may be located within a range of an orthographic projection of the opening 33 of the second electrode plate 31 on the base substrate, the fourth insulating layer and the third insulating layer in the first via V1 are etched away to expose a surface of the first electrode plate 24, and the first via V1 is configured such that a second electrode of a first transistor T1 subsequently formed is connected with the first electrode plate 24 through the via.

In an exemplary implementations, an orthographic projection of the second via V2 on the base substrate may be located within a range of an orthographic projection of the second electrode plate 31 on the base substrate, the fourth insulating layer in the second via V2 is etched away to expose a surface of the second electrode plate 31, and the second via V2 is configured such that a first electrode of a fifth transistor subsequently formed is connected with the second electrode plate 31 through the via. In an exemplary implementations, the second via V2 may be multiple, and the plurality of second vias V2 may be arranged sequentially along the second direction Y, thereby increasing connection reliability.

In an exemplary implementations, an orthographic projection of the third via V3 on the base substrate may be located within a range of an orthographic projection of the first region of the fifth active layer on the base substrate. The fourth insulating layer, the third insulating layer, and the second insulating layer in the third via V3 are etched away to expose a surface of the first region of the fifth active layer, and the third via V3 is configured such that a first electrode of a fifth transistor subsequently formed is connected with the first region of the fifth active layer through the via.

In an exemplary implementation, an orthographic projection of the fourth via V4 on the base substrate is located within a range of an orthographic projection of a second region of the sixth active layer (which is also a second region of the seventh active layer) on the base substrate, the fourth insulating layer, the third insulating layer, and the second insulating layer within the fourth via V4 are etched away to expose a surface of the second region of the sixth active layer, and the fourth via V4 is configured such that a second electrode of the sixth transistor T6 (which is also a second electrode of the seventh transistor T7) formed subsequently is connected with the second region of the sixth active layer through the fourth via.

In an exemplary implementations, an orthographic projection of the fifth via V5 on the base substrate may be located within a range of an orthographic projection of the first region of the fourth active layer on the base substrate. The fourth insulating layer, the third insulating layer, and the second insulating layer in the fifth via V5 are etched away to expose a surface of the first region of the fourth active layer, and the fifth via V5 is configured such that a first electrode of a fourth transistor subsequently formed is connected with the first region of the fourth active layer through the fifth via.

In an exemplary implementations, an orthographic projection of the sixth via V6 on the base substrate may be within a range of an orthographic projection of the first region of the second active layer on the base substrate, the fourth insulating layer, the third insulating layer and the second insulating layer within the sixth via V6 are etched away to expose a surface of the first region of the second active layer, the sixth via V6 is configured such that a first electrode of a second transistor T2 formed subsequently is connected with the first region of the second active layer through the sixth via.

In an exemplary implementations, an orthographic projection of the seventh via V7 on the base substrate may be within a range of an orthographic projection of the first region of the seventh active layer on the base substrate, the fourth insulating layer, the third insulating layer and the second insulating layer within the seventh via V7 are etched away to expose a surface of the first region of the seventh active layer, the seventh via V7 is configured such that a second initial signal line formed subsequently is connected with the first region of the seventh active layer through the seventh via.

In an exemplary implementations, an orthographic projection of the eighth via V8 on the base substrate may be within a range of an orthographic projection of the first region of the first active layer on the base substrate, the fourth insulating layer, the third insulating layer and the second insulating layer within the eighth via V8 are etched away to expose a surface of the first region of the first active layer, the eighth via V8 is configured such that a first initial signal line formed subsequently is connected with the first region of the first active layer through the eighth via.

In an exemplary implementations, an orthographic projection of the ninth via V9 on the base substrate may be within a range of an orthographic projection of the second region of the first active layer on the base substrate, the fourth insulating layer, the third insulating layer and the second insulating layer within the ninth via V9 are etched away to expose a surface of the second region of the first active layer, the ninth via V9 is configured such that a second electrode of the first transistor T1 formed subsequently is connected with the second region of the first active layer through the ninth via.

In an exemplary implementations, the third via V3, the fourth via V4, the eighth via V8, and the ninth via V9 may be located on a straight line extending along the first direction X, i.e., the four vias are designed side by side in a row direction. In the present disclosure, by arranging a plurality of vias in a side-by-side design along the first direction X, wiring space can be effectively utilized, the uniformity of via etching can be improved, and the transmittance of the display substrate can be improved.

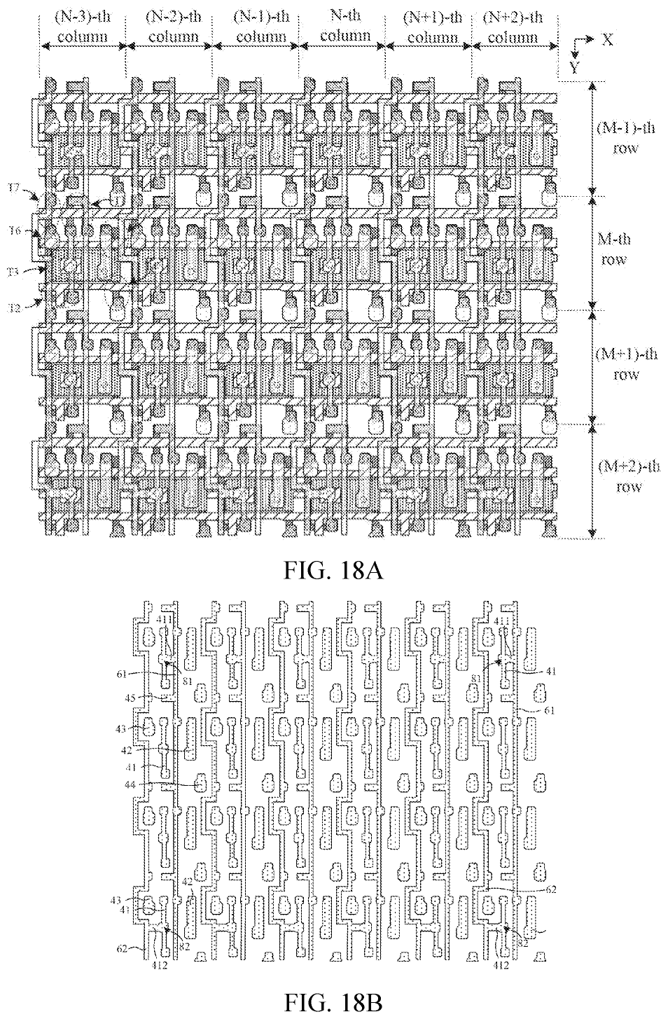

In an exemplary implementations, patterns of a plurality of vias of the dummy unit may be substantially the same as patterns of a plurality of vias of the circuit unit, the first via V1 exposes a surface of the first electrode plate 24, the second via V2 exposes a surface of the second electrode plate 31, the third via V3 exposes a surface of the first region of the fifth dummy active layer, the fourth via V4 exposes a surface of the second region of the sixth dummy active layer, the fifth via V5 exposes a surface of the first region of the fourth dummy active layer, the sixth via V6 exposes a surface of the first region of the second dummy active layer, the seventh via V7 exposes a surface of the first region of the seventh dummy active layer, the eighth via V8 exposes a surface of the first region of the first dummy active layer, and the ninth via V9 exposes a surface of the second region of the first dummy active layer.
(15) Forming a pattern of a third conductive layer. In an exemplary implementation, forming the third conductive layer may include: depositing a third conductive thin film on the base substrate on which the aforementioned patterns are formed, and patterning the third conductive thin film by a patterning process to form the third conductive layer arranged on the fourth insulating layer, as shown in FIG. 18A and FIG. 18B, and FIG. 18B is a schematic planar diagram of the third conductive layer in FIG. 18A. In an exemplary implementations, the third conductive layer may be referred to as a first source-drain metal (SD1) layer.

In an exemplary implementations, the third conductive layer of the circuit unit may at least include a first connection electrode 41, a second connection electrode 42, a third connection electrode 43, a fourth connection electrode 44, a first shielding electrode 45, a first initial signal line 61, and a second initial signal line 62.

In an exemplary implementations, the first initial signal line 61 may be in a shape of a straight line or a polyline in which a main body portion extends along the second direction Y, and the first initial signal line 61 may be connected to the first region of the first active layer through the eighth via V8, achieving that the first initial signal line 61 inputs the first initial signal to a first electrode of the first transistor T1.

In an exemplary implementations, the second initial signal line 62 may be in a shape of a straight line or a polyline in which a main body portion extends along the second direction Y, and the second initial signal line 62 may be connected to the first region of the seventh active layer through the seventh via V7, achieving that the second initial signal line 62 inputs the second initial signal to a first electrode of the seventh transistor T7.

In an exemplary implementations, the first initial signal line 61 may be located at a side of the second initial signal line 62 in the present circuit unit in the first direction X.

In the present disclosure, by providing the first initial signal line 61 and the second initial signal line 62 vertically penetrating through a display region, a first initial signal line and a second initial signal line from a bonding region may be quickly transmitted to the display region, which improves an initialization speed, is more beneficial to improving a refresh rate, and meets a high-frequency requirement. In addition, since the first initial signal line 61 and the second initial signal line 62 are arranged vertically (in the second direction Y), the first initial signal line 61 and the second initial signal line 62 can be directly connected to the first region of the first active layer and the first region of the seventh active layer through vias, respectively, to realize a quick reset.

In an exemplary implementations, the first connection electrode 41 may be in a shape of a strip in which a main body portion extends along the second direction Y, a first end of the first connection electrode 41 is connected to the first region of the second active layer through the sixth via V6, a second end of the first connection electrode 41 is connected to the second region of the first active layer through the ninth via V9, and a middle portion of the first connection electrode 41 between the first end and the second end is connected to the first electrode plate 24 through the first via V1. In an exemplary implementations, the first connection electrode 41 may serve as the second node N2 of the pixel driving circuit, i.e., the first connection electrode 41 simultaneously serves as a second electrode of the first transistor T1 and a first electrode of the second transistor T2, so that the first electrode plate 24 (a gate electrode of the third transistor T3), a second electrode of the first transistor T1 and a first electrode of the second transistor T2 have a same potential.

In an exemplary implementations, an orthographic projection of the first connection electrode 41 (the second node N2) on the base substrate at least partially overlaps an orthographic projection of the light emitting control line 23 on the base substrate, i.e., the light emitting control line 23 extending along the first direction X intersects the first connection electrode 41 extending along the second direction Y, so that a parasitic capacitance is formed between the first connection electrode 41 and the light emitting control line 23. In the present disclosure, the light emitting control line 23 intersects the second node N2, so that a light emitting control signal output by the light emitting control line 23 jumps low at the instant the light emitting control line 23 outputs the light emitting control signal, which can pull down the second node N2, thereby pull down a black state data voltage, and is beneficial to reducing power consumption.

In an exemplary implementations, the first connection electrode 41 (the second node N2) may be located between the first initial signal line 61 and the second initial signal line 62 in the first direction X. By arranging the second node N2 between the first initial signal line 61 and the second initial signal line 62, since the first initial signal line 61 and the second initial signal line 62 are metal traces, the present disclosure not only enables the second node N2 to be separated from a data signal line formed subsequently, but also enables the first initial signal line 61 and the second initial signal line 62 to play a shielding role, which can effectively avoid an influence of a jump voltage of the data signal line on a potential of the second node N2 and improve the working performance of the pixel driving circuit.

In an exemplary implementation, a shape of the second connection electrode 42 may be a strip shape, a main body portion of the second connection electrode 42 extends along the second direction Y to form the strip shape, a first end of the second connection electrode 42 is connected with the second electrode plate 31 through the second via V2, and a second end of the second connection electrode 42 may be connected with the first region of the fifth active layer through the third via V3. In an exemplary implementations, the second connection electrode 42 may serve as the first electrode of the fifth transistor T5, so that the first electrode of the fifth transistor T5 and the second electrode plate 31 have a same potential, and the second connection electrode 42 is configured to be connected with a first power supply line subsequently formed.

In an exemplary implementations, the third connection electrode 43 may be in a shape of a polygon, and the third connection electrode 43 may be connected to the second region of the sixth active layer (also the second region of the seventh active layer) through the fourth via V4. In an exemplary implementations, the fourth connection electrode 44 may serve as a second electrode of the sixth transistor T6 (also a second electrode of the seventh transistor T7), and the third connection electrode 43 is configured to be connected with an anode connection electrode formed subsequently.

In an exemplary implementations, the fourth connection electrode 44 may be in a shape of a polygon, and the fourth connection electrode 44 may be connected to the first region of the fourth active layer through the fifth via V5. In an exemplary implementations, the fourth connection electrode 44 may serve as a first electrode of the fourth transistor T4 and the fourth connection electrode 44 is configured to be connected to the data signal line formed subsequently.

In an exemplary implementations, the first shielding electrode 45 may be disposed at a side of the first initial signal line 61 towards the second initial signal line 62 and be connected to the first initial signal line 61, an orthographic projection of the first shielding electrode 45 on the base substrate overlaps at least partially an orthographic projection of the first active layer between double gates of the first transistor T1 on the base substrate, and the first shielding electrode 45 may shield an active layer node between the double gates of the first transistor T1, to improve the electrical performance of the first transistor T1.

In an exemplary implementations, the first initial signal line 61 and the first shield electrode 45 may be interconnected to be of an integral structure.

In an exemplary implementations, the third conductive layer of the dummy unit may at least include a first connection electrode 41, a second connection electrode 42, a third connection electrode 43, a fourth connection electrode 44, a first shielding electrode 45, a first initial signal line 61, and a second initial signal line 62, positions and shapes of which in the dummy unit are substantially the same as those in the circuit unit, respectively, which will not be repeated here.

In an exemplary implementations, a pattern of a third conductive layer of at least one dummy unit may further include an eleventh connection electrode 411, and a pattern of a third conductive layer of at least another dummy unit may further include a twelfth connection electrode 412, the eleventh connection electrode 411 may be disposed in dummy units of a part of the dummy rows, and the twelfth connection electrode 412 may be disposed in dummy units of another part of the dummy rows.

In an exemplary implementations, the eleventh connection electrode 411 may be in a shape of a rectangle, may be provided in a dummy unit of the (M−1)-th row as a dummy row, a first end of the eleventh connection electrode 411 may be connected to the first initial signal line 61, a second end of the eleventh connection electrode 411 may be connected to the first connection electrode 41, and the first connection electrode 41 and the eleventh connection electrode 411 connected to each other form the first initial electrode 81 according to the present disclosure. Since a plurality of first electrode plates in the (M−1)-th row are connected with each other through the first auxiliary connection lines, and the first electrode plate with an integrated structure is reused as the first connection line 71, it is achieved that the first initial signal line 61 is connected with the first connection line 71 of the (M−1)-th row through the first initial electrode 81, that is, it is achieved that the first initial signal line 61 extending along the second direction Y is connected with the first connection line 71 extending along the first direction X, so that the first initial signal line 61 and the first connection line 71 form a mesh structure for transmitting a first initial signal in the display region, which can not only effectively reduce the resistance of the first initial signal line and reduce the voltage drop of the first initial signal, but also effectively improve the uniformity of the first initial signal in the display substrate, effectively improve the display uniformity and the display effect and the display quality.

In an exemplary implementations, the first connection electrode 41, the eleventh connection electrode 411 and the first initial signal line 61 of the dummy unit in the (M−1)-th row may be of an interconnected integral structure, that is, the first initial electrode 81 and the first initial signal line 61 of the dummy unit in the (M−1)-th row may be of an interconnected integral structure.

In an exemplary implementations, the twelfth connection electrode 412 may be in a shape of a rectangle, may be provided in a dummy unit of the (M+2)-th row as a dummy row, a first end of the twelfth connection electrode 412 may be connected to the second initial signal line 62, a second end of the twelfth connection electrode 412 may be connected to the first connection electrode 41, and the first connection electrode 41 and the twelfth connection electrode 412 connected to each other form the second initial electrode 82 according to the present disclosure. Since a plurality of first electrode plates in the (M+2)-th row are connected to each other through the first auxiliary connection lines, and the first electrode plate with an integral structure are reused as a second connection line 72, it is achieved that the second initial signal line 62 is connected to the second connection line 72 in the (M+2)-th row through the second initial electrode 82, that is, it is achieved that the second initial signal line 62 extending along the second direction Y and the second connection line 72 extending along the first direction X are connected, so that the second initial signal line 62 and the second connection line 72 form a mesh structure for transmitting a second initial signal in the display region, which can not only effectively reduce the resistance of the second initial signal line and reduce the voltage drop of the second initial signal, but also effectively improve the uniformity of the second initial signal in the display substrate, effectively improve the display uniformity and the display effect and the display quality.

In an exemplary implementations, the first connection electrode 41, the twelfth connection electrode 412 and the second initial signal line 62 of the dummy unit in the (M+2)-th row may be of an interconnected integral structure, that is, the second initial electrode 82 and the second initial signal line 62 of the dummy unit in the (M+2)-th row may be of an interconnected integral structure.

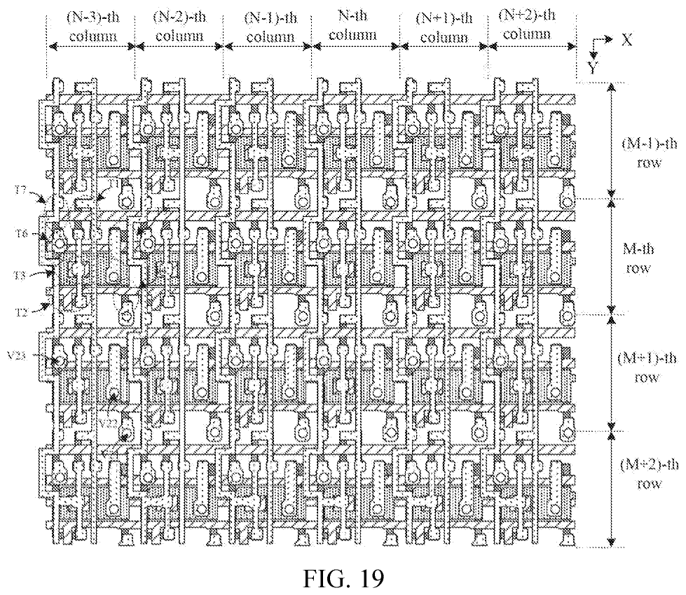

In an exemplary implementations, the first initial electrode 81 of the dummy unit in the N-th column is connected to the first initial signal line 61 in the N-th column, and the second initial electrode 82 of the dummy unit in the N-th column is connected to the second initial signal line 62 in the N-th column.
(16) Forming a pattern of a first planarization layer. In an exemplary implementation, forming the pattern of the first planarization layer may include: first depositing a fifth insulating thin film on the base substrate on which the aforementioned patterns are formed, then coating a first planarization thin film, and patterning the first planarization thin film and the fifth insulating thin film by a patterning process to form a fifth insulating layer that covers the third conductive layer and the first planarization layer arranged on the fifth insulating layer, wherein the first planarization layer and the fifth insulating layer are provided with a plurality of vias, as shown in FIG. 19.

In an exemplary implementations, the plurality of vias of the circuit unit at least include a twenty-first via V21, a twenty-second via V22, and a twenty-third via V23.

In an exemplary implementations, an orthographic projection of the twenty-first via V21 on the base substrate is located within a range of an orthographic projection of a fourth connection electrode 44 on the base substrate, the first planarization layer in the twenty-first via V21 is removed to expose a surface of the fourth connection electrode 44, and the twenty-first via V21 is configured such that a data signal line formed subsequently is connected to the fourth connection electrode 44 through the via.

In an exemplary implementations, an orthographic projection of the twenty-second via V22 on the base substrate may be within a range of an orthographic projection of the second connection electrode 42 on the base substrate, the first planarization layer within the twenty-second via V22 is removed to expose a surface of the second connection electrode 42, and the twenty-second via V22 is configured such that a power supply connection electrode formed subsequently is connected with the second connection electrode 42 through the via.

In an exemplary implementations, an orthographic projection of the twenty-third via V23 on the base substrate may be within a range of an orthographic projection of the third connection electrode 43 on the base substrate, the first planarization layer in the twenty-third via V23 is removed to expose a surface of the third connection electrode 43, and the twenty-third via V23 is configured such that an anode connection electrode formed subsequently is connected with the third connection electrode 43 through the via.

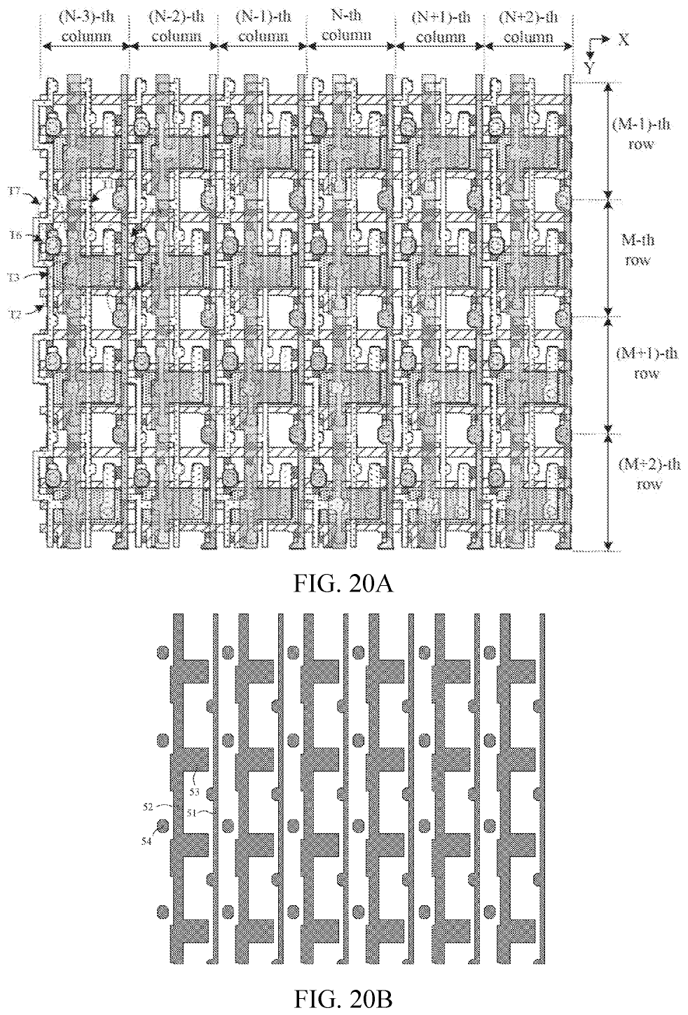

In an exemplary implementations, patterns of the plurality of vias of the dummy unit and patterns of the plurality of vias of the circuit unit may be substantially the same.
(17) Forming a pattern of a fourth conductive layer. In an exemplary implementation, forming the pattern of the fourth conductive layer may include: depositing a fourth conductive thin film on the base substrate on which the aforementioned patterns are formed, and patterning the fourth conductive thin film by a patterning process to form the fourth conductive layer arranged on the first planarization layer, as shown in FIG. 20A and FIG. 20B, FIG. 20B is a schematic planar diagram of the fourth conductive layer in FIG. 20A. In an exemplary implementations, the fourth conductive layer may be referred to as a second source-drain metal (SD2) layer.

In an exemplary implementations, the fourth conductive layer of the circuit unit at least includes a data signal line 51, a first power supply line 52, a power supply connection electrode 53 and an anode connection electrode 54.

In an exemplary implementations, a shape of the data signal line 51 may be a line shape of which a main body portion extends along the second direction Y, and the data signal line 51 may be connected to the fourth connection electrode 44 through the twenty-first via V21. Since the fourth connection electrode 44 is connected with the first region of the fourth active layer through a via, it is achieved that the data signal line 51 writes a data signal to a first electrode of the fourth transistor T4 through the fourth connection electrode 44.

In an exemplary implementations, the first power supply line 52 may be in a shape of a line in which a main body portion extends along the second direction Y, and the power supply connection electrode 53 may be in a shape of a rectangle, the power supply connection electrode 53 is provided at a side of the first power supply line 52 close to the data signal line 51 and connected to the first power supply line 52. The power supply connection electrode 53 may be connected to the second connection electrode 42 through the twenty-second via V22. Since the second connection electrode 42 is connected to the first region of the fifth active layer and the second electrode plate 31 through a via, it is achieved that the first power supply line 52 writes a first power supply signal to a first electrode of the fifth transistor T5, and the second electrode plate 31 and the first power supply line 52 have a same potential.

In an exemplary implementations, the first power supply line 52 and the power supply connection electrode 53 may be of an interconnected integral structure.

In an exemplary implementations, an orthographic projection of the first power supply line 52 on the base substrate overlaps at least partially an orthographic projection of the first connection electrode 41 on the base substrate. Since the first power supply line 52 continuously provides a high voltage signal, the first power supply line 52 can effectively shield a key node (the second node N2) on the pixel driving circuit, and can avoid the influence of a corresponding signal (such as a data voltage jump signal) on the potential of the second node N2 of the pixel driving circuit, thereby stabilizing the second node N2, improving the display uniformity and the display effect.

In an exemplary implementations, an orthographic projection of the first connection electrode 41 on the base substrate may be within a range of an orthographic projection of the first power supply line 52 on the base substrate, such that the first power supply line 52 completely covers the second node N2, shelters and shields the second node N2.

In an exemplary implementations, the anode connection electrode 54 may be in a shape of polygon, and the anode connection electrode 54 may be connected to the third connection electrode 43 through the twenty-third via v23. Since the third connection electrode 43 is connected to the second region of the sixth active layer (also the second region of the seventh active layer) through a via, it is achieved that the anode connection electrode 54 is connected to a second electrode of the sixth transistor T6 and a second electrode of the seventh transistor T7, respectively, and a same-electrode reset is achieved. In an exemplary implementations, the anode connection electrode 54 is configured to be connected with an anode subsequently formed.

In an exemplary implementations, an orthographic projection of the anode connection electrode 54 on the base substrate does not overlap an orthographic projection of the first initial signal line 61 on the base substrate, and an orthographic projection of the anode connection electrode 54 on the base substrate does not overlap an orthographic projection of the second initial signal line 62 on the base substrate.

In a display substrate, in order to realize a same-electrode reset of the first transistor and the seventh transistor, the sixth transistor and the seventh transistor are respectively arranged at two sides of the storage capacitor in the second direction Y, it needs to provide a connection electrode in a shape of “C” to connect a second electrode of the sixth transistor and a second electrode of the seventh transistor. Through research, it is found that the connection electrode will increase the parasitic capacitance of the pixel driving circuit, and the second electrode of the sixth transistor and the second electrode of the seventh transistor are susceptible to external interference, resulting in poor display uniformity. By arranging the first transistor, the sixth transistor and the seventh transistor on a same side of the third transistor (the storage capacitor) in the second direction Y, the exemplary embodiment of the present disclosure can not only realize the same-electrode reset of the first transistor and the seventh transistor, but also avoid the increase in the parasitic capacitance in the pixel driving circuit, thus improving the display uniformity.

In an exemplary implementations, a pattern of a fourth conductive layer of a dummy unit and a pattern of a fourth conductive layer of a circuit unit may be substantially the same.

A subsequent preparation process may include: forming a pattern of a second planarization layer, completing a drive circuit layer, and then preparing a light emitting structure layer and an encapsulation structure layer on the drive circuit layer.

In an exemplary implementations, forming the pattern of the second planarization layer may include: coating a second planarization thin film on the base substrate on which the aforementioned patterns are formed, patterning the second planarization thin film through a patterning process to form the second planarization layer covering the fourth conductive layer, wherein the second planarization layer is provided with a plurality of anode vias, orthographic projections of the anode vias on the base substrate may be within a range of an orthographic projection of the anode connection electrode on the base substrate, the second planarization layers in the anode vias are removed to expose a surface of the anode connection electrode, an anode via is configured such that an anode subsequently formed is connected with the anode connection electrode through the via.

In an exemplary implementations, preparing the light emitting structure layer may include: a pattern of an anode is formed, and the anode is connected with the anode connection electrode through the anode via; a pattern of a pixel definition layer is formed, wherein the pixel definition layer is provided with a pixel opening exposing the anode; an organic light emitting layer is formed using an evaporation or inkjet printing process, and the organic light emitting layer is connected with the anode through the pixel opening; a cathode is formed, and the cathode is connected with the organic light emitting layer. In an exemplary implementations, an orthographic projection of an anode in at least one light emitting unit on the base substrate at least partially overlaps an orthographic projection of a dummy pixel circuit in at least one dummy unit on the base substrate.

In an exemplary implementations, the encapsulation structure layer may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is provided between the first encapsulation layer and the third encapsulation layer, and it may be ensured that external water vapor cannot enter the light emitting structure layer.

So far, preparation of the display substrate including the drive circuit layer, the light emitting structure layer, and the encapsulation structure layer is completed.

In an exemplary implementation, the base substrate may be a flexible base substrate, or a rigid base substrate. The rigid base substrate may be made of, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementations, the flexible base substrate may include a first flexible material layer, a first inorganic material layer, a semiconductor layer, a second flexible material layer, and a second inorganic material layer which are stacked, wherein materials of the first flexible material layer and the second flexible material layer may be Polyimide (PI), Polyethylene Terephthalate (PET), or a surface-treated polymer soft film, or the like, materials of the first inorganic material layer and the second inorganic material layer may be Silicon Nitride (SiNx) or Silicon Oxide (SiOx), or the like, for improving a water and oxygen resistance capability of the base substrate, and a material of the semiconductor layer may be amorphous silicon (a-si).

In an exemplary implementations, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulating layer, the second insulating layer, the third insulating layer, the fourth insulating layer, and the fifth insulating layer may be made of any one or more of Silicon Oxide (SiOx), Silicon Nitride (SiNx), and Silicon Oxynitride (SiON), and may be a single layer, a multi-layer, or a composite layer. The first insulating layer is referred to as a buffer layer for improving the water and oxygen resistance of the base substrate, the second and the third insulating layers are referred to as gate insulating (GI) layers, the fourth insulating layer is referred to as an interlayer insulating (ILD) layer, and the fifth insulating layer is referred to as a passivation (PVX) layer. The first planarization layer and the second planarization layer may be made of an organic material, such as resin. An active layer may be made of a material such as amorphous Indium Gallium Zinc Oxide (a-IGZO), Zinc Oxynitride (ZnON), Indium Zinc Tin Oxide (IZTO), amorphous Silicon (a-Si), poly-crystalline Silicon (p-Si), hexathiophene, or polythiophene. That is, the present disclosure is applicable to a transistor that is manufactured based on an oxide technology, a silicon technology, or an organic matter technology.

In some possible exemplary implementations, the mesh structure shown in FIG. 13 may be as follows: the first conductive layers in the (M−1)-th and (M+2)-th rows as dummy rows each are provided with formed first connection line 71, which is connected to the first initial signal line 61 to form the first initial signal line with a mesh structure. In some other possible exemplary implementations, the mesh structure shown in FIG. 13 may be as follows: the first conductive layers in the (M−1)-th and (M+2)-th rows as dummy rows each are provided with formed second connection line 72, which is connected to the second initial signal line 62 to form the second initial signal line with a mesh structure. In yet some other possible exemplary implementations, the mesh structure shown in FIG. 13 may be as follows: the first conductive layers in the dummy rows of an upper region in the display region each are provided with formed first connection line 71, and the first conductive layers in the dummy rows of an lower region in the display region each are provided with formed second connection line 72, which is not limited in the present disclosure.

As can be seen from the structure and the preparation process of the display substrate described above, in the display substrate according to the present disclosure, the first connection line and the second connection line in which main body portions extend along the first direction are provided in the dummy row respectively, the first connection line and the second connection line are provided in the first conductive layer, the first connection line is connected with the first initial signal line in which a main body portion extends along the second direction, and the second connection line is connected with the second initial signal line in which a main body portion extends along the second direction, so that the first initial signal line transmitting the first initial signal forms a mesh structure and the second initial signal line transmitting the second initial signal forms a mesh structure, which not only effectively reduces the resistances of the first initial signal line and the second initial signal line, reduces the voltage drops of the first initial voltage and the second initial voltage, but also effectively improves the uniformity of the first initial voltage and the second initial voltage in the display substrate, effectively improves the display uniformity and the display effect and the display quality. By arranging the first connection line and the second connection line in the dummy row and connecting part or all of the signal lines in the dummy row with the bezel power supply lead line in the bezel region, the present disclosure not only enables the signal lines in the dummy row to be reasonably utilized, avoids the waste of the space in the display region, but also greatly reduces the load for transmitting a power supply signal and is beneficial to improving the display uniformity. The preparation process in the present disclosure may be compatible well with an existing preparation process, is simple in process implementation, is easy to implement, and has a high production efficiency, a low production cost, and a high yield.

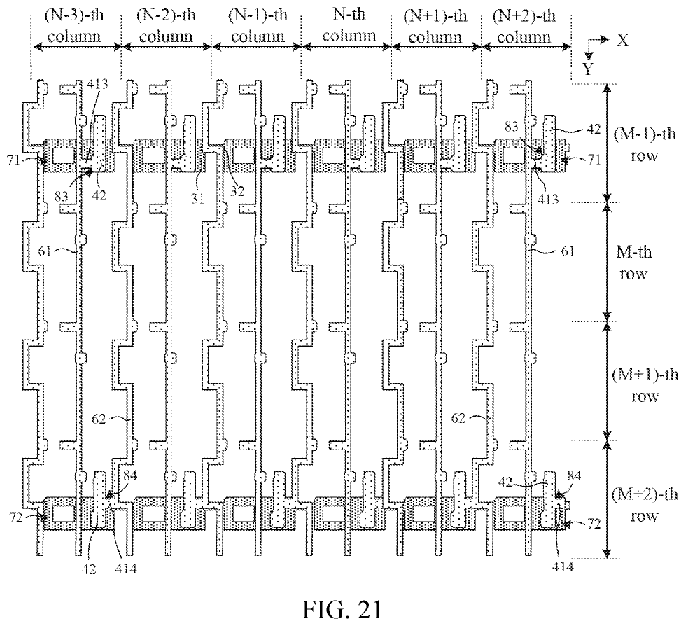

FIG. 21 is a schematic diagram of an initial signal line with another mesh structure according to an exemplary embodiment of the present disclosure, and an arrangement of circuit units and dummy units is the same as that shown in FIG. 12. As shown in FIG. 21, in an exemplary implementations, the first initial signal line 61 and the second initial signal line 62 may be disposed in each unit column, the first connection line 71 may be disposed in the (M−1)-th row as a dummy row, the first connection line 71 in the (M−1)-th row is connected to the first initial signal line 61, and the second connection line 72 may be disposed in the (M+2)-th row as a dummy row, the second connection line 72 in the (M+2)-th row is connected to the second initial signal line 62, both the first connection line 71 and the second connection line 72 are located in the second conductive layer.

In an exemplary implementations, the first connection line 71 and the second connection line 72 may be in a shape of a line in which a main body portion extends along the first direction X. The first connection line 71 and the second connection line 72 may include second electrode plates 31 and second auxiliary connection lines 32 alternately arranged and sequentially connected along the first direction X, i.e., the second electrode plates 31 adjacent in the first direction X are connected to each other through the second auxiliary connection lines 32.

In an exemplary implementations, the first initial signal line 61 may be in a shape of a line in which a main body portion extends along the second direction Y, and in the (M−1)-th row, the first initial signal line 61 may be connected to the first connection line 71 through the third initial electrode 83 to form a first initial signal line with a mesh structure. The second initial signal line 62 may be in a shape of a line in which a main body portion extends in the second direction Y, and in the (M+2)-th row, the second initial signal line 62 may be connected to the second connection line 72 through the fourth initial electrode 84 to form a second initial signal line with a mesh structure. Thus, a mesh structure for transmitting a first initial signal and a mesh structure for transmitting a second initial signal are formed simultaneously in the display region.

In an exemplary implementations, the first initial signal line 61 may be connected to the third initial electrode 83 which may be connected to the first connection line 71 through a via.

In an exemplary implementations, the third initial electrode 83 may include a second connection electrode 42 and a thirteenth connection electrode 413 connected to each other. The second connection electrode 42 and the thirteenth connection electrode 413 may be disposed in at least one dummy unit in the (M−1)-th row, a first end of the thirteenth connection electrode 413 is connected to the first initial signal line 61, a second end of the thirteenth connection electrode 413 is connected to the second connection electrode 42, and the second connection electrode 42 is connected to the first connection line 71 through a via, thereby achieving a connection between the first initial signal line 61 extending along the second direction Y and the first connection line 71 extending along the first direction X, so that the first initial signal line 61 and the first connection line 71 form a mesh structure for transmitting a first initial signal in the display region.

In an exemplary implementations, the second initial signal line 62 may be connected to the fourth initial electrode 84 which may be connected to the second connection line 72 through a via.

In an exemplary implementations, the fourth initial electrode 84 may include a second connection electrode 42 and a fourteenth connection electrode 414 connected to each other. The second connection electrode 42 and the fourteenth connection electrode 414 may be disposed in at least one dummy unit in the (M+2)-th row, a first end of the fourteenth connection electrode 414 is connected to the second initial signal line 62, a second end of the fourteenth connection electrode 414 is connected to the second connection electrode 42, and the second connection electrode 42 is connected to the second connection line 72 through a via, thereby achieving a connection between the second initial signal line 62 extending along the second direction Y and the second connection line 72 extending along the first direction X, so that the second initial signal line 62 and the second connection line 72 form a mesh structure for transmitting a second initial signal in the display region.

In an exemplary implementations, the third initial electrode 83 of the dummy unit in the N-th column is connected to the first initial signal line 61 in the N-th column, and the fourth initial electrode 84 of the dummy unit in the N-th column is connected to the second initial signal line 62 in an (N+1)-th column.

In an exemplary implementations, the second electrode plate 31 and the second auxiliary connection line 32 may be arranged in a same layer, i.e., the second conductive layer, and are synchronously formed through a same patterning process, and are of an interconnected integral structure. The first initial signal line 61, the second connection electrode 42, and the thirteenth connection electrode 413 may be arranged in a same layer, i.e., the third conductive layer, and are synchronously formed through a same patterning process, and are of an interconnected integral structure. The second initial signal line 62, the second connection electrode 42, and the fourteenth connection electrode 414 may be arranged in a same layer, i.e., the third conductive layer, and are synchronously formed through a same patterning process, and are of an interconnected integral structure.

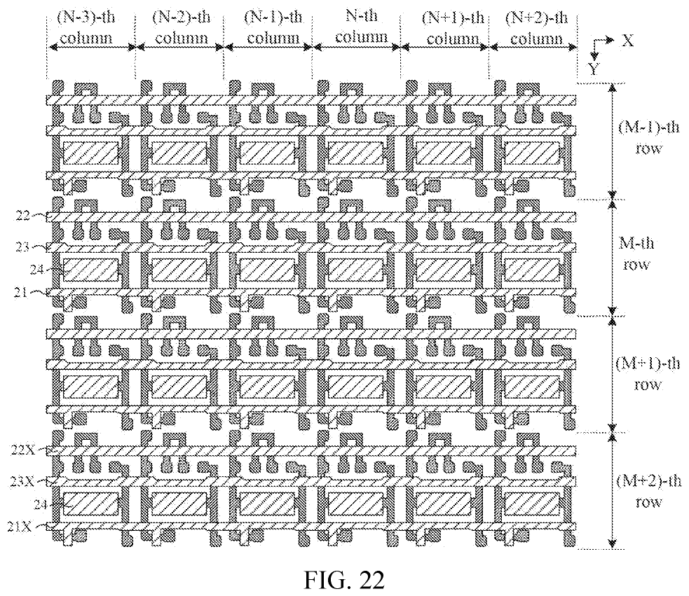

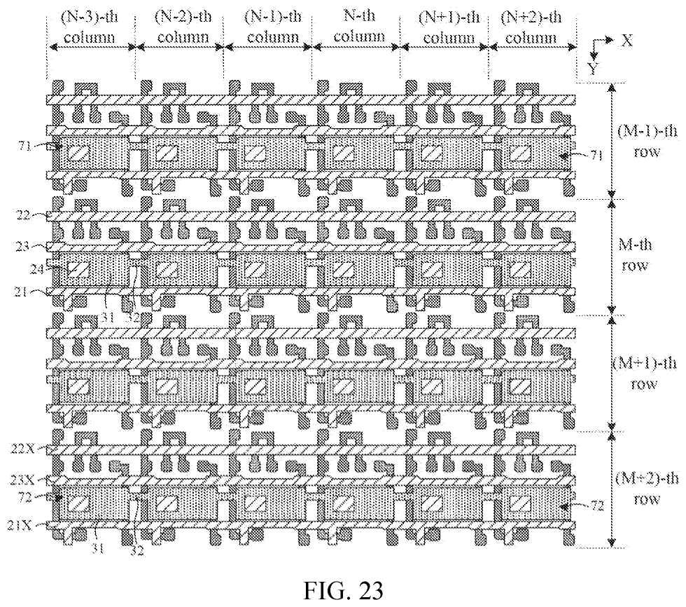

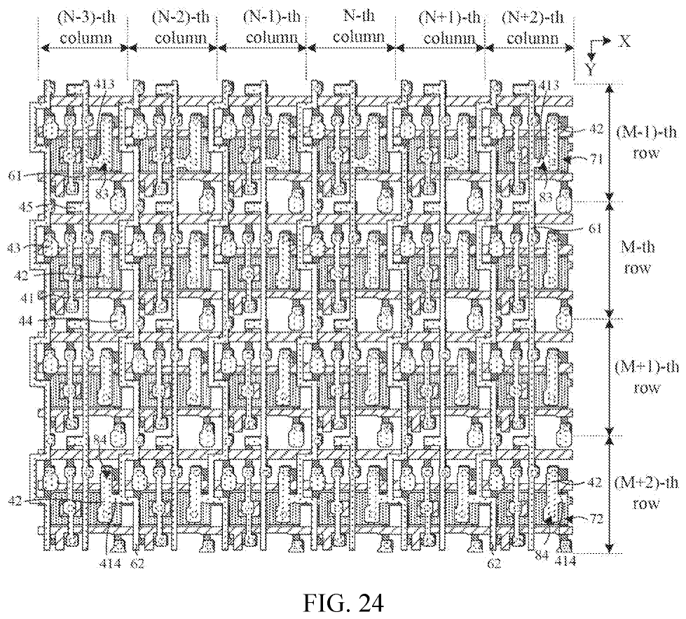

In an exemplary implementations, the preparation process of the display substrate according to this exemplary embodiment may include following acts.
(21) Forming a pattern of a semiconductor layer, a preparation process and formed pattern of the semiconductor layer are substantially the same as those in the act (11) of the foregoing embodiment.
(22) Forming a pattern of a first conductive layer, a preparation process and formed pattern of the first conductive layer are substantially the same as those in the act (12) of the foregoing embodiment, except that the pattern of the first conductive layer in the dummy unit according to the present exemplary embodiment is not provided with a first auxiliary connection line, i.e., the first electrode plates of adjacent dummy units in the first direction X are isolated from each other, as shown in FIG. 22.
(23) Forming a pattern of a second conductive layer, a preparation process and formed pattern of the second conductive layer are substantially the same as those in the act (13) of the foregoing embodiment, except that in the (M−1)-th row as a dummy row, the second electrode plate 31 with an integral structure is reused as the first connection line 71, and in the (M+2)-th row as a dummy row, the second electrode plate 31 with an integral structure is reused as the second connection line 72, as shown in FIG. 23.
(24) Forming a pattern of a fourth insulating layer, a preparation process and formed plurality of vias are substantially the same as those in the act (14) of the foregoing embodiment.
(25) Forming a pattern of a third conductive layer, a preparation process and formed pattern of the third conductive layer are substantially the same as the pattern of the third conductive layer formed in act (15) of the foregoing embodiment. The third conductive layers of the circuit unit and the dummy unit may each at least include a first connection electrode 41, a second connection electrode 42, a third connection electrode 43, a fourth connection electrode 44, a first shielding electrode 45, a first initial signal line 61 and a second initial signal line 62, except that at least one dummy unit is further provided with a thirteenth connection electrode 413 in the dummy unit of the (M−1)-th row as a dummy row, and at least one dummy unit is further provided with a fourteenth connection electrode 414 in the dummy unit of the (M+2)-th row as a dummy row, as shown in FIG. 24.

In an exemplary implementations, the thirteenth connection electrode 413 may be in a shape of a rectangle, a first end of the thirteenth connection electrode 413 may be connected to the first initial signal line 61, a second end of the thirteenth connection electrode 413 may be connected to the second connection electrode 42, and the second connection electrode 42 and the thirteenth connection electrode 413 connected to each other form the third initial electrode 83 according to the present disclosure. Since the second connection electrode 42 in the dummy unit is connected to the second electrode plate, a plurality of second electrode plates in the (M−1)-th row are connected to each other through the second auxiliary connection lines, and the second electrode plate with an integral structure is reused as the first connection line 71, it is achieved that the first initial signal line 61 is connected to the first connection line 71 in the (M−1)-th row through the third initial electrode 83, that is, it is achieved that the first initial signal line 61 extending along the second direction Y is connected to the first connection line 71 extending along the first direction X.

In an exemplary implementations, the fourteenth connection electrode 414 may be in a shape of a rectangle, a first end of the fourteenth connection electrode 414 may be connected to the second initial signal line 62, a second end of the fourteenth connection electrode 414 may be connected to the second connection electrode 42, and the second connection electrode 42 and the fourteenth connection electrode 414 connected to each other form the fourth initial electrode 84 according to the present disclosure. Since the second connection electrode 42 in the dummy unit is connected to the second electrode plate, a plurality of second electrode plates in the (M+2)-th row are connected to each other through the second auxiliary connection lines, and the second electrode plate with an integral structure is reused as the second connection line 72, the connection of the second initial signal line 62 to the second connection line 72 in the (M+2)-th row through the fourth initial electrode 84 is achieved, that is, the connection of the second initial signal line 62 extending along the second direction Y and the second connection line 72 extending along the first direction X is achieved.
(26) Forming a pattern of a first planarization layer and a pattern of a fourth conductive layer, a preparation process and formed patterns are substantially the same as those in the acts (16) to (17) of the foregoing embodiment, and will not be repeated here.

In the display substrate according to an exemplary embodiment of the present disclosure, the first connection line and the second connection line, of which main portions extend in the first direction, are respectively arranged in a dummy row, and the first connection line and the second connection line are arranged in the second conductive layer, it is achieved that the first initial signal line transmitting a first initial signal forms a mesh structure and the second initial signal line transmitting a second initial signal forms a mesh structure, which not only effectively reduces the resistances of the first initial signal line and the second initial signal line, reduces the voltage drop of the first initial voltage and the second initial voltage, but also effectively improves the uniformity of the first initial voltage and the second initial voltage in the display substrate, effectively improves the display uniformity and the display effect and the display quality.

In some possible exemplary implementations, the mesh structure shown in FIG. 21 may be as follows: the second conductive layers in the (M−1)-th and (M+2)-th rows as dummy rows each are provided with formed first connection line 71, which is connected to the first initial signal line 61 to form the first initial signal line with a mesh structure. In some other possible exemplary implementations, the mesh structure shown in FIG. 21 may be as follows: the second conductive layers in the (M−1)-th and (M+2)-th rows as dummy rows each are provided with formed second connection line 72, which is connected to the second initial signal line 62 to form the second initial signal line with a mesh structure. In yet some possible exemplary implementations, the mesh structure shown in FIG. 21 may be as follows: the second conductive layers in the dummy rows of an upper region in the display region each are provided with formed first connection line 71, and the second conductive layers in the dummy rows of a lower region in the display region each are provided with formed second connection line 72, which is not limited in the present disclosure.

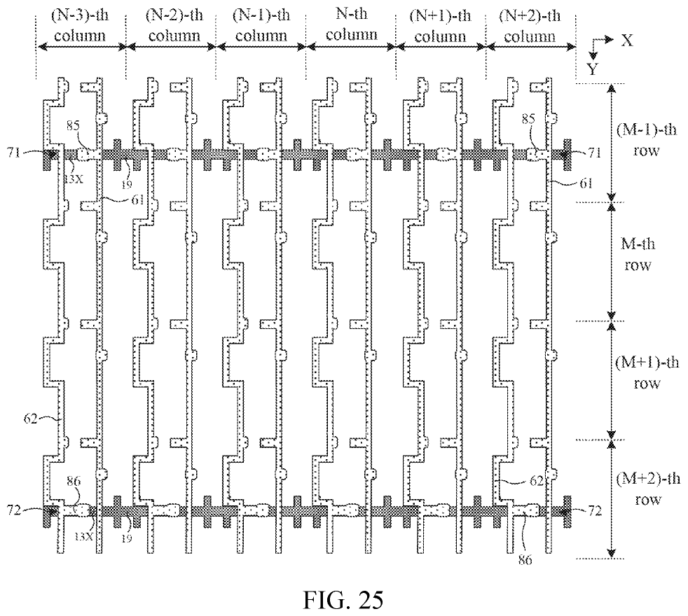

FIG. 25 is a schematic diagram of an initial signal line with yet another mesh structure according to an exemplary embodiment of the present disclosure, and an arrangement of circuit units and dummy units is the same as that shown in FIG. 12. As shown in FIG. 25, in an exemplary implementations, the first initial signal line 61 and the second initial signal line 62 may be disposed in each unit column, the first connection line 71 may be disposed in the (M−1)-th row as a dummy row, the first connection line 71 in the (M−1)-th row is connected to the first initial signal line 61, and the second connection line 72 may be disposed in the (M+2)-th row as a dummy row, the second connection line 72 in the (M+2)-th row is connected to the second initial signal line 62, both the first connection line 71 and the second connection line 72 are located in the semiconductor layer.

In an exemplary implementations, the first connection line 71 and the second connection line 72 may be in a shape of a line in which a main body portion extends along the first direction X. The first connection line 71 and the second connection line 72 may each include semiconductor body parts 13X and third auxiliary connection lines 19 alternately arranged and connected sequentially along the first direction X, that is, semiconductor body parts 13X adjacent in the first direction X are connected to each other through the third auxiliary connection lines 19.

In an exemplary implementations, the first initial signal line 61 may be in a shape of a line in which a main body portion extends along the second direction Y, and in the (M−1)-th row, the first initial signal line 61 may be connected to the first connection line 71 through the fifth initial electrode 85 to form a first initial signal line with a mesh structure. The second initial signal line 62 may be in a shape of a line in which a main body portion extends in the second direction Y, and in the (M+2)-th row, the second initial signal line 62 may be connected to the second connection line 72 through the sixth initial electrode 86 to form a second initial signal line with a mesh structure. Thus, a mesh structure for transmitting a first initial signal and a mesh structure for transmitting a second initial signal are formed simultaneously in the display region.

In an exemplary implementations, the fifth initial electrode 85 may be provided in at least one dummy unit in the (M−1)-th row, a first end of the fifth initial electrode 85 is connected to the first initial signal line 61, and a second end of the fifth initial electrode 85 is connected to the first connection line 71 through a via, a connection between the first initial signal line 61 extending along the second direction Y and the first connection line 71 extending along the first direction X is thus achieved, so that the first initial signal line 61 and the first connection line 71 form a mesh structure for transmitting a first initial signal in a display region.

In an exemplary implementations, the sixth initial electrode 86 may be provided in at least one dummy unit in the (M+2)-th row, a first end of the sixth initial electrode 86 is connected to the second initial signal line 62, and a second end of the sixth initial electrode 86 is connected to the second connection line 72 through a via, a connection between the second initial signal line 62 extending along the second direction Y and the second connection line 72 extending along the first direction X is thus achieved, so that the second initial signal line 62 and the second connection line 72 form a mesh structure for transmitting a second initial signal in the display region.

In an exemplary implementations, the fifth initial electrode 85 of the dummy unit in the N-th column is connected to the first initial signal line 61 in the N-th column, and the sixth initial electrode 86 of the dummy unit in the N-th column is connected to the second initial signal line 62 in the N-th column.

In an exemplary implementations, the semiconductor body part 13X and the third auxiliary connection line 19 may be provided in a same layer, i.e., the semiconductor layer, and are synchronously formed through a same patterning process and are of an interconnected integral structure. The first initial signal line 61 and the fifth initial electrode 85 may be arranged in a same layer, i.e., the third conductive layer, and formed synchronously through a same patterning process and have an integral structure connected with each other. The second initial signal line 62 and the sixth initial electrode 86 may be arranged in a same layer, i.e., the third conductive layer, and are synchronously formed through a same patterning process, and are of an interconnected integral structure.

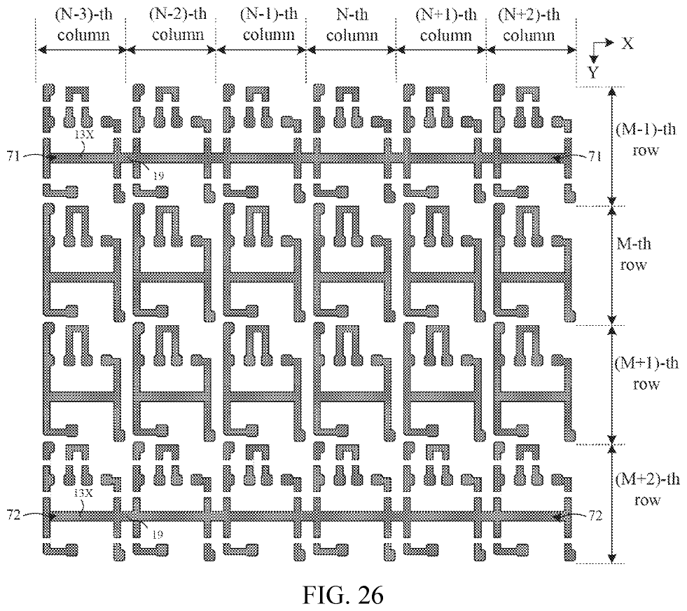

In an exemplary implementations, the preparation process of the display substrate according to this exemplary embodiment may include following acts.
(31) Forming a pattern of a semiconductor layer, a preparation process and formed pattern of the semiconductor layer are substantially the same as those in the act (11) of the foregoing embodiment, except that the semiconductor body parts 13X adjacent to each other in the first direction X are connected to each other by the third auxiliary connection lines 19. In the (M−1)-th row as a dummy row, the semiconductor body part 13X with an integral structure are reused as the first connection line 71, which may be in a shape of a strip in which a main body portion extend along the first direction X, and in the (M+2)-th row as a dummy row, the semiconductor body part 13X with an integral structure are reused as the second connection line 72, which may be in a shape of a strip in which a main body portion extend along the first direction X, as shown in FIG. 26.

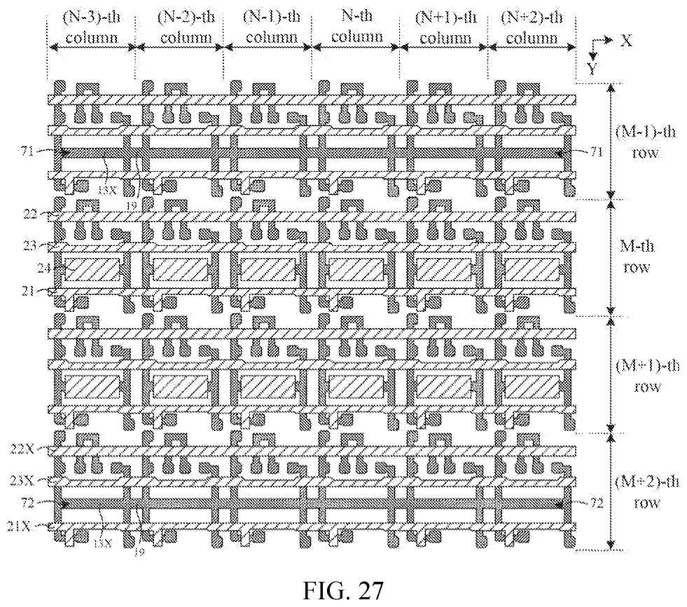

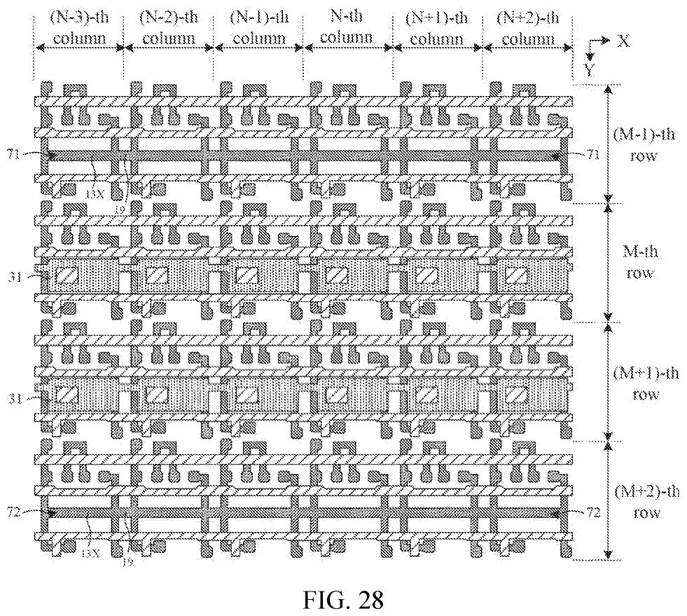

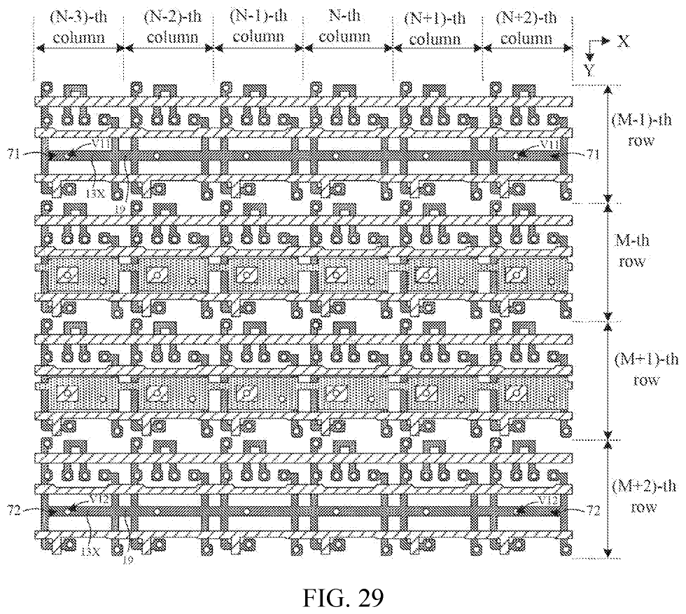

In an exemplary implementations, the pattern of the semiconductor layer in the dummy unit further includes a third auxiliary connection line 19. The third auxiliary connection line 19 may be in a shape of a strip in which a main body portion extends along the first direction X, and may be provided at a side of the semiconductor body part 13X in the first direction X or in an opposite direction of the first direction X, that is, the third auxiliary connection line 19 may be located between semiconductor body parts 13X adjacent in the first direction X. A first end of the third auxiliary connection line 19 is connected to the semiconductor main body part 13X of the present dummy unit, and a second end of the third auxiliary connection line 19, after extending along the first direction X or the opposite direction of the first direction X, is connected to the semiconductor main body part 13X of an adjacent dummy unit. The third auxiliary connection line 19 is such that the semiconductor main body parts 13X of adjacent dummy units in a dummy row are connected with each other, the semiconductor main body parts 13X of a plurality of dummy units in a dummy row form an interconnected integral structure, and the first electrode plate with an integral structure may be reused as the first connection line 71 or the second connection line 72.
(32) Forming a pattern of a first conductive layer, a preparation process and formed pattern of the first conductive layer are substantially the same as those in the act (12) of the foregoing embodiment, except that the first electrode plate and the first auxiliary connection line are not provided in the pattern of the first conductive layer in the dummy unit according to the present exemplary embodiment, i.e., a region where the first connection line 71 and the second connection line 72 are located is not sheltered, as shown in FIG. 27.
(33) Forming a pattern of a second conductive layer, a preparation process and formed pattern of the second conductive layer are substantially the same as those in the act (13) of the foregoing embodiment, except that the second electrode plate and the second auxiliary connection line are not provided in the pattern of the second conductive layer in the dummy unit according to the present exemplary embodiment, i.e., a region where the first connection line 71 and the second connection line 72 are located is not sheltered, as shown in FIG. 28.
(34) Forming a pattern of a fourth insulating layer, a preparation process and formed plurality of vias are substantially the same as those in the act (14) of the foregoing embodiment, except that, since the first electrode plate and the second electrode plate are not provided in the dummy unit, the first via V1 and the second via V2 are not provided, but the eleventh via V11 and the twelfth via V12 are provided in the dummy unit according to the present exemplary embodiment, as shown in FIG. 29.

In an exemplary implementations, the eleventh via V11 may be located in a dummy unit in the (M−1)-th row, an orthographic projection of the eleventh via V11 on the base substrate may be within a range of an orthographic projection of the semiconductor body part 13X on the base substrate, the fourth insulating layer, the third insulating layer and the second insulating layer within the eleventh via V11 are etched away to expose a surface of the semiconductor body part 13X, and the eleventh via V11 is configured such that a first initial signal line formed subsequently is connected with the semiconductor body part 13X (the first connection line 71) through the via. In an exemplary implementations, the eleventh via V11 may be multiple, and the plurality of eleventh vias V11 may be sequentially arranged along the first direction X to increase connection reliability.

In an exemplary implementations, the twelfth via V12 may be located in a dummy unit in the (M+2)-th row, an orthographic projection of the twelfth via V12 on the base substrate may be within a range of an orthographic projection of the semiconductor body part 13X on the base substrate, the fourth insulating layer, the third insulating layer and the second insulating layer within the twelfth via V12 are etched away to expose a surface of the semiconductor body part 13X, and the twelfth via V12 is configured such that a second initial signal line formed subsequently is connected with the semiconductor body part 13X (the second connection line 72) through the via. In an exemplary implementations, the twelfth via V12 may be multiple, and the plurality of twelfth vias V12 may be sequentially arranged along the first direction X to increase connection reliability.

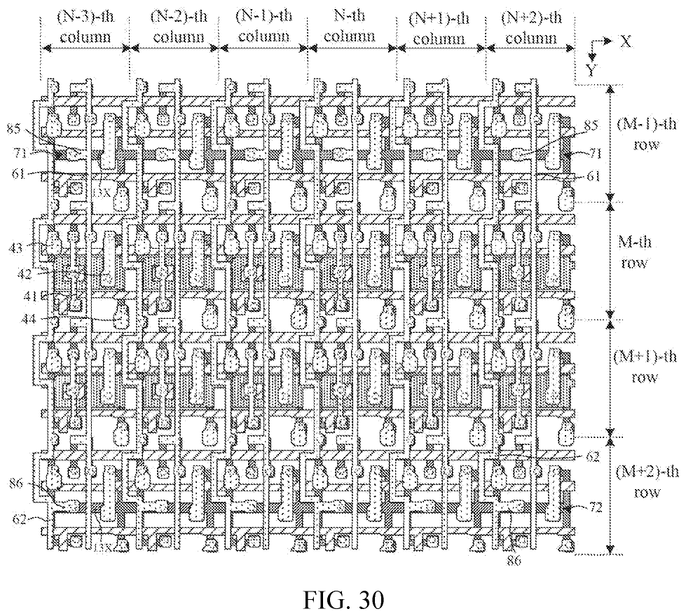

In an exemplary implementations, the third via V3 to the ninth via V9 in the dummy unit may be substantially the same as those in the act (14) of the foregoing embodiment.
(35) Forming a pattern of a third conductive layer, a preparation process and formed pattern of the third conductive layer are substantially the same as the pattern of the third conductive layer formed in act (15) of the foregoing embodiment. The third conductive layers of the circuit unit and the dummy unit may each at least include a first connection electrode 41, a second connection electrode 42, a third connection electrode 43, a fourth connection electrode 44, a first shielding electrode 45, a first initial signal line 61 and a second initial signal line 62, except that at least one dummy unit is provided with the fifth initial electrode 85 in the dummy unit of the (M−1)-th row as a dummy row, and at least one dummy unit is provided with the sixth initial electrode 86 in the dummy unit of the (M+2)-th row as a dummy row, as shown in FIG. 30.

In an exemplary implementations, the fifth initial electrode 85 may be provided in at least one dummy unit in the (M−1)-th row, the fifth initial electrode 85 may be in a shape of a strip, a first end of the fifth initial electrode 85 may be connected to the first initial signal line 61, and a second end of the fifth initial electrode 85 may be connected to the semiconductor body part 13X through the eleventh via V11. Since the semiconductor body parts 13X of a plurality of dummy units in the (M−1)-th row are connected to each other through the third auxiliary connection lines 19, the semiconductor body part 13X and the third auxiliary connection line 19 of an integral structure are reused as the first connection line 71, a connection between the first initial signal line 61 and the first connection line 71 of the (M−1)-th row through the fifth initial electrode 85 is thus achieved, that is, a connection between the first initial signal line 61 extending in the second direction Y and the first connection line 71 extending in the first direction X is achieved.

In an exemplary implementations, the sixth initial electrode 86 may be provided in at least one dummy unit in the (M+2)-th row, the sixth initial electrode 86 may be in a shape of a strip, a first end of the sixth initial electrode 86 may be connected to the second initial signal line 62, and a second end of the sixth initial electrode 86 may be connected to the semiconductor body part 13X through the twelfth via V12. Since the semiconductor body parts 13X of a plurality of dummy units in the (M+2)-th row are connected to each other through the third auxiliary connection lines 19, and the semiconductor body part 13X and the third auxiliary connection line 19 of an integral structure are reused as the second connection line 72, a connection between the second initial signal line 62 and the second connection line 72 in the (M+2)-th row through the sixth initial electrode 86 is thus achieved, that is, a connection between the second initial signal line 62 extending in the second direction Y and the second connection line 72 extending in the first direction X is achieved.

In an exemplary implementations, since the first electrode plate and the second electrode plate are not provided in the dummy unit, the first connection electrode in the dummy unit may include two isolated connection electrodes in a shape of a block, one connection electrode is connected to the first region of the second active layer through the sixth via, and the other connection electrode is connected to the second region of the first active layer through the ninth via, so as to ensure the uniformity of the via etching process and the via connection process.
(36) Forming a pattern of a first planarization layer and a pattern of a fourth conductive layer, a preparation process and formed patterns are substantially the same as those in the acts (16) to (17) of the foregoing embodiment, and will not be repeated here.

In the display substrate according to an exemplary embodiment of the present disclosure, by respectively arranging the first connection line and the second connection line in which main portions extend in the first direction in the dummy row, and arranging the first connection line and the second connection line in the semiconductor layer, it is achieved that the first initial signal line transmitting the first initial signal forms a mesh structure and the second initial signal line transmitting the second initial signal forms a mesh structure, which not only effectively reduces the resistances of the first initial signal line and the second initial signal line, reduces the voltage drops of the first initial voltage and the second initial voltage, but also effectively improves the uniformity of the first initial voltage and the second initial voltage in the display substrate, effectively improves the display uniformity and the display effect and the display quality.

In some possible exemplary implementations, the mesh structure shown in FIG. 25 may be as follows: the semiconductor layers in the (M−1)-th row and the (M+2)-th row as dummy rows each are provided with formed first connection line 71, which is connected to the first initial signal line 61 to form a first initial signal line with a mesh structure. In some other possible exemplary implementations, the mesh structure shown in FIG. 25 may be as follows: the semiconductor layers in the (M−1)-th and (M+2)-th rows as dummy rows each are provided with formed second connection line 72, which is connected to the second initial signal line 62 to form a second initial signal line with a mesh structure. In yet some another possible exemplary implementations, the mesh structure shown in FIG. 25 may be as follows: the semiconductor layers in the dummy rows of an upper region in the display region each are provided with formed first connection line 71, and the semiconductor layers in the dummy rows of a lower region in the display region each are provided with formed second connection line 72, which is not limited in the present disclosure.

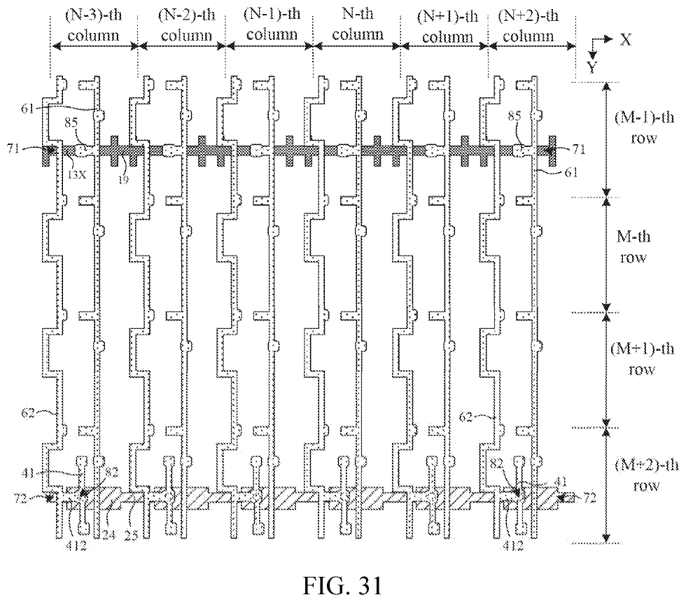

FIG. 31 is a schematic diagram of an initial signal line with still yet another mesh structure according to an exemplary embodiment of the present disclosure, and an arrangement of circuit units and dummy units is the same as that shown in FIG. 12. As shown in FIG. 31, in an exemplary implementations, the first initial signal line 61 and the second initial signal line 62 may be disposed in each unit column, the first connection line 71 may be disposed in the (M−1)-th row and the (M+2)-th row as dummy rows, the first connection line 71 is connected with the first initial signal line 61, and the second connection line 72 may be disposed in the (M−1)-th row and the (M+2)-th row as dummy rows, the second connection line 72 is connected with the second initial signal line 62. In an exemplary embodiment, the first connection line 71 may be disposed in the semiconductor layer, and the second connection line 72 may be disposed in the first conductive layer.

In an exemplary implementations, the first connection line 71 and the second connection line 72 may be in a shape of a line in which a main body portion extends along the first direction X. The first connection line 71 may include the semiconductor body part 13X and the third auxiliary connection line 19 alternately arranged and sequentially connected along the first direction X, and the second connection line 72 may include the first electrode plate 24 and the first auxiliary connection line 25 alternately arranged and sequentially connected along the first direction X.

In an exemplary implementations, the first initial signal line 61 may be in a shape of a line in which a main body portion extends along the second direction Y, and in the (M−1)-th and (M+2)-th rows, the first initial signal line 61 may be connected to the first connection line 71 through the fifth initial electrode 85 to form a first initial signal line with a mesh structure. The second initial signal line 62 may be in a shape of a line in which a main body portion extends in the second direction Y, and in the (M−1)-th and (M+2)-th rows, the second initial signal line 62 may be connected with the second connection line 72 through the second initial electrode 82 (including the first connection electrode 41 and the twelfth connection electrode 412 connected to each other) to form a second initial signal line with a mesh structure.

It should be noted that, in FIG. 31, only a connection between the first initial signal line 61 and the first connection line 71 is shown in the (M−1)-th row, and only a connection relationship between the second initial signal line 62 and the second connection line 72 is shown in the (M+2)-th row, so as to clearly reflect the connection structure. In an exemplary implementations, the (M−1)-th row may be provided with a second connection line 72 connected to the second initial signal line 62, and the (M+2)-th row may be provided with a first connection line 71 connected to the first initial signal line 61.

In an exemplary implementations, the structures of the second initial electrode 82 and the fifth initial electrode 85 are substantially the same as those of the foregoing embodiments.

In an exemplary implementations, the preparation process of the display substrate according to the present exemplary embodiment may be substantially the same as the preparation process of the foregoing embodiment, except that in the formation of the pattern of the semiconductor layer, the first connection line 71 is formed in both (M−1)-th and (M+2)-th rows as dummy rows, in the formation of the pattern of the first conductive layer, the second connection line 72 is formed in both (M−1)-th and (M+2)-th rows as dummy rows, in the formation of the pattern of the third conductive layer, the twelfth connection electrode 412 and the fifth initial electrode 85 are formed in both (M−1)-th and (M+2)-th rows as dummy rows, the first initial signal line 61 is connected to the first connection line 71 through the fifth initial electrode 85, and the second initial signal line 62 is connected to the second connection line 72 through the first connection electrode 41 and the twelfth connection electrode 412 (the second initial electrode 82).

In some possible exemplary implementations, the first connection line may be disposed in the first conductive layer, the second connection line may be disposed in the semiconductor layer, the third conductive layer may include an eleventh connection electrode and a sixth initial electrode, the first initial signal line may be connected to the first connection line through the first connection electrode and the eleventh connection electrode (the first initial electrode), and the second initial signal line may be connected to the second connection line through the sixth initial electrode, which is not limited in the present disclosure.

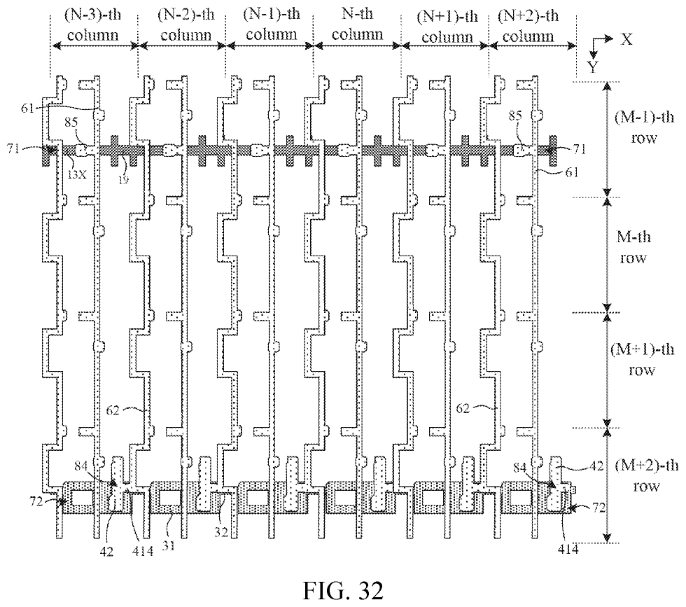

FIG. 32 is a schematic diagram of an initial signal line with also still yet another mesh structure according to an exemplary embodiment of the present disclosure, and an arrangement of circuit units and dummy units is the same as that shown in FIG. 12. As shown in FIG. 32, in an exemplary implementations, the first initial signal line 61 and the second initial signal line 62 may be disposed in each unit column, the first connection line 71 may be disposed in the (M−1)-th row and the (M+2)-th row as dummy rows, the first connection line 71 is connected with the first initial signal line 61, and the second connection line 72 may be disposed in the (M−1)-th row and the (M+2)-th row as dummy rows, the second connection line 72 is connected with the second initial signal line 62. In an exemplary embodiment, the first connection line 71 may be disposed in the semiconductor layer, and the second connection line 72 may be disposed in the second conductive layer.

In an exemplary implementations, the first connection line 71 and the second connection line 72 may be in a shape of a line in which a main body portion extends along the first direction X. The first connection line 71 may include the semiconductor body part 13X and the third auxiliary connection line 19 alternately arranged and sequentially connected along the first direction X, and the second connection line 72 may include the second electrode plate 31 and the second auxiliary connection line 32 alternately arranged and sequentially connected along the first direction X.

In an exemplary implementations, the first initial signal line 61 may be in a shape of a line in which a main body portion extends along the second direction Y, and in the (M−1)-th and (M+2)-th rows, the first initial signal line 61 may be connected to the first connection line 71 through the fifth initial electrode 85 to form a first initial signal line with a mesh structure. The second initial signal line 62 may be in a shape of a line in which a main body portion extends in the second direction Y, and in the (M−1)-th and (M+2)-th rows, the second initial signal line 62 may be connected with the second connection line 72 through the fourth initial electrode 84 (including the second connection electrode 42 and the fourteenth connection electrode 414 connected to each other) to form a second initial signal line with a mesh structure.

It should be noted that, in FIG. 32, only a connection between the first initial signal line 61 and the first connection line 71 is shown in the (M−1)-th row, and only a connection relationship between the second initial signal line 62 and the second connection line 72 is shown in the (M+2)-th row, so as to clearly reflect the connection structure. In an exemplary implementations, the (M−1)-th row may be provided with a second connection line 72 connected to the second initial signal line 62, and the (M+2)-th row may be provided with a first connection line 71 connected to the first initial signal line 61.

In an exemplary implementations, the structures the fourth initial electrode 84 and the fifth initial electrode 85 are substantially the same as those of the foregoing embodiments.

In an exemplary implementations, the preparation process of the display substrate according to the present exemplary embodiment may be substantially the same as the preparation process of the foregoing embodiment, except that in the formation of the pattern of the semiconductor layer, the first connection line 71 is formed in both (M−1)-th and (M+2)-th rows as dummy rows, in the formation of the pattern of the second conductive layer, the second connection line 72 is formed in both (M−1)-th and (M+2)-th rows as dummy rows, and in the formation of the pattern of the third conductive layer, the second connection electrode 42, the fourteenth connection electrode 414 and the fifth initial electrode 85 are formed in both (M−1)-th and (M+2)-th rows as dummy rows, the first initial signal line 61 is connected to the first connection line 71 through the fifth initial electrode 85, and the second initial signal line 62 is connected to the second connection line 72 through the second connection electrode 42 and the fourteenth connection electrode 414 (the fourth initial electrode 84).

In some possible exemplary implementations, the first connection line may be disposed in the second conductive layer, the second connection line may be disposed in the semiconductor layer, the third conductive layer may include a second connection electrode, a thirteenth connection electrode, and a sixth initial electrode, the first initial signal line may be connected to the first connection line through the second connection electrode and the thirteenth connection electrode (the third initial electrode), and the second initial signal line may be connected to the second connection line through the sixth initial electrode, which is not limited in the present disclosure.

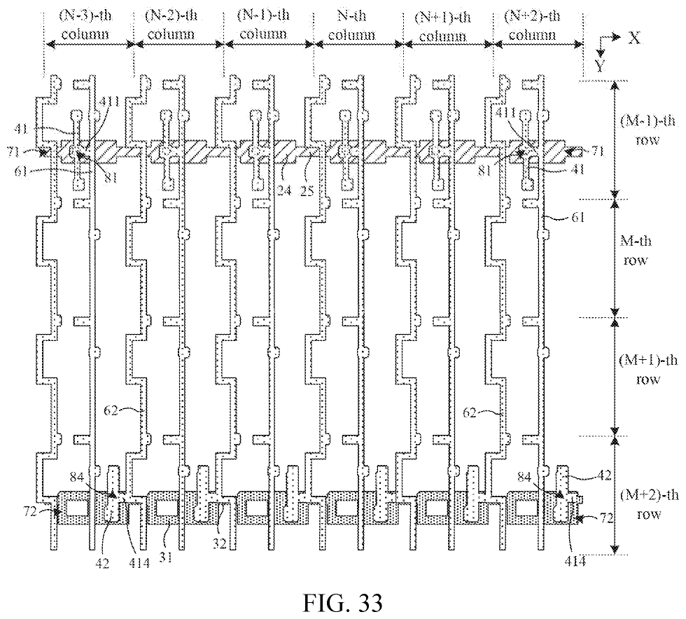

FIG. 33 is a schematic diagram of an initial signal line with also still further yet another mesh structure region according to an exemplary embodiment of the present disclosure, and an arrangement of circuit units and dummy units is the same as that shown in FIG. 12. As shown in FIG. 33, in an exemplary implementations, the first initial signal line 61 and the second initial signal line 62 may be disposed in each unit column, the first connection line 71 may be disposed in the (M−1)-th row and the (M+2)-th row as dummy rows, the first connection line 71 is connected with the first initial signal line 61, and the second connection line 72 may be disposed in the (M−1)-th row and the (M+2)-th row as dummy rows, the second connection line 72 is connected with the second initial signal line 62. In the present exemplary embodiment, the first connection line 71 may be provided in the first conductive layer, and the second connection line 72 may be provided in the second conductive layer.

In an exemplary implementations, the first connection line 71 and the second connection line 72 may be in a shape of a line in which a main body portion extends along the first direction X. The first connection line 71 may include the first electrode plate 24 and the first auxiliary connection line 25 alternately arranged and sequentially connected along the first direction X, and the second connection line 72 may include the second electrode plate 31 and the second auxiliary connection line 32 alternately arranged and sequentially connected along the first direction X.

In an exemplary implementations, the first initial signal line 61 may be in a shape of a line in which a main body portion extends along the second direction Y, and in the (M−1)-th and (M+2)-th rows, the first initial signal line 61 may be connected with the first connection line 71 through the first initial electrode 81 (including the first connection electrode 41 and the eleventh connection electrode 411 connected to each other) to form a first initial signal line with a mesh structure. The second initial signal line 62 may be in a shape of a line in which a main body portion extends in the second direction Y, and in the (M−1)-th and (M+2)-th rows, the second initial signal line 62 may be connected with the second connection line 72 through the fourth initial electrode 84 (including the second connection electrode 42 and the fourteenth connection electrode 414 connected to each other) to form a second initial signal line with a mesh structure.

It should be noted that, in FIG. 33, only a connection between the first initial signal line 61 and the first connection line 71 is shown in the (M−1)-th row, and only a connection relationship between the second initial signal line 62 and the second connection line 72 is shown in the (M+2)-th row, so as to clearly reflect the connection structure. In an exemplary implementations, the (M−1)-th row may be provided with a second connection line 72 connected to the second initial signal line 62, and the (M+2)-th row may be provided with a first connection line 71 connected to the first initial signal line 61.

In an exemplary implementations, the structures of the first connection electrode 41, the second connection electrode 42, the eleventh connection electrode 411 and the fourteenth connection electrode 414 are substantially the same as those of the foregoing embodiments.

In an exemplary implementations, the preparation process of the display substrate according to the present exemplary embodiment may be substantially the same as the preparation process of the foregoing embodiment, except that in the formation of the pattern of the first conductive layer, the first connection line 71 is formed in both (M−1)-th and (M+2)-th rows as dummy rows, in the formation of the pattern of the second conductive layer, the second connection line 72 is formed in both (M−1)-th and (M+2)-th rows as dummy rows, and in the formation of the pattern of the third conductive layer, the first connection electrode 41, the second connection electrode 42, the eleventh connection electrode 411 and the fourteenth connection electrode 414 are formed in both (M−1)-th and (M+2)-th rows as dummy rows, the first initial signal line 61 is connected to the first connection line 71 through the first connection electrode 41 and the eleventh connection electrode 411 (the first initial electrode 81), and the second initial signal line 62 is connected to the second connection line 72 through the second the electrode 42 and the fourteenth connection electrode 414 (the fourth initial electrode 84).

In some possible exemplary implementations, the first connection line may be disposed in the second conductive layer, the second connection line may be disposed in the first conductive layer, the third conductive layer may include the first connection electrode, the second connection electrode, the twelfth connection electrode and the thirteenth connection electrode, the first initial signal line may be connected to the first connection line through the third initial electrode (including the second connection electrode and the thirteenth connection electrode connected to each other), and the second initial signal line may be connected to the second connection line through the second initial electrode (including the first connection electrode and the twelfth connection electrode connected to each other), which is not limited in the present disclosure.

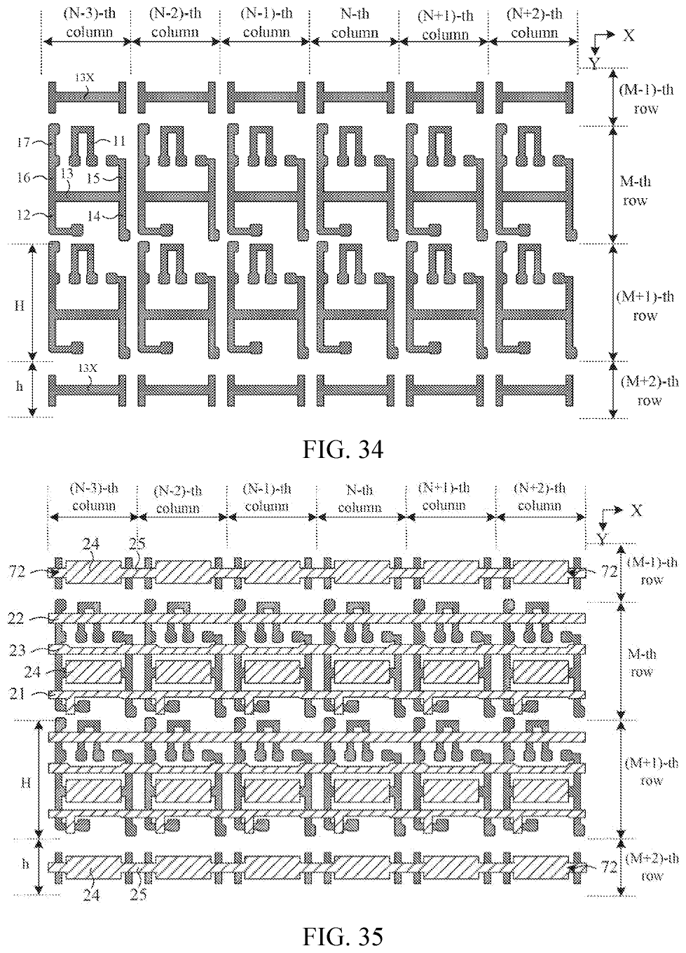

FIGS. 34 to 37 are schematic diagrams of a structure of another first circuit region according to an exemplary embodiment of the present disclosure, illustrating a structure in which the first connection line is located in the second conductive layer and the second connection line is located in the first conductive layer. Herein, the first circuit region may include two unit rows and two dummy rows, the M-th row and the (M+1)-th row are unit rows, each including 6 circuit units, and the (M−1)-th row and the (M+2)-th row are dummy rows, each including 6 dummy units. Structures of the unit row and the circuit unit according to the present exemplary embodiment are substantially the same as those of the unit row and the circuit unit shown above in FIG. 12, and a film layer structure of the first circuit region is substantially the same as that of the film layer structure shown above in FIG. 12, except that the dummy unit size h of the dummy unit in the second direction is smaller than the circuit unit size H of the unit row in the second direction.

In an exemplary implementations, a dummy row may at least include a plurality of dummy units sequentially arranged along the first direction X, at least one dummy unit may include a dummy pixel circuit, the dummy pixel circuit may include only the semiconductor body part 13X, and the first dummy signal line, the second dummy signal line and the dummy light emitting light are not provided in the dummy unit.

In an exemplary implementations, the pattern of the semiconductor layer of the circuit unit may be substantially the same as the pattern of the semiconductor layer of the circuit unit in the foregoing embodiment, and the semiconductor layer of the dummy unit may include only the semiconductor body part 13X, and is not provided with the first dummy active layer, the second dummy active layer, the fourth dummy active layer to the seventh dummy active layer, and the shape of the semiconductor body part 13X of the dummy unit is substantially the same as the shape of the third active layer 13 in the circuit unit, as shown in FIG. 34.

In an exemplary implementations, the pattern of the first conductive layer of the circuit unit may be substantially the same as the pattern of the first conductive layer of the circuit unit in the foregoing embodiment, the pattern of the first conductive layer of the dummy unit may include a first electrode plate 24 and a first auxiliary connection line 25, a first end of the first auxiliary connection line 25 is connected with the first electrode plate 24 of the present dummy unit, and a second end of the first auxiliary connection line 25, after extending along the first direction X or along an opposite direction of the first direction X, is connected with the first electrode plate 24 of an adjacent dummy unit. The first auxiliary connection line 25 is configured such that first electrode plates of adjacent dummy units on a dummy row are connected with each other, and first electrode plates of a plurality of dummy units in a dummy row form an interconnected integral structure, the first electrode plate with an integral structure may be reused as the second connection line 72, that is, the (M−1)-th and (M+2)-th rows as dummy rows are formed with the second connection lines 72, as shown in FIG. 35.

In an exemplary implementations, the first dummy signal line, the second dummy signal line, and the dummy light emitting signal line are not provided in the dummy unit, and the shape of the first electrode plate 24 of the dummy unit is substantially the same as that of the first electrode plate 24 in the circuit unit.

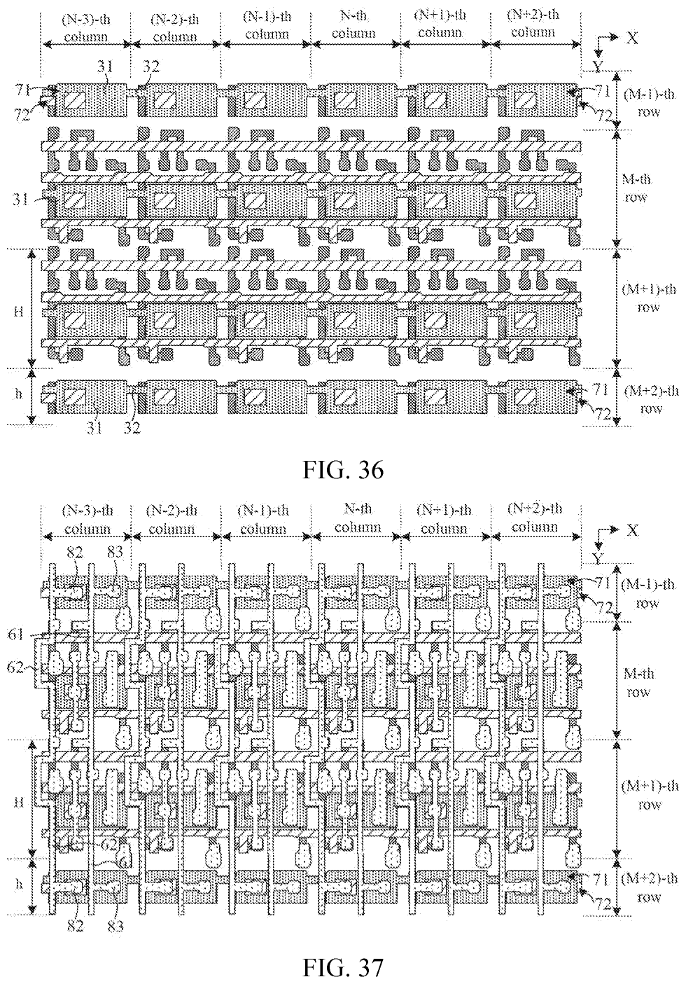

In an exemplary implementations, the pattern of the second conductive layer of the circuit unit may be substantially the same as the pattern of the second conductive layer of the circuit unit in the foregoing embodiments, and the pattern of the second conductive layer of the dummy unit may include a second electrode plate 31 and a second auxiliary connection line 32, the second electrode plate 31 and the second auxiliary connection line 32 of the dummy unit have substantially the same shape as the second electrode plate 31 and the second auxiliary connection line 32 in the circuit unit. A first end of the second auxiliary connection line 32 is connected with the second electrode plate 31 of the present circuit unit, a second end of the second auxiliary connection line 32, after extending along the first direction X or the opposite direction of the first direction X, is connected with the second electrode plate 31 of an adjacent circuit unit, the second auxiliary connection line 32 is configured such that second electrode plates of adjacent circuit units on a unit row are connected with each other, and the second electrode plate with an integral structure is reused as the first connection line 71, that is, the (M−1)-th and (M+2)-th rows as dummy rows are formed with the first connection line 71, as shown in FIG. 36.

In an exemplary implementations, the pattern of the third conductive layer of the circuit unit may be substantially the same as the pattern of the third conductive layer of the circuit unit in the foregoing embodiment, and the pattern of the third conductive layer of the dummy unit may include a second initial electrode 82 and a third initial electrode 83, a first end of the third initial electrode 83 is connected to the first initial signal line 61, a second end of the third initial electrode 83 is connected to the first connection line 71 through a via, a first end of the second initial electrode 82 is connected to the second initial signal line 62, and a second end of the second initial electrode 82 is connected to the second connection line 72 through a via, so that the first initial signal line 61 and the first connection line 71 form a mesh structure for transmitting a first initial signal in the display region, and the second initial signal line 62 and the second connection line 72 form a mesh structure for transmitting a second initial signal in the display region, as shown in FIG. 37. Since the dummy unit of this embodiment is not provided with the first connection electrode and the second connection electrode, structures of the second initial electrode 82 and the third initial electrode 83 in this embodiment are different from those of the foregoing embodiment, and can be understood as the twelfth connection electrode and the thirteenth connection electrode with connection parts.

In some possible exemplary implementations, the first connection line may be disposed in the first conductive layer, the second connection line may be disposed in the second conductive layer, and the pattern of the third conductive layer may include a first initial electrode and a fourth initial electrode, a first end of the first initial electrode is connected to the first initial signal line, a second end of the first initial electrode is connected to the first connection line through a via, a first end of the fourth initial electrode is connected to the second connection line, and a second end of the fourth initial electrode is connected to the second connection line through a via, which is not limited here in the present disclosure.

The display substrate provided by the exemplary embodiment of the present disclosure not only achieves that the first initial signal line transmitting the first initial signal forms a mesh structure and the second initial signal line transmitting the second initial signal forms a mesh structure by respectively providing the first connection line and the second connection line in which main portions extend in the first direction in the dummy row, but also can leave more space to set up the circuit units and improve the resolution of the display region by reducing the size of the dummy row in the second direction.

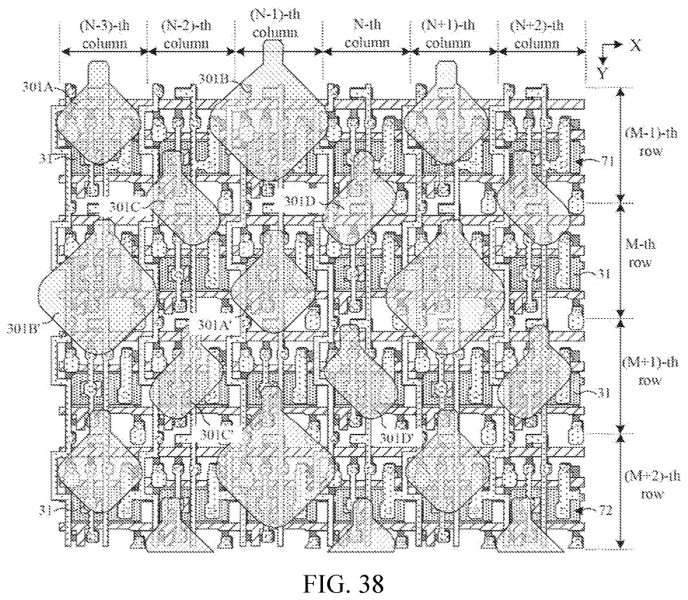

FIG. 38 is a schematic diagram of an arrangement of anodes in a first circuit region according to an embodiment of the present disclosure. An arrangement of circuit units and dummy units in the first circuit region is the same as an arrangement shown in FIG. 12, and a structure of the initial signal line with a mesh structure is the same as that shown in FIG. 21. In an exemplary implementations, patterns of a plurality of anodes may include a first anode 301A of a red light emitting device, a second anode 301B of a blue light emitting device, a third anode 301C of a first green light emitting device, and a fourth anode 301D of a second green light emitting device. The first anode 301A and the second anode 301B may be sequentially disposed along the first direction X, the third anode 301C and the fourth anode 301D may be sequentially disposed along the first direction X, and the third anode 301C and the fourth anode 301D may be disposed on one side of the first anode 301A and the second anode 301B in the second direction Y. Or, the first anode 301A and the second anode 301B may be sequentially disposed along the second direction Y, the third anode 301C and the fourth anode 301D may be sequentially disposed along the second direction Y, and the third anode 301C and the fourth anode 301D may be disposed on one side of the first anode 301A and the second anode 301B in the first direction X.

In an exemplary implementations, the first anode 301A, the second anode 301B, the third anode 301C, and the fourth anode 301D are respectively connected to the pixel driving circuit in the M-th row, and the first anode 301A′, the second anode 301B′, the third anode 301C′, and the fourth anode 301D′ are respectively connected to the pixel driving circuit in the (M+1)-th row. The (M−1)-th row and the (M+2)-th row are dummy rows, and dummy pixel circuits of dummy units in the dummy rows are not used to drive the light emitting units.

In an exemplary implementations, an orthographic projection of at least one of the first anode 301A, the second anode 301B, the third anode 301C, and the fourth anode 301D on the base substrate at least partially overlaps an orthographic projection of a dummy pixel circuit in at least one dummy unit (dummy pixel circuits in the (M−1)-th row and the (M+2)-th row in FIG. 38) on the base substrate, an orthographic projection of at least one of the first anode 301A, the second anode 301B, the third anode 301C, and the fourth anode 301D on the base substrate at least partially overlaps an orthographic projection of the first connection line 71 in at least one dummy unit on the base substrate, and/or, an orthographic projection of at least one of the first anode 301A, the second anode 301B, the third anode 301C, and the fourth anode 301D on the base substrate at least partially overlaps an orthographic projection of the second connection line 72 in at least one dummy unit on the base substrate.

In an exemplary implementations, the first connection line 71 in the (M−1)-th row as a dummy row may include the second electrode plate 31 and the second auxiliary connection line alternately arranged and connected sequentially along the first direction X, and an orthographic projection of at least one of the first anode 301A, the second anode 301B, the third anode 301C and the fourth anode 301D on the base substrate at least partially overlaps an orthographic projection of the second electrode plate 31 in the first connection line 71 on the base substrate.

In an exemplary implementations, for anodes of light emitting devices of a same color, an orthographic projection of the anode of that color on the base substrate and an orthographic projection of the first connection line 71 on the base substrate have a first overlapping region, and an orthographic projection of the anode of that color on the base substrate and an orthographic projection of the second electrode plate 31 in at least one circuit unit on the base substrate have a third overlapping region, an area of the first overlapping region may be smaller than an area of the third overlapping region. For example, an area of an overlapping region of an orthographic projection of the at least one first anode 301A on the base substrate and an orthographic projection of the first connection line 71 on the base substrate is smaller than an area of an overlapping region of an orthographic projection of the at least one first anode 301A′ on the base substrate and an orthographic projection of the second electrode plate 31 in the circuit unit on the base substrate. For another example, an area of an overlapping region of an orthographic projection of the at least one second anode 301B on the base substrate and an orthographic projection of the first connection line 71 on the base substrate is smaller than an area of an overlapping region of an orthographic projection of the at least one second anode 301B′ on the base substrate and an orthographic projection of the second electrode plate 31 in the circuit unit on the base substrate. For yet another example, an area of an overlapping region of an orthographic projection of the at least one third anode 301C on the base substrate and an orthographic projection of the first connection line 71 on the base substrate is smaller than an area of an overlapping region of an orthographic projection of the at least one third anode 301C′ on the base substrate and an orthographic projection of the second electrode plate 31 in the circuit unit on the base substrate. For yet another example, an area of an overlapping region of an orthographic projection of the at least one fourth anode 301D on the base substrate and an orthographic projection of the first connection line 71 on the base substrate is smaller than an area of an overlapping region of an orthographic projection of the at least one fourth anode 301D′ on the base substrate and an orthographic projection of the second electrode plate 31 in the circuit unit on the base substrate.

In an exemplary implementations, the second connection line 72 in the (M+2)-th row as a dummy row may include the second electrode plate 31 and the second auxiliary connection line alternately arranged and connected sequentially along the first direction X, and an orthographic projection of at least one of the first anode 301A, the second anode 301B, the third anode 301C and the fourth anode 301D on the base substrate at least partially overlaps an orthographic projection of the second electrode plate 31 in the second connection line 72 on the base substrate.

In an exemplary implementations, for anodes of light emitting devices of a same color, an orthographic projection of the anode of that color on the base substrate and an orthographic projection of the second connection line 72 on the base substrate have a second overlapping region, and an orthographic projection of the anode of that color on the base substrate and an orthographic projection of the second electrode plate 31 in at least one circuit unit on the base substrate have a third overlapping region, an area of the second overlapping region may be smaller than an area of the third overlapping region. For example, an area of an overlapping region of an orthographic projection of the at least one first anode 301A on the base substrate and an orthographic projection of the second connection line 72 on the base substrate is smaller than an area of an overlapping region of an orthographic projection of the at least one first anode 301A′ on the base substrate and an orthographic projection of the second electrode plate 31 in the circuit unit on the base substrate. For another example, an area of an overlapping region of an orthographic projection of the at least one second anode 301B on the base substrate and an orthographic projection of the second connection line 72 on the base substrate is smaller than an area of an overlapping region of an orthographic projection of the at least one second anode 301B′ on the base substrate and an orthographic projection of the second electrode plate 31 in the circuit unit on the base substrate. For yet another example, an area of an overlapping region of an orthographic projection of the at least one third anode 301C on the base substrate and an orthographic projection of the second connection line 72 on the base substrate is smaller than an area of an overlapping region of an orthographic projection of the at least one third anode 301C′ on the base substrate and an orthographic projection of the second electrode plate 31 in the circuit unit on the base substrate. For yet another example, an area of an overlapping region of an orthographic projection of the at least one fourth anode 301D on the base substrate and an orthographic projection of the second connection line 72 on the base substrate is smaller than an area of an overlapping region of an orthographic projection of the at least one fourth anode 301D′ on the base substrate and an orthographic projection of the second electrode plate 31 in the circuit unit on the base substrate.

In an exemplary implementations, the first connection line 71 and the second connection line 72 respectively transmit the first initial signal and the second initial signal. By setting the anode and the first connection line 71 to have a small overlapping area or setting the anode and the second connection line 72 to have a small overlapping area, the present disclosure can prevent the first initial signal or the second initial signal from disturbing the anode during reset, reduce the influence on the brightness, and improve the display quality and display effect. Since the second electrode plate in the circuit unit is at the potential of the first power supply line, and the first power supply line continuously provides a high voltage signal, the anode and the second electrode plate in the circuit unit can have a larger overlapping area, which not only does not disturb the anode, but also can improve the flatness of the anode.

In an exemplary implementations, the light emitting structure layer may also include a plurality of anode connection lines (not shown in FIG. 38), a first end of the anode connection line may be connected to a corresponding anode, and a second end of the anode connection line may be connected to the anode connection electrode of a corresponding circuit unit, so as to realize the connection of the anode and the pixel driving circuit. The anode connection line may use a single-layer structure, such as Indium Tin Oxide (ITO) or Indium Zinc Oxide (IZO) or may use a multi-layer composite structure, such as ITO/Ag/ITO. The anode connection line and the anode may be arranged in a same layer or in different layers, which is not limited in the present disclosure.

The structure shown and mentioned above in the present disclosure and the manufacturing process thereof are merely an exemplary description. In an exemplary implementation, the corresponding structures may be altered and the patterning processes may be added or reduced according to actual needs. For example, a first connection line in at least one dummy row may extend to one side or two sides of the display substrate along the first direction X and then be connected to a low voltage power supply lead line in the bezel region, the low voltage power supply lead line is configured to transmit a low voltage power supply signal (VSS), such that the first connection line forms a transverse grid structure for transmitting a low voltage power supply signal in the display region. For another example, a second connection line in at least one dummy row can extend to one side or two sides of the display substrate along the first direction X and then be connected with a low voltage power supply lead line in the bezel region, so that the second connection line forms a transverse grid structure for transmitting a low voltage power supply signal in the display region. For yet another example, a part of first connection lines are connected with the first initial signal line to form a mesh structure for transmitting a first initial signal, another part of the first connection lines are connected with a low voltage power supply lead line in the bezel region to form a transverse grid structure for transmitting a low voltage power supply signal, a part of second connection lines are connected with the second initial signal line to form a mesh structure for transmitting a second initial signal, and another part of the second connection lines are connected with a low voltage power supply lead line in the bezel region to form a transverse grid structure for transmitting a low voltage power supply signal, which is not limited in the present disclosure.

The display substrate of the present disclosure may be applied to another display apparatus having a pixel driving circuit, which is not limited here in the present disclosure.

The present disclosure also provides a preparation method for a display substrate, for preparing the display substrate according to the foregoing embodiments. In an exemplary implementation, the method may include the following acts.

A drive structure layer is formed on the base substrate. The drive structure layer includes a plurality of unit rows and at least two dummy rows, a unit row includes a plurality of circuit units sequentially arranged along a first direction, a dummy row includes a plurality of dummy units sequentially arranged along the first direction, the plurality of unit rows and the at least two dummy rows are sequentially provided along a second direction, the first direction and the second direction intersect. A circuit unit includes a pixel driving circuit, a dummy unit includes a dummy pixel circuit, the pixel driving circuit is configured to drive a corresponding light emitting unit. At least one dummy row is provided with a first connection line extending along the first direction, the first connection line is connected with a first initial signal line extending along the second direction to form a mesh structure for transmitting a first initial signal; and/or, at least one other dummy row is provided with a second connection line extending along the first direction, the second connection line is connected with a second initial signal line extending along the second direction to form a mesh structure for transmitting a second initial signal.

A light emitting structure layer is formed on the drive structure layer. The light emitting structure layer includes a plurality of light emitting units, an orthographic projection of at least one light emitting unit on the base substrate at least partially overlaps an orthographic projection of the dummy pixel circuit on the base substrate.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, and this is not limited in the embodiments of the present invention.

Although implementations disclosed in the present disclosure are described as above, the described contents are only implementations which are used for facilitating understanding of the present disclosure, but are not intended to limit the present invention. Any skilled person in the art to which the present disclosure pertains may make any modification and variation in a form and details of implementation without departing from the spirit and scope of the present disclosure. However, the patent protection scope of the present invention should be subject to the scope defined in the appended claims.

1. A display substrate, comprising a drive structure layer disposed on a base substrate, and a light emitting structure layer disposed on a side of the drive structure layer away from the base substrate, wherein the light emitting structure layer comprises a plurality of light emitting units, the drive structure layer comprises a plurality of unit rows and at least two dummy rows, a unit row comprises a plurality of circuit units sequentially arranged along a first direction, a dummy row comprises a plurality of dummy units sequentially arranged along the first direction, the plurality of unit rows and the at least two dummy rows are sequentially provided along a second direction, the first direction and the second direction intersect; a circuit unit comprises a pixel driving circuit, a dummy unit comprises a dummy pixel circuit, the pixel driving circuit is configured to drive a corresponding light emitting unit, an orthographic projection of at least one light emitting unit on the base substrate at least partially overlaps an orthographic projection of the dummy pixel circuit on the base substrate; at least one dummy row is provided with a first connection line extending along the first direction, the first connection line is connected with a first initial signal line extending along the second direction to form a mesh structure for transmitting a first initial signal; and/or, at least another dummy row is provided with a second connection line extending along the first direction, the second connection line is connected with a second initial signal line extending along the second direction, to form a mesh structure for transmitting a second initial signal.

2. The display substrate according to claim 1, wherein, in a plane perpendicular to the base substrate, the drive structure layer comprises a semiconductor layer, a first conductive layer, a second conductive layer, and a third conductive layer that are sequentially disposed on the base substrate, the first connection line is disposed in at least one of the semiconductor layer, the first conductive layer, and the second conductive layer, the second connection line is disposed in at least one of the semiconductor layer, the first conductive layer, and the second conductive layer, and the first initial signal line and the second initial signal line are disposed in the third conductive layer.

3. The display substrate according to claim 2, wherein a first conductive layer in a dummy unit of the at least one dummy row comprises the first connection line; a third conductive layer of at least one dummy unit in the dummy row comprises at least a first initial electrode, the first initial signal line is connected with the first initial electrode, and the first initial electrode is connected with the first connection line through a via;
or
a first conductive layer in a dummy unit of the at least one dummy row comprises the second connection line; a third conductive layer of at least one dummy unit in the dummy row at least comprises a second initial electrode, the second initial signal line is connected with the second initial electrode, and the second initial electrode is connected with the second connection line through a via;
or
a second conductive layer in a dummy unit of the at least one dummy row comprises the first connection line; a third conductive layer of at least one dummy unit in the dummy row at least comprises a third initial electrode, the first initial signal line is connected with the third initial electrode, and the third initial electrode is connected with the first connection line through a via;
or
a second conductive layer in a dummy unit of the at least one dummy row comprises the second connection line; a third conductive layer of at least one dummy unit in the dummy row at least comprises a fourth initial electrode, the second initial signal line is connected with the fourth initial electrode, and the fourth initial electrode is connected with the second connection line through a via.

4-6. (canceled)

7. The display substrate according to claim 2, wherein a semiconductor layer in a dummy unit of the at least one dummy row comprises the first connection line; a third conductive layer of at least one dummy unit in the dummy row at least comprises a fifth initial electrode, the first initial signal line is connected with the fifth initial electrode, and the fifth initial electrode is connected with the first connection line through a via.

8. The display substrate according to claim 2, wherein a semiconductor layer in a dummy unit of the at least one dummy row comprises the second connection line; a third conductive layer of at least one dummy unit in the dummy row at least comprises a sixth initial electrode, the second initial signal line is connected with the sixth initial electrode, and the sixth initial electrode is connected with the second connection line through a via.

9. The display substrate according to claim 2, wherein a first conductive layer in a dummy unit of the at least one dummy row comprises the first connection line, and a second conductive layer in a dummy unit of the dummy row comprises the second connection line; a third conductive layer of at least one dummy unit in the dummy row at least comprises a first initial electrode and a fourth initial electrode, the first initial signal line is connected with the first initial electrode, the first initial electrode is connected with the first connection line through a via, the second initial signal line is connected with the fourth initial electrode, and the fourth initial electrode is connected with the second connection line through a via;
or
a first conductive layer in a dummy unit of the at least one dummy row comprises the second connection line, and a second conductive layer in a dummy unit of the dummy row comprises the first connection line; a third conductive layer of at least one dummy unit in the dummy row at least comprises a second initial electrode and a third initial electrode, the first initial signal line is connected to the third initial electrode, the third initial electrode is connected to the first connection line through a via, the second initial signal line is connected to the second initial electrode, and the second initial electrode is connected to the second connection line through a via;
or
a first conductive layer of a dummy unit of the at least one dummy row comprises the first connection line, and a third conductive layer of at least one dummy unit of the dummy row at least comprises a first initial electrode, the first initial signal line is connected to the first initial electrode, the first initial electrode is connected to the first connection line through a via; a first conductive layer of a dummy unit of at least another dummy row comprises the second connection line, a third conductive layer of at least one dummy unit of the dummy row at least comprises a second initial electrode, the second initial signal line is connected to the second initial electrode, and the second initial electrode is connected to the second connection line through a via;
or
a second conductive layer in a dummy unit of the at least one dummy row comprises the first connection line, and a third conductive layer of at least one dummy unit of the dummy row at least comprises a third initial electrode, the first initial signal line is connected to the third initial electrode, and the third initial electrode is connected to the first connection line through a via; a second conductive layer in a dummy unit of at least another dummy row comprises the second connection line, a third conductive layer of at least one dummy unit of the dummy row at least comprises a fourth initial electrode, the second initial signal line is connected to the fourth initial electrode, and the fourth initial electrode is connected to the second connection line through a via.

10-12. (canceled)

13. The display substrate according to claim 1, wherein at least one circuit unit comprises a pixel driving circuit at least comprising a first transistor, a second transistor, a third transistor, a fourth transistor, a fifth transistor, a sixth transistor, a seventh transistor, a first node and a second node; a first electrode of the first transistor is connected to the first initial signal line, a second electrode of the first transistor is connected to the second node, a first electrode of the second transistor is connected to the second node, a second electrode of the second transistor is connected to a second electrode of the third transistor and a first electrode of the sixth transistor, a first electrode of the third transistor is connected to the first node, a first electrode of the fourth transistor is connected to a data signal line, a second electrode of the fourth transistor is connected to the first node, a first electrode of the fifth transistor is connected to a first power supply line, a second electrode of the fifth transistor is connected to the first node, a second electrode of the sixth transistor is connected to a second electrode of the seventh transistor, and a first electrode of the seventh transistor is connected to the second initial signal line.

14. The display substrate according to claim 13, wherein, in at least one circuit unit, an active layer of the third transistor is in a shape of a straight line extending along the first direction;
or
in at least one circuit unit, the first transistor, the sixth transistor, and the seventh transistor are disposed on a same side of the third transistor in the second direction.

15. (canceled)

16. The display substrate according to claim 13, wherein an orthographic projection of the second node on the base substrate overlaps at least partially an orthographic projection of the first power supply line on the base substrate;
or
the second node is located between the first initial signal line and the second initial signal line in the first direction.

17. (canceled)

18. The display substrate according to claim 13, wherein at least one circuit unit further comprises a light emitting control line extending along the first direction, the light emitting control line is connected to a gate electrode of the fifth transistor and a gate electrode of the sixth transistor, and an orthographic projection of the second node on the base substrate at least partially overlaps an orthographic projection of the light emitting control line on the base substrate.

19. The display substrate according to claim 13, wherein the pixel driving circuit further comprises a first shielding electrode connected to the first initial signal line, an orthographic projection of the first shielding electrode on the base substrate at least partially overlaps an orthographic projection of an active layer of the first transistor on the base substrate.

20. The display substrate according to claim 13, wherein orthographic projections of a via through which the first electrode of the fifth transistor is connected to a first region of an active layer of the fifth transistor, a via through which the second electrode of the sixth transistor is connected to a second region of an active layer of the sixth transistor, a via through which the first initial signal line is connected to a first region of an active layer of the first transistor, a via through which the second node is connected to a second region of the active layer of the first transistor on the base substrate at least partially overlap an orthographic projection of a hole extension line on the base substrate, the hole extension line is a straight line extending along the first direction.

21. The display substrate according to claim 1, wherein at least one dummy unit comprises a dummy pixel circuit at least comprising a semiconductor body part and a storage capacitor, the storage capacitor comprises a first electrode plate and a second electrode plate, an orthographic projection of the first electrode plate on the base substrate at least partially overlaps an orthographic projection of the second electrode plate on the base substrate; semiconductor body parts adjacent in the first direction are connected to each other by a third auxiliary connection line to form the first connection line or the second connection line, or first electrode plates adjacent in the first direction are connected to each other by a first auxiliary connection line to form the first connection line or the second connection line, or second electrode plates adjacent in the first direction are connected to each other by a second auxiliary connection line to form the first connection line or the second connection line.

22. The display substrate according to claim 21, wherein the dummy pixel circuit of the at least one dummy unit is connected to a first dummy signal line, a second dummy signal line and/or a dummy light emitting line, the first dummy signal line, the second dummy signal line and/or the dummy light emitting line, after extending to one side or two sides of the display substrate along the first direction, are connected to a bezel power supply lead line in a bezel region, and the bezel power supply lead line is configured to transmit a high voltage power supply signal or a low voltage power supply signal;
or
the dummy pixel circuit of the at least one dummy unit further comprises a first dummy transistor, a second dummy transistor, a third dummy transistor, a fourth dummy transistor, a fifth dummy transistor, a sixth dummy transistor, and a seventh dummy transistor, an active layer of the third dummy transistor serves as the semiconductor body part, and active layers of the first dummy transistor, the second dummy transistor, the fourth dummy transistor, the fifth dummy transistor, the sixth dummy transistor, and the seventh dummy transistor lack channel regions.

23. (canceled)

24. The display substrate according to claim 1, wherein one or two unit rows are provided between dummy rows adjacent in the second direction.

25. The display substrate according to claim 24, wherein a size of the dummy row in the second direction is less than or equal to a size of the unit row in the second direction.

26. The display substrate according to claim 1, wherein a light emitting unit at least comprises an anode, an orthographic projection of the anode on the base substrate at least partially overlaps an orthographic projection of the first connection line on the base substrate; and/or, an orthographic projection of the anode on the base substrate at least partially overlaps an orthographic projection of the second connection line on the base substrate.

27. The display substrate according to claim 26, wherein, for anodes of light emitting units of a same color, an orthographic projection of the anodes on the base substrate and an orthographic projection of the first connection line on the base substrate have a first overlapping region, the orthographic projection of the anodes on the base substrate and an orthographic projection of the second connection line on the base substrate have a second overlapping region, the orthographic projection of the anodes on the base substrate and an orthographic projection of the second electrode plate of the pixel driving circuit in at least one circuit unit have a third overlapping region, an area of at least one first overlapping region is smaller than an area of the third overlapping region, and an area of at least one second overlapping region is smaller than the area of the third overlapping region.

28. A display apparatus, comprising the display substrate according to claim 1.

29. A preparation method for a display substrate, comprising:
forming a drive structure layer on a base substrate; wherein the drive structure layer comprises a plurality of unit rows and at least two dummy rows, a unit row comprises a plurality of circuit units sequentially arranged along a first direction, a dummy row comprises a plurality of dummy units sequentially arranged along the first direction, the plurality of unit rows and the at least two dummy rows are sequentially provided along a second direction, the first direction and the second direction intersect; a circuit unit comprises a pixel driving circuit, a dummy unit comprises a dummy pixel circuit, the pixel driving circuit is configured to drive a corresponding light emitting unit; at least one dummy row is provided with a first connection line extending along the first direction, the first connection line is connected with a first initial signal line extending along the second direction to form a mesh structure for transmitting a first initial signal; and/or, at least one another dummy row is provided with a second connection line extending along the first direction, the second connection line is connected with a second initial signal line extending along the second direction to form a mesh structure for transmitting a second initial signal; and
forming a light emitting structure layer on the drive structure layer, wherein the light emitting structure layer comprises a plurality of light emitting units, an orthographic projection of at least one light emitting unit on the base substrate at least partially overlaps an orthographic projection of the dummy pixel circuit on the base substrate.
